(19) United States
(12) Patent Application Publication
(10) Pub. No.: US 2025/0248293 A1
(43) Pub. Date: Jul. 31, 2025

(54) PHOSPHORESCENT PLATINUM EMITTERS FOR OLED APPLICATIONS

(71) Applicants: The University of Hong Kong, Hong Kong (CN); Hong Kong Quantum AI Lab Limited, Hong Kong (CN)

(72) Inventors: Chi-Ming Che, Hong Kong (CN); Chengzhi Jiang, Hong Kong (CN)

(21) Appl. No.: 19/012,590

(22) Filed: Jan. 7, 2025

Related U.S. Application Data
(60) Provisional application No. 63/625,646, filed on Jan. 26, 2024.

(51) Int. Cl. H10K 85/30; C07F 15/00; C09K 11/06; H10K 50/12; H10K 50/13

(52) U.S. Cl. CPC H10K 85/346; C07F 15/0086; C09K 11/06; C09K 2211/1011; C09K 2211/1044; C09K 2211/1059; C09K 2211/185; H10K 50/121; H10K 50/13

(57) ABSTRACT

Described herein are platinum(II) complexes and their methods of making and using thereof. The design of the platinum(II) complexes results in emission in the blue spectral region with high quantum yields and fast radiative decay rates at room temperature. The platinum(II) complexes can be used to fabricate efficient blue emitting OLEDs.

### CROSS REFERENCE TO RELATED APPLICATION

This application claims priority to U.S. Provisional Patent Application No. 63/625,646 filed Jan. 26, 2024, the disclosure of which is incorporated herein by reference.

### FIELD OF THE INVENTION

The disclosed invention is generally in the field of platinum(II) complexes and their use in organic electronics, such as organic light-emitting diodes (OLEDs), as phosphorescent blue dopants.

### BACKGROUND OF THE INVENTION

In the past decade, several examples of phosphorescent blue platinum(II) complexes supported by N-heterocyclic carbene (NHC) ligand have been reported. For example, Strassner, et al. (Dalton Trans. 2013, 42, 9847; Chem. Eur. J. 2019, 25, 14495) reported a series of blue light-emitting bidentate Pt(C*\hat{ }C)acac complexes. Che, et al. (J. Mater. Chem. C 2022, 10, 10271) reported a series of deep blue NHC-pincer-type Pt(II) complexes. However, these examples of bi- or tridentate platinum complexes suffer from unwanted structural distortion in excited states, and weak electrochemical stability, which in turn hinder their development and restrict their applications.

Platinum (II) complexes with tetradentate ligands are more stable and robust owing to the stronger chelating effect and ligand rigidity. Different types of NHC-supported tetradentate platinum(II) complexes were reported, one of which is based on the C*\hat{ }C\hat{ }C\hat{ }N (C* represents NHC coordination, and C means phenyl carbanion coordination) ligand system. Kim, et al. (Nat. Photonics 2022, 16, 212) reported a benzimidazole based NHC supported platinum(II) complex showing luminescence in a deep blue region. Applying two NHC moieties can help achieve an even higher-lying metal-centered triplet excited state (3MC). Considering the stability issue associated with the trans-effect, two phenolate moieties can be installed in the trans-position of the NHCs as a weak field ligand, leading to a unique ligand system O\hat{ }C*\hat{ }C*\hat{ }O. Che, et al. (Chem. Commun. 2011, 47, 9075; U.S. Pat. No. 8,957,217B2) reported Pt(II)-O\hat{ }C*\hat{ }C*\hat{ }O complexes with blue emission at 443 nm, where the phenolate, as a typical electron donor, formed a donor-acceptor structure with the imidazole based NHC and resulted in a blue emission from high energy ³ILCT with ³MLCT perturbation. Che, et al. also reported the vacuum-deposited device which showed blue electrophosphorescence. Later, Che, et al. (Chem. Sci. 2013, 4, 2630) fabricated deep blue OLEDs using Pt(II)-O\hat{ }C*\hat{ }C*\hat{ }O complex as phosphorescent blue dopant.

Although these fused 6,6,6-metallacycle allows a good coordinate geometry, the Pt-O\hat{ }C*\hat{ }C*\hat{ }O complexes still face problems in (i) high turn-on voltage and (ii) large EQE roll-off. Thus, devices fabricated with Pt-O\hat{ }C*\hat{ }C*\hat{ }O complexes suffer from (i) a high triplet energy mainly coming from the higher-lying LUMO, and (ii) a slow radiative decay rate (small kᵣ) and therefore a longer emission lifetime (t).

There remains a need to develop blue emitters with improved properties, such as high emission quantum yield and fast radiative decay rate.

Therefore, it is the object of the present invention to provide new platinum(II) complexes that emit in the blue regions with improved properties.

It is a further object of the present invention to provide devices containing the new platinum(II) complexes.

It is a further object of the present invention to provide methods for using the new platinum(II) complexes.

### SUMMARY OF THE INVENTION

Platinum(II) complexes that can emit in the blue regions and methods of making and using thereof are described. The platinum(II) complexes contain platinum(II) atoms complexed by ligands containing benzimidazole based NHC and phenolate moieties. In some forms, the phenolate moiety of the ligands contains one or more bulky substitutions, such as bulky phenyl groups, for example, 3,5-di-tertbutyl-phenyl (ditBuPh) and/or 2,6-dimethyl-phenyl (diMePh). The structure of the disclosed Pt(II) complexes allows for tremendous increment in emission quantum yield and radiative decay rate constant, compared to the previously reported imidazole-based Pt(II)-O\hat{ }C*\hat{ }C*\hat{ }O complexes. For example, the Pt(II) complexes emit in blue regions (λₘₐₓ at 420 nm-490 nm, such as 441-454 nm) with a high emission quantum yield (i.e. Φₑₘ≥30% measured in thin films, such as from 30% to 90%, from 30% to 85%, or from 30% to 80%), a short emission lifetime (i.e. τₑₘ or τ≤5.5 μs or ≤5 μs and down to about 2 μs, such as about 2.25 μs), and/or a fast radiative decay rate (i.e. kᵣ≥1.0×10⁵ s⁻¹ and up to about 6.0×10⁵ s⁻¹, such as about 3.4×10⁵ s⁻¹), measured in thin films at room temperature. Without being bound to any theories, the improvement in the emission properties of the Pt(II) complexes may be ascribed to the geometry in these metal complexes (e.g., a reduced planarity and changed orientation between the NHC and the phenolate ring) and the extended π-conjugation of acceptor units.

In some forms, the platinum(II) complexes can have a structure:

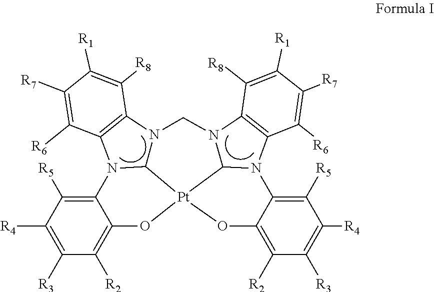

wherein: (i) each occurrence of R₁-R₈ can be independently hydrogen, a halide (e.g., fluoride, chloride, bromide, iodide, etc.), hydroxyl, amino, amido, thiol, cyano, nitro, alkoxy, carbonyl, a substituted or unsubstituted C₁-C₁₂ alkyl, a substituted or unsubstituted C₁-C₁₂ alkenyl, a substituted or unsubstituted C₁-C₁₂ alkynyl, a substituted or unsubstituted aryl (e.g., phenyl), a substituted or unsubstituted heteroaryl, a substituted or unsubstituted polyaryl, or a substituted or unsubstituted heteropolyaryl, or two neighboring R groups together with the carbon atoms to which they are attached can form a substituted or unsubstituted aryl, a substituted or unsubstituted heteroaryl, a substituted or unsubstituted polyaryl, or a substituted or unsubstituted heteropolyaryl; and (ii) the substituent(s), when present, can be independently an unsubstituted C₁-C₁₂ alkyl, an unsubstituted C₁-C₁₂ alkenyl, an unsubstituted C₁-C₁₂ alkynyl, an unsubstituted aryl (e.g., phenyl), a substituted aryl (e.g., phenyl) by unsubstituted aryl(s) (e.g., unsubstituted phenyls) and/or unsubstituted alkyl(s) (e.g., unsubstituted C₁-C₁₂ alkyl), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), an amino, or a halide.

In some forms, the platinum(II) complexes can have a structure:

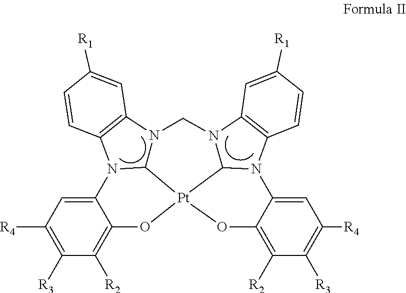

wherein R₁-R₄ can be as defined above for Formula I.

In some forms, the platinum(II) complexes can have a structure:

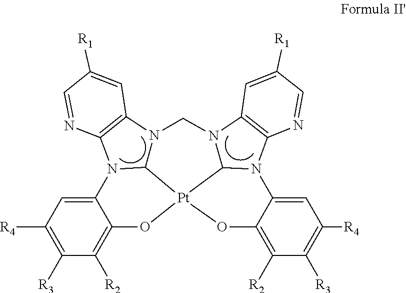

wherein R₁-R₄ can be as defined above for Formula I.

In some forms, the platinum(II) complexes can have a structure:

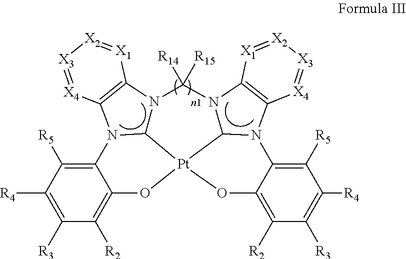

wherein: (i) each occurrence of X₁-X₄ can be independently nitrogen or CR₁₆; (ii) R₂-R₅ and R₁₆ can be as defined for R₁-R₈ of Formula I above; (iii) n1 is an integer from 1 to 6, from 1 to 5, from 1 to 4, from 1 to 3, or 1 or 2; (iv) R₁₄ and R₁₅ can be independently hydrogen, a substituted or unsubstituted C₁-C₁₂ alkyl, a substituted or unsubstituted C₁-C₁₂ alkenyl, or a substituted or unsubstituted C₁-C₁₂ alkynyl, or R₁₄ and R₁₅ of two neighboring carbon atoms, together with the carbon atoms to which they are attached, can form a substituted or unsubstituted aryl, a substituted or unsubstituted heteroaryl, a substituted or unsubstituted polyaryl, or a substituted or unsubstituted heteropolyaryl; and (v) the substituent(s), when present, can be as defined above for Formula I.

In some forms, X₁ and X₄ can be independently nitrogen or CR₁₆; X₂ and X₃ can be CR₁₆; R₁₆ can be hydrogen, halide, an unsubstituted C₁-C₁₂ alkyl, an unsubstituted aryl, or an aryl substituted by unsubstituted C₁-C₁₂ alkyl(s); R₂-R₅ can be independently hydrogen, amino, an unsubstituted C₁-C₁₂ alkyl, a substituted or unsubstituted aryl, a substituted or unsubstituted heteroaryl, a substituted or unsubstituted polyaryl, or a substituted or unsubstituted heteropolyaryl, or R₂ and R₃, R₃ and R₄, or R₄ and R₅ together with the carbon atoms to which they are attached can form a substituted or unsubstituted aryl, a substituted or unsubstituted heteroaryl, a substituted or unsubstituted polyaryl, or a substituted or unsubstituted heteropolyaryl; and the substituent(s), when present, can be independently an unsubstituted C₁-C₁₂ alkyl, an unsubstituted aryl (e.g., phenyl), a substituted aryl (e.g., phenyl) by unsubstituted aryl(s) (e.g., phenyls) and/or unsubstituted alkyl(s), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), or an amino. In some forms, X₁-X₃ can be CR₁₆ and X₄ can be independently nitrogen or CR₁₆, R₁₆ can be hydrogen, a halide, an unsubstituted C₁-C₁₂ alkyl (e.g., an unsubstituted C₁-C₆ alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or

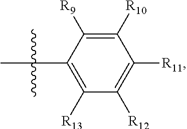

and wherein R₉-R₁₃ can be independently hydrogen or an unsubstituted C₁-C₁₂ alkyl (e.g., methyl, ethyl, n-propyl, isopropyl, n-butyl, isobutyl, tert-butyl, etc.).

In some forms, each occurrence of R₁-R₈ can be independently hydrogen, a halide, a substituted or unsubstituted C₁-C₁₂ alkyl, a substituted or unsubstituted C₁-C₁₂ alkenyl, a substituted or unsubstituted C₁-C₁₂ alkynyl, a substituted or unsubstituted aryl, a substituted or unsubstituted heteroaryl, a substituted or unsubstituted polyaryl, or a substituted or unsubstituted heteropolyaryl.

In some forms, each occurrence of R₁-R₈ can be independently hydrogen, a halide, a substituted or unsubstituted C₁-C₁₂ alkyl, or a substituted or unsubstituted aryl.

In some forms, each occurrence of R₁-R₈ can be independently hydrogen, a halide (e.g., fluoride, chloride, or bromide), an unsubstituted C₁-C₁₂ alkyl (e.g., an unsubstituted C₁-C₆alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or

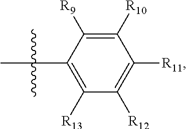

and wherein R₉-R₁₃ can be independently hydrogen, an unsubstituted C₁-C₁₂ alkyl (e.g., methyl, ethyl, n-propyl, isopropyl, n-butyl, isobutyl, tert-butyl, etc.), an unsubstituted phenyl, an unsubstituted heteropolyaryl, or an amino. In some forms, R₉-R₁₃ can be independently hydrogen or an unsubstituted C₁-C₆ alkyl (e.g., methyl, ethyl, n-propyl, isopropyl, n-butyl, isobutyl, tert-butyl, etc.). In some forms, R₉ and R₁₃ can be independently hydrogen or an unsubstituted C₁-C₆alkyl (e.g., methyl, ethyl, n-propyl, isopropyl, n-butyl, isobutyl, tert-butyl, etc.) and R₁₀-R₁₂ can be hydrogen. In some forms, R₁₀ and R₁₂ can be independently hydrogen or an unsubstituted C₁-C₆ alkyl (e.g., methyl, ethyl, n-propyl, isopropyl, n-butyl, isobutyl, tert-butyl, etc.) and R₉, R₁₁, and R₁₃ can be hydrogen.

In some forms, when the platinum(II) complex has the structure of Formula II or II′, R₁-R₄ can be independently hydrogen, a halide, an unsubstituted C₁-C₁₂ alkyl (e.g., an unsubstituted C₁-C₆ alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or

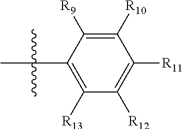

and wherein R₉-R₁₃ can be independently hydrogen, an unsubstituted C₁-C₁₂ alkyl (e.g., methyl, ethyl, n-propyl, isopropyl, n-butyl, isobutyl, tert-butyl, etc.), an unsubstituted phenyl, an unsubstituted heteropolyaryl, or an amino. In some forms, R₉-R₁₃ can be independently hydrogen or an unsubstituted C₁-C₆ alkyl (e.g., methyl, ethyl, n-propyl, isopropyl, n-butyl, isobutyl, tert-butyl, etc.). In some forms, R₉ and R₁₃ can be independently hydrogen or an unsubstituted C₁-C₆ alkyl (e.g., methyl, ethyl, n-propyl, isopropyl, n-butyl, isobutyl, tert-butyl, etc.) and Rio-R₁₂ can be hydrogen. In some forms, R₁₀ and R₁₂ can be independently hydrogen or an unsubstituted C₁-C₆ alkyl (e.g., methyl, ethyl, n-propyl, isopropyl, n-butyl, isobutyl, tert-butyl, etc.) and R₉, R₁₁, and R₁₃ can be hydrogen.

In some forms, when the platinum(II) complex has the structure of Formula II′, R₁-R₄ can be independently hydrogen, a halide, an unsubstituted C₁-C₁₂ alkyl (e.g., an unsubstituted C₁-C₆ alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or

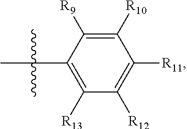

and wherein R₉-R₁₃ can be independently hydrogen, an unsubstituted C₁-C₁₂ alkyl (e.g., methyl, ethyl, n-propyl, isopropyl, n-butyl, isobutyl, tert-butyl, etc.), an unsubstituted phenyl, an unsubstituted heteropolyaryl, or an amino. Optionally, in these forms, at least one of R₁-R₄ is not hydrogen (e.g., R₄ can be a halide, an unsubstituted C₁-C₆ alkyl, or

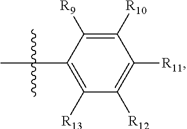

R₉-R₁₃ can be independently hydrogen or an unsubstituted C₁-C₆ alkyl).

In some forms, the platinum(II) complex can have any one of the structures below:

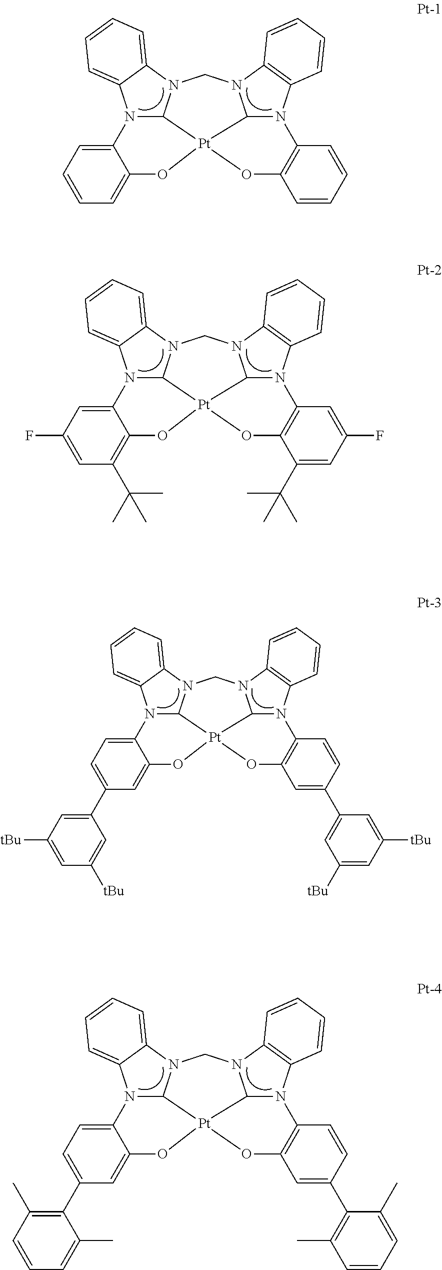

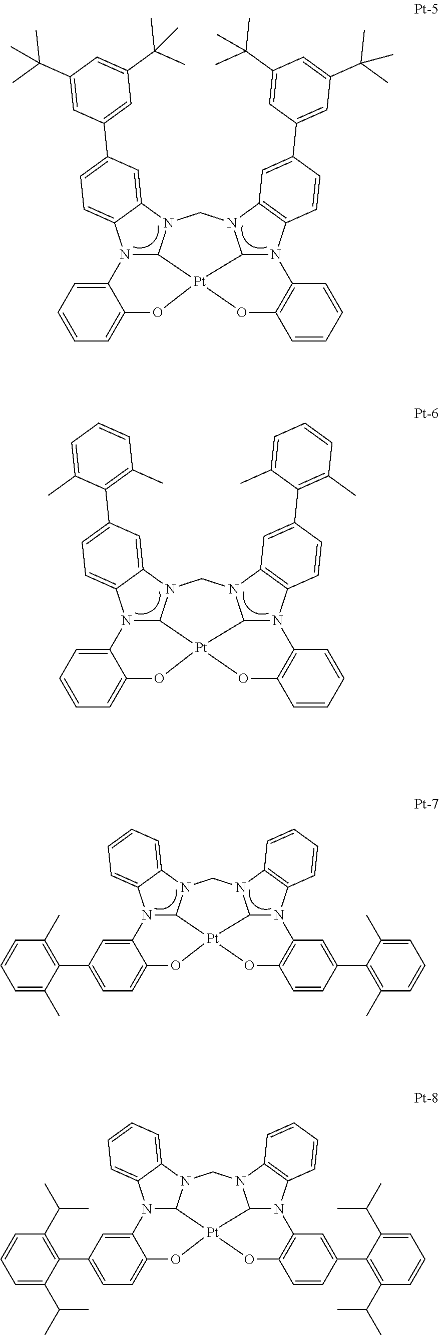

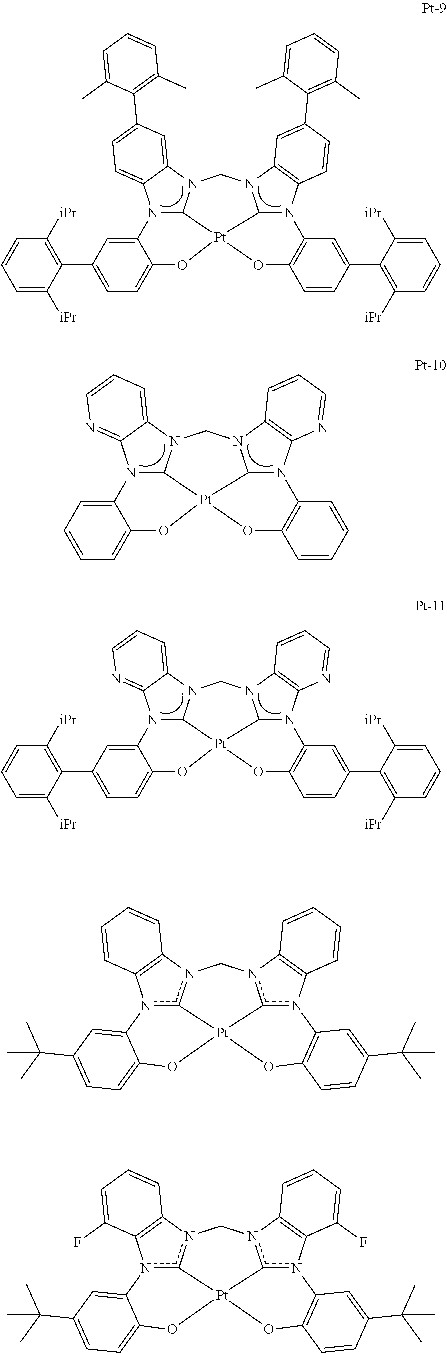

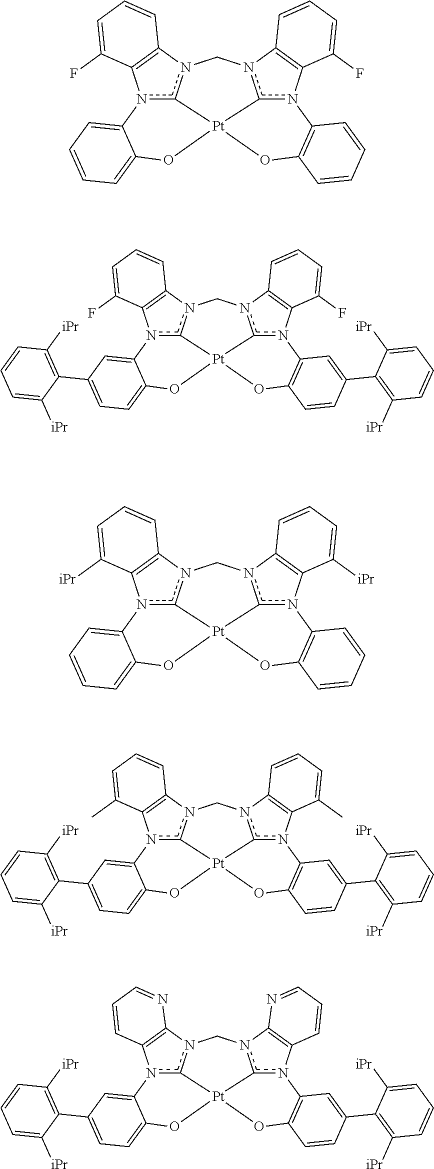

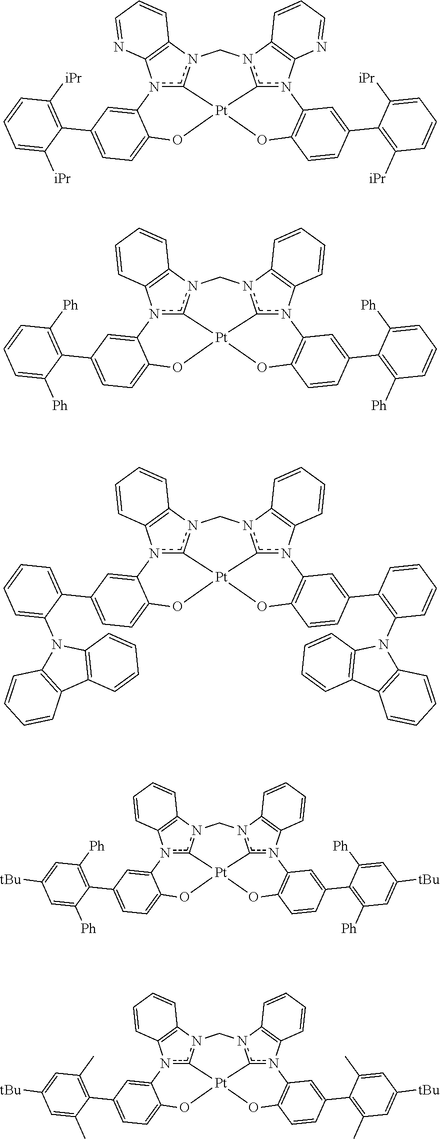

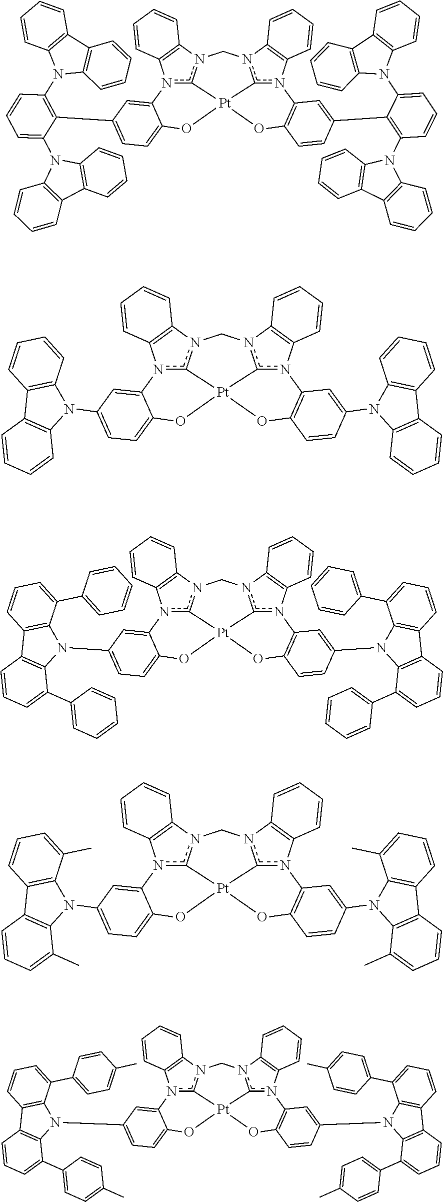

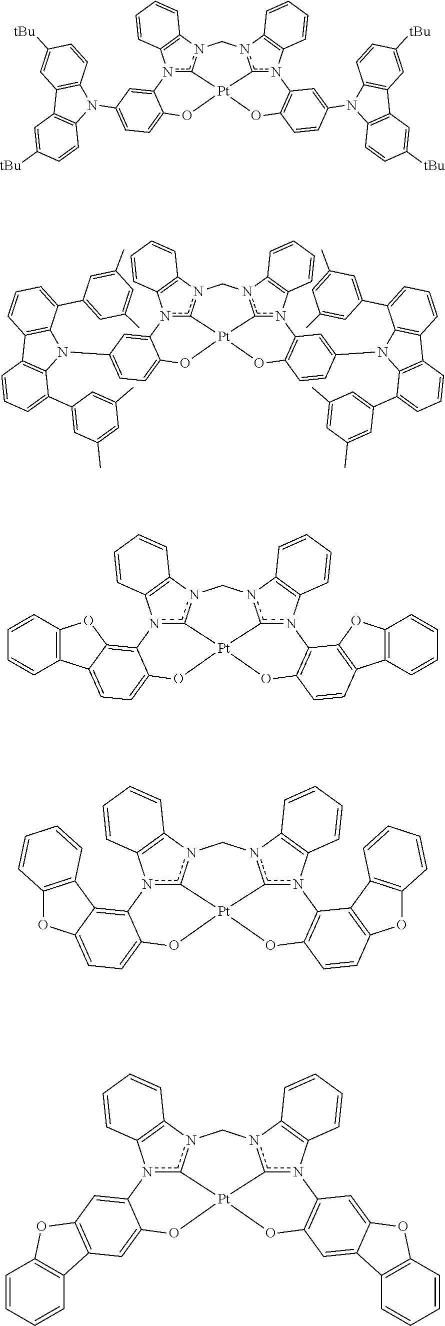

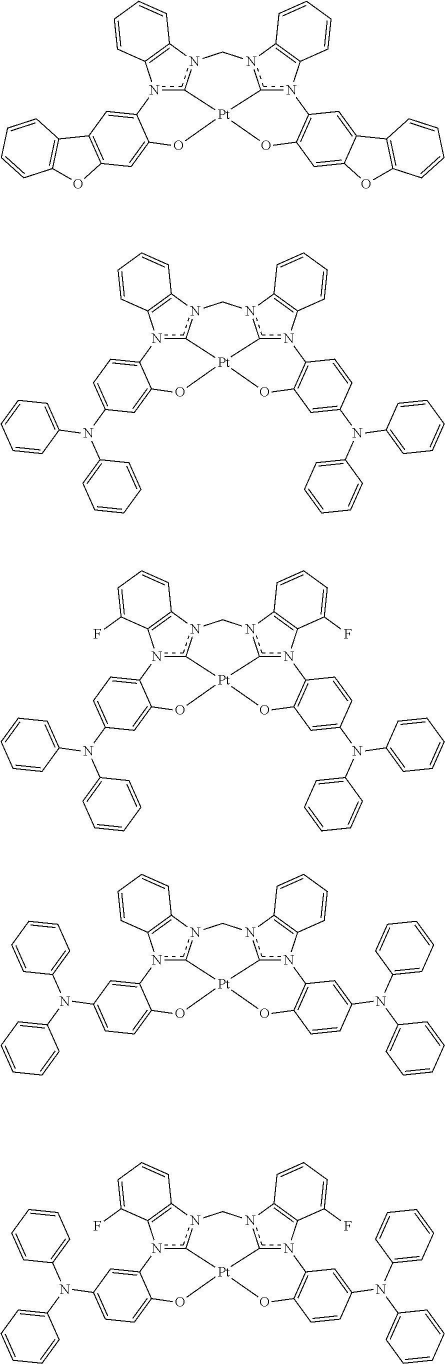

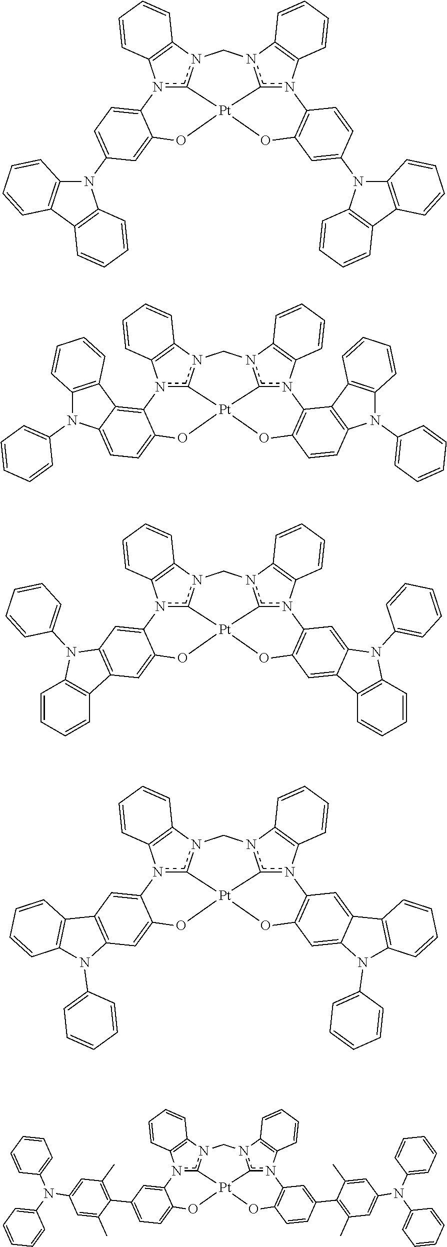

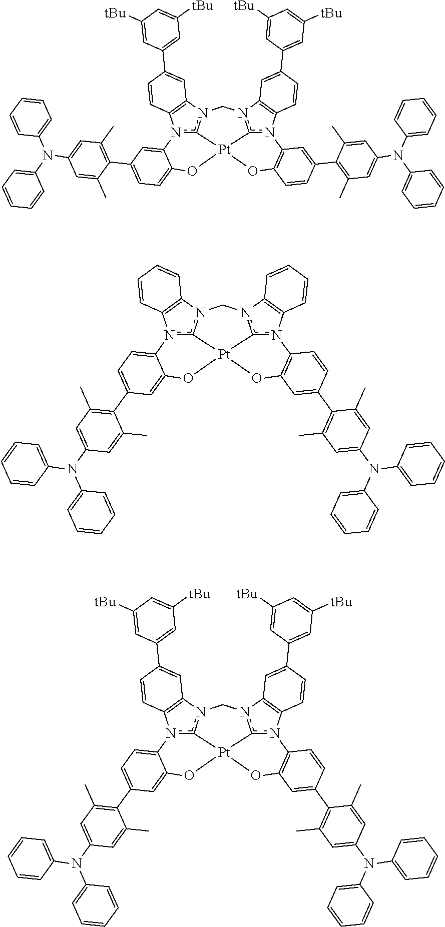

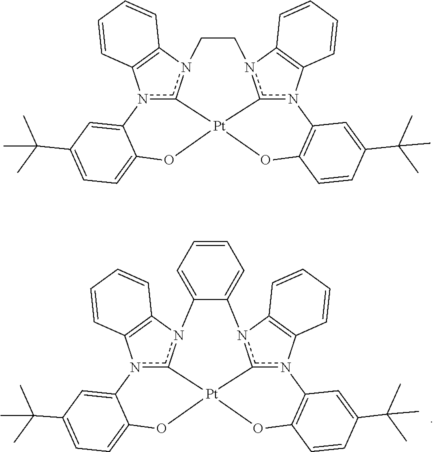

Typically, the platinum(II) complexes emit in the blue region with a maximum emission wavelength (λₘₐₓ) in a range from 420 nm to 490 nm, from 430 nm to 490 nm, from 440 nm to 490 nm, from 450 nm to 490 nm, from 460 nm to 490 nm, from 430 nm to 465 nm, or from 440 nm to 470 nm, such as from 441 nm to 454 nm.

In some forms, the platinum(II) complexes can have an emission quantum yield (Φₑₘ) of at least 30%, at least 35%, at least 45%, at least 50%, at least 60%, at least 70%, in a range from 30% to 90%, from 30% to 85%, from 30% to 80%, from 35% to 85%, from 35% to 80%, from 45% to 85%, from 45% to 80%, from 50% to 85%, or from 50% to 80%; an emission lifetime (τₑₘ) of ≤5.5 μs, ≤5 μs, ≤4 μs, ≤3 μs, ≤2 μs, ≤1 μs, in a range from 0.5 μs to 5 μs, from 1 μs to 5 μs, or from 2 μs to 5 μs, such as about 2.25 μs; and/or a radiative decay rate (kᵣ) of at least 1.0×10⁵ s⁻¹, at least 1.5×10⁵ s⁻¹, at least 2.0×10⁵ s⁻¹, in a range from 1.0×10⁵ s⁻¹ to 6.0×10⁵ s⁻¹, 1.0×10⁵ s⁻¹ to 5.0×10⁵ s⁻¹, 1.5×10⁵ s⁻¹ to 6.0×10⁵ s⁻¹, from 1.5×10⁵ s⁻¹ to 5.0×10⁵ s⁻¹, from 2.0×10⁵ s⁻¹ to 6.0×10⁵ s⁻¹, from 2.0×10⁵ s⁻¹ to 5.0×10⁵ s⁻¹, from 1.0×10⁵ s⁻¹ to 4.0×10⁵ s⁻¹, from 1.5×10⁵ s⁻¹ to 4.0×10⁵ s⁻¹, from 2.0×10⁵ s-1 to 4.0×10⁵ s⁻¹, or from 3.0×10⁵ s⁻¹ to 6.0×10⁵ s⁻¹, such as about 3.4×10⁵ s⁻¹, measured in films, at room temperature.

Organic light-emitting components, such as organic light-emitting diode (“OLED”), containing one or more light-emitting layer or two or more light-emitting layers formed using the disclosed platinum(II) complexes are also disclosed. Generally, the total concentration of the platinum(II) complexes in the light-emitting layer or each light-emitting layer of the two or more light-emitting layers in the organic light-emitting component is up to 20 wt %, up to 10 wt %, at least 1 wt %, in a range from about 1 wt % to about 20 wt %, from about 1 wt % to about 10 wt %, from about 2 wt % to about 20 wt %, from about 2 wt % to about 15 wt %, or from about 2 wt % to about 10 wt %, such as about 2 wt %, about 6 wt %, or about 10 wt %. These organic light-emitting components can emit light in the blue region, with high performance at room temperature.

For examples, the organic light-emitting component can emit light in the blue region with a maximum brightness (L) of at least 3000 cd m⁻², at least 4000 cd m⁻², at least 5000 cd m⁻², at least 6000 cd m⁻², at least 8000 cd m⁻², in a range from 3000 cd m⁻² to 50000 cd m⁻², from 3000 cd m⁻² to 40000 cd m⁻², from 3000 cd m⁻² to 30000 cd m⁻², from 3000 cd m⁻² to 25000 cd m⁻², or from 3000 cd m⁻² to 15000 cd m⁻²; a current efficiency (CE) at 1000 cd/m² of at least 20 cd A⁻¹, at least 25 cd/A, in a range from 20 cd/A to 50 cd/A, or from 20 cd/A to 45 cd/A; a power efficiency (PE) at 1000 cd/m² of at least 20 lm/W, in a range from 20 lm/W to 50 lm/W, or from 20 lm/W to 45 lm/W; and/or an external quantum efficiency (EQE) at 1000 cd/m² of at least 10%, at least 15%, in a range from 10% to 35%, from 10% to 30%, from 10% to 25%, from 15% to 35%, from 15% to 30%, from 15% to 25%, from 20% to 30%, or from 15% to 20%, such as about 20%.

These high-performance organic blue light-emitting components containing the platinum(II) complexes disclosed herein can be used in a variety of devices, such as a stationary visual display unit, a mobile visual display unit, an illumination device, a wearable device, or a medical monitoring device.

### BRIEF DESCRIPTION OF THE DRAWINGS

FIG. 1 shows the TGA thermograms of Pt-ref1, Pt-4, Pt-7, and Pt-8.

FIGS. 2A-2C show the crystal structures of Pt-1 (FIG. 2A), Pt-4 (FIG. 2B), and Pt-ref1 (FIG. 2C).

FIG. 3A shows the emission spectra of Pt-1, Pt-2, Pt-3, and Pt-4 in PMMA films.

FIG. 3B shows the emission spectra of Pt-5, Pt-6, Pt-7, and Pt-8 in PMMA films.

FIGS. 4A-4D show the EL spectra (FIG. 4A) and performance characteristics of devices fabricated with Pt-4 with doping concentration of 2, 6 and 10 wt %. The performance characteristics of these devices include EQE (FIG. 4B), luminance (FIG. 4C), and current density (FIG. 4D). The device structure is: ITO/HAT-CN (5 nm)/TAPC (30 nm)/TCTA (5 nm)/CzSi (3 nm)/Pt-4: CzSi: BCPO (18 nm)/TSPO1 (30 nm)/LiF (1.2 nm)/Al (100 nm).

FIGS. 5A-5D show the EL spectra (FIG. 5A) and performance characteristics of devices fabricated with Pt-8 with doping concentration of 2, 6 and 10 wt %. The performance characteristics of these devices include EQE (FIG. 5B), luminance (FIG. 5C), and current density (FIG. 5D). The device structure is: ITO/HAT-CN (5 nm)/TAPC (30 nm)/TCTA (5 nm)/CzSi (3 nm)/Pt-8: CzSi: BCPO (32 nm)/TSPO1 (30 nm)/LiF (1.2 nm)/Al (100 nm).

FIG. 6 shows a non-limiting example of an organic light-emitting diode device, 100, having a multilayer architecture.

FIG. 7 shows the emission spectra of Pt-9, Pt-10, and Pt-11 in PMMA films.

FIGS. 8A-8D show the EL spectra (FIG. 8A) and performance characteristics of devices fabricated with Pt-9 with doping concentration of 10 and 15 wt %. The performance characteristics of these devices include EQE (FIG. 8B), luminance (FIG. 8C), and current density (FIG. 8D). The device structure is: ITO/HAT-CN (5 nm)/TAPC (40 nm)/TCTA (7 nm)/CzSi (3 nm)/Pt-9: CzSi (20 nm)/TSPO1 (30 nm)/LiF (1.2 nm)/Al (100 nm).

### DETAILED DESCRIPTION OF THE INVENTION

### I. Definitions

It is to be understood that the disclosed compounds, compositions, and methods are not limited to specific synthetic methods, specific analytical techniques, or to particular reagents unless otherwise specified, and, as such, may vary. It is also to be understood that the terminology used herein is for the purpose of describing particular forms and embodiments only and is not intended to be limiting.

“Substituted,” as used herein, refers to all permissible substituents of the compounds or functional groups described herein. In the broadest sense, the permissible substituents include acyclic and cyclic, branched and unbranched, carbocyclic and heterocyclic, aromatic and nonaromatic substituents of organic compounds. Illustrative substituents include, but are not limited to, halogens, hydroxyl groups, or any other organic groupings containing any number of carbon atoms, preferably 1-14 carbon atoms, and optionally include one or more heteroatoms such as oxygen, sulfur, or nitrogen grouping in linear, branched, or cyclic structural formats. Representative substituents include a substituted or unsubstituted alkyl, a substituted or unsubstituted alkenyl, a substituted or unsubstituted alkynyl, a substituted or unsubstituted heterocyclyl, a substituted or unsubstituted phenyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a halogen, a hydroxyl, an alkoxy, a phenoxy, an aroxy, a silyl, a thiol, an alkylthio, a substituted alkylthio, a phenylthio, an arylthio, a cyano, an isocyano, a nitro, a substituted or unsubstituted carbonyl, a carboxyl, an amino, an amido, an oxo, a sulfinyl, a sulfonyl, a sulfonic acid, a phosphonium, a phosphanyl, a phosphoryl, a phosphonyl, an amino acid. Such a substituted or unsubstituted alkyl, a substituted or unsubstituted alkenyl, a substituted or unsubstituted alkynyl, a substituted or unsubstituted heterocyclyl, a substituted or unsubstituted phenyl, a substituted or unsubstituted aryl, a substituted or unsubstituted heteroaryl, a substituted or unsubstituted polyaryl, a substituted or unsubstituted polyheteroaryl, a substituted or unsubstituted aralkyl, a halogen, a hydroxyl, an alkoxy, a phenoxy, an aroxy, a silyl, a thiol, an alkylthio, a substituted alkylthio, a phenylthio, an arylthio, a cyano, an isocyano, a nitro, a substituted or unsubstituted carbonyl, a carboxyl, an amino, an amido, an oxo, a sulfinyl, a sulfonyl, a sulfonic acid, a phosphonium, a phosphanyl, a phosphoryl, a phosphonyl, and an amino acid can be further substituted.

Heteroatoms such as nitrogen may have hydrogen substituents and/or any permissible substituents of organic compounds described herein which satisfy the valences of the heteroatoms. It is understood that “substitution” or “substituted” includes the implicit proviso that such substitution is in accordance with permitted valence of the substituted atom and the substituent, and that the substitution results in a stable compound, i.e., a compound that does not spontaneously undergo transformation such as by rearrangement, cyclization, elimination, etc.

“Alkyl,” as used herein, refers to the radical of saturated aliphatic groups, including straight-chain alkyl groups, branched-chain alkyl, and cycloalkyl (alicyclic). In some forms, a straight chain or branched chain alkyl has 30 or fewer carbon atoms in its backbone (e.g., C₁-C₃₀ for straight chains, C₃-C₃₀ for branched chains), 20 or fewer, 15 or fewer, or 10 or fewer. Alkyl includes methyl, ethyl, n-propyl, isopropyl, n-butyl, isobutyl, t-butyl, pentyl, hexyl, heptyl, octyl, decyl, tetradecyl, hexadecyl, eicosyl, tetracosyl and the like. Likewise, a cycloalkyl is a non-aromatic carbon-based ring composed of at least three carbon atoms, such as a nonaromatic monocyclic or nonaromatic polycyclic ring containing 3-30 carbon atoms, 3-20 carbon atoms, or 3-10 carbon atoms in their ring structure, and have 5, 6 or 7 carbons in the ring structure. Cycloalkyls containing a polycyclic ring system can have two or more non-aromatic rings in which two or more carbons are common to two adjoining rings (i.e., “fused cycloalkyl rings”). Examples of cycloalkyl groups include, but are not limited to, cyclopropyl, cyclobutyl, cyclopentyl, cyclohexyl, cycloheptyl, cyclooctanyl, etc.

“Substituted alkyl” refers to alkyl moieties having one or more substituents replacing a hydrogen on one or more carbons of the hydrocarbon backbone. Such substituents can be any substituents described above, e.g., halogen (such as fluorine, chlorine, bromine, or iodine), hydroxyl, carbonyl (such as a carboxyl, alkoxycarbonyl, formyl, or an acyl), thiocarbonyl (such as a thioester, a thioacetate, or a thioformate), aryl, alkoxyl, aralkyl, phosphonium, phosphanyl, phosphonyl, phosphoryl, phosphate, phosphonate, a phosphinate, amino, amido, amidine, imine, cyano, nitro, azido, oxo, sulfhydryl, thiol, alkylthio, silyl, sulfinyl, sulfate, sulfonate, sulfamoyl, sulfonamido, sulfonyl, heterocyclyl, an aromatic or heteroaromatic moiety. —NRR′, wherein R and R′ are independently hydrogen, alkyl, or aryl, and wherein the nitrogen atom is optionally quaternized; —SR, wherein R is a phosphonyl, a sulfinyl, a silyl a hydrogen, an alkyl, or an aryl; —CN; —NO₂; —COOH;
carboxylate; —COR, —COOR, or —CON(R)₂, wherein R is hydrogen, alkyl, or aryl; imino, silyl, ether, haloalkyl (such as —CF₃, —CH₂—CF₃, —CCl₃); —CN; —NCOCOCH₂CH₂; —NCOCOCHCH; and —NCS; and combinations thereof.

It will be understood by those skilled in the art that the moieties substituted on the hydrocarbon chain can themselves be substituted, if appropriate. For instance, the substituents of a substituted alkyl may include halogen, hydroxy, nitro, thiols, amino, aralkyl, azido, imino, amido, phosphonium, phosphanyl, phosphoryl (including phosphonate and phosphinate), oxo, sulfonyl (including sulfate, sulfonamido, sulfamoyl and sulfonate), and silyl groups, as well as ethers, alkylthios, carbonyls (including ketones, aldehydes, carboxylates, and esters), haloalkyls, —CN and the like. Cycloalkyls can be substituted in the same manner.

Unless the number of carbons is otherwise specified, “lower alkyl” as used herein means an alkyl group, as defined above, but having from one to ten carbons, more preferably from one to six carbon atoms in its backbone structure. Likewise, “lower alkenyl” and “lower alkynyl” have similar chain lengths.

“Heteroalkyl,” as used herein, refers to straight or branched chain, or cyclic carbon-containing alkyl radicals, or combinations thereof, containing at least one heteroatom on the carbon backbone. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkyl group” is a cycloalkyl group as defined above where at least one of the carbon atoms of the ring is substituted with a heteroatom such as, but not limited to, nitrogen, oxygen, sulphur, or phosphorus.

The term “alkenyl” as used herein is a hydrocarbon group of from 2 to 24 carbon atoms and structural formula containing at least one carbon-carbon double bond. Alkenyl groups include straight-chain alkenyl groups, branched-chain alkenyl, and cycloalkenyl. A cycloalkenyl is a non-aromatic carbon-based ring composed of at least three carbon atoms and at least one carbon-carbon double bond, such as a nonaromatic monocyclic or nonaromatic polycyclic ring containing 3-30 carbon atoms and at least one carbon-carbon double bond, 3-20 carbon atoms and at least one carbon-carbon double bond, or 3-10 carbon atoms and at least one carbon-carbon double bond in their ring structure, and have 5, 6 or 7 carbons and at least one carbon-carbon double bond in the ring structure. Cycloalkenyls containing a polycyclic ring system can have two or more non-aromatic rings in which two or more carbons are common to two adjoining rings (i.e., “fused cycloalkenyl rings”) and contain at least one carbon-carbon double bond. Asymmetric structures such as (AB)C=C(C′D) are intended to include both the E and Z isomers. This may be presumed in structural formulae herein wherein an asymmetric alkene is present, or it may be explicitly indicated by the bond symbol C. The term “alkenyl” as used throughout the specification, examples, and claims is intended to include both “unsubstituted alkenyls” and “substituted alkenyls,” the latter of which refers to alkenyl moieties having one or more substituents replacing a hydrogen on one or more carbons of the hydrocarbon backbone. The term “alkenyl” also includes “heteroalkenyl.”

The term “substituted alkenyl” refers to alkenyl moieties having one or more substituents replacing one or more hydrogen atoms on one or more carbons of the hydrocarbon backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, oxo, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

“Heteroalkenyl,” as used herein, refers to straight or branched chain, or cyclic carbon-containing alkenyl radicals, or combinations thereof, containing at least one heteroatom. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkenyl group” is a cycloalkenyl group where at least one of the carbon atoms of the ring is substituted with a heteroatom such as, but not limited to, nitrogen, oxygen, sulphur, or phosphorus.

The term “alkynyl group” as used herein is a hydrocarbon group of 2 to 24 carbon atoms and a structural formula containing at least one carbon-carbon triple bond. Alkynyl groups include straight-chain alkynyl groups, branched-chain alkynyl, and cycloalkynyl. A cycloalkynyl is a non-aromatic carbon-based ring composed of at least three carbon atoms and at least one carbon-carbon triple bond, such as a nonaromatic monocyclic or nonaromatic polycyclic ring containing 3-30 carbon atoms and at least one carbon-carbon triple bond, 3-20 carbon atoms and at least one carbon-carbon triple bond, or 3-10 carbon atoms and at least one carbon-carbon triple bond in their ring structure, and have 5, 6 or 7 carbons and at least one carbon-carbon triple bond in the ring structure. Cycloalkynyls containing a polycyclic ring system can have two or more non-aromatic rings in which two or more carbons are common to two adjoining rings (i.e., “fused cycloalkynyl rings”) and contain at least one carbon-carbon triple bond. Asymmetric structures such as (AB)C≡C(C″D) are intended to include both the E and Z isomers. This may be presumed in structural formulae herein wherein an asymmetric alkyne is present, or it may be explicitly indicated by the bond symbol C. The term “alkynyl” as used throughout the specification, examples, and claims is intended to include both “unsubstituted alkynyls” and “substituted alkynyls,” the latter of which refers to alkynyl moieties having one or more substituents replacing a hydrogen on one or more carbons of the hydrocarbon backbone. The term “alkynyl” also includes “heteroalkynyl.”

The term “substituted alkynyl” refers to alkynyl moieties having one or more substituents replacing one or more hydrogen atoms on one or more carbons of the hydrocarbon backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

“Heteroalkynyl,” as used herein, refers to straight or branched chain, or cyclic carbon-containing alkynyl radicals, or combinations thereof, containing at least one heteroatom. Suitable heteroatoms include, but are not limited to, O, N, Si, P and S, wherein the nitrogen, phosphorous and sulfur atoms are optionally oxidized, and the nitrogen heteroatom is optionally quaternized. For example, the term “heterocycloalkynyl group” is a cycloalkynyl group where at least one of the carbon atoms of the ring is substituted with a heteroatom such as, but not limited to, nitrogen, oxygen, sulphur, or phosphorus.

“Aryl,” as used herein, refers to C₄-C₂₆-membered aromatic rings or fused ring systems containing one aromatic ring and optionally one or more non-aromatic rings. Examples of aryl groups are benzene, tetralin, indane, etc.

The term “substituted aryl” refers to an aryl group, wherein one or more hydrogen atoms on one or more aromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfoxide, sulfonamido, sulfonyl, heterocyclyl, alkylaryl, haloalkyl (such as CF₃, —CH₂—CF₃, —CCl₃), —CN, aryl, heteroaryl, and combinations thereof.

“Heterocyclo” and “heterocyclyl” are used interchangeably, and refer to a cyclic radical attached via a ring carbon or nitrogen atom of a monocyclic ring or polycyclic ring system containing 3-30 ring atoms, 3-20 ring atoms, 3-10 ring atoms, or 5-6 ring atoms, where the polycyclic ring system contains one or more non-aromatic rings and optionally one or more aromatic rings, where at least one non-aromatic ring contains carbon and one to four heteroatoms each selected from the group consisting of non-peroxide oxygen, sulfur, and N(Y) wherein Y is absent or is H, O, C₁-C₁₀ alkyl, phenyl or benzyl, and optionally containing 1-3 double bonds and optionally substituted with one or more substituents. Heterocyclyl are distinguished from heteroaryl by definition. Heterocycles can be a heterocycloalkyl, a heterocycloalkenyl, a heterocycloalkynyl, etc, such as piperazinyl, piperidinyl, piperidonyl, 4-piperidonyl, dihydrofuro[2,3-b]tetrahydrofuran, morpholinyl, piperazinyl, piperidinyl, piperidonyl, 4-piperidonyl, piperonyl, pyranyl, 2H-pyrrolyl, 4H-quinolizinyl, quinuclidinyl, tetrahydrofuranyl, 6H-1,2,5-thiadiazinyl. Heterocyclic groups can optionally be substituted with one or more substituents as defined above for alkyl and aryl.

The term “heteroaryl” refers to C₃-C₂₆-membered aromatic rings or fused ring systems containing one aromatic ring and optionally one or more non-aromatic rings, in which one or more carbon atoms on the aromatic ring structure have been substituted with a heteroatom. Suitable heteroatoms include, but are not limited to, oxygen, sulfur, and nitrogen. Examples of heteroaryl groups pyrrole, furan, thiophene, imidazole, oxazole, thiazole, triazole, tetrazole, pyrazole, pyridine, pyrazine, pyridazine and pyrimidine, and the like. Examples of heteroaryl rings include, but are not limited to, benzimidazolyl, benzofuranyl, benzothiofuranyl, benzothiophenyl, benzoxazolyl, benzoxazolinyl, benzthiazolyl, benztriazolyl, benztetrazolyl, benzisoxazolyl, benzisothiazolyl, benzimidazolinyl, carbazolyl, 4aH-carbazolyl, carbolinyl, chromanyl, chromenyl, cinnolinyl, decahydroquinolinyl, 2H,6H-1,5,2-dithiazinyl, furanyl, furazanyl, imidazolidinyl, imidazolinyl, imidazolyl, 1H-indazolyl, indolenyl, indolinyl, indolizinyl, indolyl, 3H-indolyl, isatinoyl, isobenzofuranyl, isochromanyl, isoindazolyl, isoindolinyl, isoindolyl, isoquinolinyl, isothiazolyl, isoxazolyl, methylenedioxyphenyl, naphthyridinyl, octahydroisoquinolinyl, 1,2,3-oxadiazolyl, 1,2,4-oxadiazolyl, 1,2,5-oxadiazolyl, 1,3,4-oxadiazolyl, oxazolidinyl, oxazolyl, oxindolyl, pyrimidinyl, phenanthridinyl, phenanthrolinyl, phenazinyl, phenothiazinyl, phenoxathinyl, phenoxazinyl, phthalazinyl, pteridinyl, purinyl, pyrazinyl, pyrazolidinyl, pyrazolinyl, pyrazolyl, pyridazinyl, pyridooxazole, pyridoimidazole, pyridothiazole, pyridinyl, pyridyl, pyrimidinyl, pyrrolidinyl, pyrrolinyl, pyrrolyl, quinazolinyl, quinolinyl, quinoxalinyl, tetrahydroisoquinolinyl, tetrahydroquinolinyl, tetrazolyl, 1,2,3-thiadiazolyl, 1,2,4-thiadiazolyl, 1,2,5-thiadiazolyl, 1,3,4-thiadiazolyl, thianthrenyl, thiazolyl, thienyl, thienothiazolyl, thienooxazolyl, thienoimidazolyl, thiophenyl and xanthenyl. One or more of the rings can be substituted as defined below for “substituted heteroaryl.”

The term “substituted heteroaryl” refers to a heteroaryl group in which one or more hydrogen atoms on one or more heteroaromatic rings are substituted with one or more substituents including, but not limited to, halogen, azide, alkyl, aralkyl, alkenyl, alkynyl, cycloalkyl, hydroxyl, alkoxy, carbonyl (such as a ketone, aldehyde, carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, imino, alkylthio, sulfate, sulfonate, sulfamoyl, sulfoxide, sulfonamido, sulfonyl, heterocyclyl, alkylaryl, haloalkyl (such as CF₃, —CH₂—CF₃, —CCl₃), —CN, aryl, heteroaryl, and combinations thereof.

The term “polyaryl” refers to a fused ring system that includes two or more aromatic rings and optionally one or more non-aromatic rings. Examples of polyaryl groups are naphthalene, anthracene, phenanthrene, chrysene, pyrene, corannulene, coronene, etc. When a fused ring system containing two or more aromatic rings and optionally one or more non-aromatic rings, in which one or more carbon atoms on two or more aromatic ring structures have been substituted with a heteroatom, the fused ring system can be referred to as a “polyheteroaryl”. When a fused ring system containing two or more aromatic rings and optionally one or more non-aromatic rings, in which one or more carbon atoms in the fused ring system is substituted with a heteroatom it can be referred to as a “heteropolyaryl.”

The term “substituted polyaryl” refers to a polyaryl in which one or more of the aryls are substituted, with one or more substituents including, but not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (or quarternized amino), amido, amidine, imine, cyano, nitro, azido, sulfhydryl, alkylthio, sulfate, sulfonate, sulfamoyl, sulfoxide, sulfonamido, sulfonyl, heterocyclyl, alkylaryl, haloalkyl, —CN, aryl, heteroaryl, and combinations thereof. When a polyheteroaryl is involved, the chemical moiety can be referred to as a “substituted polyheteroaryl.”

The term “cyclic,” “cyclic ring” or “cyclic group” refers to a substituted or unsubstituted monocyclic ring or a substituted or unsubstituted polycyclic ring (such as those formed from single or fused ring systems), such as a substituted or unsubstituted cycloalkyl, a substituted or unsubstituted cycloalkenyl, a substituted or unsubstituted cycloalkynyl, or a substituted or unsubstituted heterocyclyl, that have from three to 30 carbon atoms, as geometric constraints permit. The substituted cycloalkyls, cycloalkenyls, cycloalkynyls, and heterocyclyls are substituted as defined above for the alkyls, alkenyls, alkynyls, and heterocyclyls, respectively.

The term “aralkyl” as used herein is an aryl group or a heteroaryl group having an alkyl, alkynyl, or alkenyl group as defined above attached to the aromatic group, such as an aryl, a heteroaryl, a polyaryl, or a polyheteroaryl. An example of an aralkyl group is a benzyl group.

The terms “alkoxyl” or “alkoxy,” “aroxy” or “aryloxy,” generally describe compounds represented by the formula —OR, wherein R^{v} includes, but is not limited to, a substituted or unsubstituted alkyl, a substituted or unsubstituted alkenyl, a substituted or unsubstituted alkynyl, a substituted or unsubstituted cycloalkyl, a substituted or unsubstituted heterocyclyl, a substituted or unsubstituted cycloalkenyl, a substituted or unsubstituted heterocycloalkenyl, a substituted or unsubstituted aryl, a substituted or unsubstituted heteroaryl, a substituted or unsubstituted polyaryl, a substituted or unsubstituted polyheteroaryl, a substituted or unsubstituted arylalkyl, a substituted or unsubstituted heteroalkyl, a substituted or unsubstituted alkylaryl, a substituted or unsubstituted alkylheteroaryl, a substituted or unsubstituted aralkyl, a substituted or unsubstituted carbonyl, a phosphonium, a phosphanyl, a phosphonyl, a sulfinyl, a silyl, a thiol, an amido, and an amino. Exemplary alkoxyl groups include methoxy, ethoxy, propyloxy, tert-butoxy and the like. A “lower alkoxy” group is an alkoxy group containing from one to six carbon atoms. An “ether” is two functional groups covalently linked by an oxygen as defined below. Accordingly, the substituent of an alkyl that renders that alkyl an ether is or resembles an alkoxyl, such as can be represented by one of —O-alkyl, —O-alkenyl, —O-alkynyl, —O-arakyl, —O-aryl, —O-heteroaryl, -O-polyaryl, -O-polyheteroaryl, —O-heterocyclyl, etc.

The term “substituted alkoxy” refers to an alkoxy group having one or more substituents replacing one or more hydrogen atoms on one or more carbons of the alkoxy backbone. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, oxo, sulfate, sulfonate, sulfamoyl, sulfonamido, sulfonyl, heterocyclyl, alkylaryl, haloalkyl, —CN, aryl, heteroaryl, and combinations thereof.

The term “ether” as used herein is represented by the formula A²OA¹, where A² and A¹ can be, independently, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl, a substituted or unsubstituted polyaryl, a substituted or unsubstituted polyheteroaryl, a phosphonium, a phosphanyl, a phosphonyl, a sulfinyl, a silyl, a thiol, a substituted or unsubstituted carbonyl, an alkoxy, an amido, or an amino, described above.

The term “polyether” as used herein is represented by the formula:

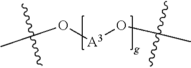

where A³ can be, independently, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl, a substituted or unsubstituted polyaryl, a substituted or unsubstituted polyheteroaryl, a phosphonium, a phosphanyl, a substituted or unsubstituted carbonyl, an alkoxy, an amido, or an amino, described above; g can be a positive integer from 1 to 30.

The term “phenoxy” is art recognized and refers to a compound of the formula —OR^{v} wherein R^{v} is C₆H₅(i.e., —O—C₆H₅). One of skill in the art recognizes that a phenoxy is a species of the aroxy genus.

The term “substituted phenoxy” refers to a phenoxy group, as defined above, having one or more substituents replacing one or more hydrogen atoms on one or more carbons of the phenyl ring. Such substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof.

The terms “aroxy” and “aryloxy,” as used interchangeably herein, are represented by —O-aryl or —O-heteroaryl, wherein aryl and heteroaryl are as defined herein.

The terms “substituted aroxy” and “substituted aryloxy,” as used interchangeably herein, represent —O-aryl or —O-heteroaryl, having one or more substituents replacing one or more hydrogen atoms on one or more ring atoms of the aryl and heteroaryl, as defined herein. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

The term “amino” as used herein includes the group

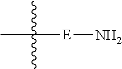

(primary amino),

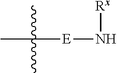

(secondary amino),

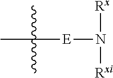

(tertiary amino), and

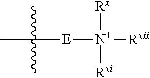

(quaternary amino),
wherein, E is absent, or E is substituted or unsubstituted alkyl, substituted or unsubstituted alkenyl, substituted or unsubstituted alkynyl, substituted or unsubstituted aralkyl, substituted or unsubstituted aryl, substituted or unsubstituted heteroaryl, a substituted or unsubstituted polyaryl, a substituted or unsubstituted polyheteroaryl, substituted or unsubstituted heterocyclyl, wherein independently of E, R^{x}, R^{xi}, and R^{xii} each independently represent a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. The term “quaternary amino” also includes the groups where the nitrogen, R^{x}, R^{xi}, and R^{xii} with the N⁺ to which they are attached complete a heterocyclyl or heteroaryl having from 3 to 14 atoms in the ring structure. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The terms “amide” or “amido” are used interchangeably, refer to both “unsubstituted amido” and “substituted amido” and are represented by the general formula:

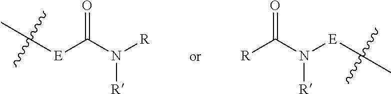

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted aryl, substituted or unsubstituted heteroaryl, a substituted or unsubstituted polyaryl, a substituted or unsubstituted polyheteroaryl, or a substituted or unsubstituted heterocyclyl, wherein independently of E, R and R′ each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R and R′ taken together with the N atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. In some forms, when E is oxygen, a carbamate is formed. It is understood by those of ordinary skill in the art, that the E groups listed above are divalent (e.g., methylene, ethane-1,2-diyl, ethene-1,2-diyl, 1,4-phenylene, cyclohexane-1,2-diyl).

“Carbonyl,” as used herein, is art-recognized and includes such moieties as can be represented by the general formula:

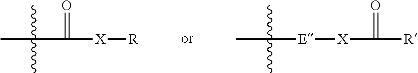

wherein X is a bond, or represents an oxygen or a sulfur, and R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R″, or a pharmaceutical acceptable salt; E″ is absent, or E″ is a substituted or unsubstituted alkyl, a substituted or unsubstituted alkenyl, a substituted or unsubstituted alkynyl, a substituted or unsubstituted aralkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl; R′ represents a hydrogen, a substituted or unsubstituted alkyl, a substituted or unsubstituted alkenyl, a substituted or unsubstituted alkynyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R″; R″ represents a hydroxyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphonium, phosphanyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, and combinations thereof. It is understood by those of ordinary skill in the art, that the E″ groups listed above are divalent (e.g., methylene, ethane-1,2-diyl, ethene-1,2-diyl, 1,4-phenylene, cyclohexane-1,2-diyl). Where X is oxygen and R is defined as above, the moiety is also referred to as a carboxyl group. When X is oxygen and R is hydrogen, the formula represents a “carboxylic acid.” Where X is oxygen and R′ is hydrogen, the formula represents a “formate.” Where X is oxygen and R or R′ is not hydrogen, the formula represents an “ester.” In general, where the oxygen atom of the above formula is replaced by a sulfur atom, the formula represents a “thiocarbonyl” group. Where X is sulfur and R or R′ is not hydrogen, the formula represents a “thioester.” Where X is sulfur and R is hydrogen, the formula represents a “thiocarboxylic acid.” Where X is sulfur and R′ is hydrogen, the formula represents a “thioformate.” Where X is a bond and R is not hydrogen, the above formula represents a “ketone.” Where X is a bond and R is hydrogen, the above formula represents an “aldehyde.”

The term “phosphanyl” is represented by the formula

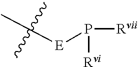

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted cycloalkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R^{vi} and R^{vii} each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi} and R^{vii} taken together with the P atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphonium” is represented by the formula

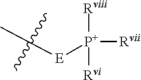

wherein, E is absent, or E is a substituted or unsubstituted alkyl, a substituted or unsubstituted alkenyl, a substituted or unsubstituted alkynyl, a substituted or unsubstituted aralkyl, a substituted or unsubstituted cycloalkyl, a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R^{vi}, R^{vii}, and R^{viii} each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi}, R^{vii}, and R^{viii} taken together with the P⁺ atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphonyl” is represented by the formula

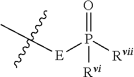

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, oxygen, alkoxy, aroxy, or substituted alkoxy or substituted aroxy, wherein, independently of E, R^{vi} and R^{vii} are independently a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a sulfinyl, a silyl, a thiol, an amido, an amino, or —(CH₂)ₘ—R′″, or R^{vi} and R^{vii} taken together with the P atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “phosphoryl” defines a phosphonyl in which E is absent, oxygen, alkoxy, aroxy, substituted alkoxy or substituted aroxy, as defined above, and independently of E, R^{vi} and R^{vii} are independently hydroxyl, alkoxy, aroxy, substituted alkoxy or substituted aroxy, as defined above. When E is oxygen, the phosphoryl cannot be attached to another chemical species, such as to form an oxygen-oxygen bond, or other unstable bonds, as understood by one of ordinary skill in the art. When E, R^{vi} and R^{vii} are substituted, the substituents include, but are not limited to, halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfinyl” is represented by the formula

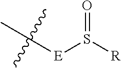

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted heterocyclyl, a substituted or unsubstituted polyaryl, a substituted or unsubstituted polyheteroaryl, wherein independently of E, R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, a phosphonyl, a silyl, a thiol, an amido, an amino, or —(CH₂)ₘ—R′″, or E and R taken together with the S atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonyl” is represented by the formula

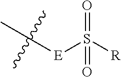

wherein E is absent, or E is a substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted arylalkyl, etc.), a substituted or unsubstituted aryl, a substituted or unsubstituted heteroaryl, a substituted or unsubstituted heterocyclyl, a substituted or unsubstituted polyaryl, a substituted or unsubstituted polyheteroaryl, wherein independently of E, R represents a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R′″, or E and R taken together with the S atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonic acid” refers to a sulfonyl, as defined above, wherein R is hydroxyl, and E is absent, or E is substituted or unsubstituted cycloalkyl, substituted or unsubstituted heterocyclyl, substituted or unsubstituted alkylaryl, substituted or unsubstituted arylalkyl, substituted or unsubstituted aryl, a substituted or unsubstituted polyaryl, a substituted or unsubstituted polyheteroaryl, or substituted or unsubstituted heteroaryl. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfate” refers to a sulfonyl, as defined above, wherein E is absent, oxygen, alkoxy, aroxy, substituted alkoxy or substituted aroxy, as defined above, and R is independently hydroxyl, alkoxy, aroxy, substituted alkoxy or substituted aroxy, as defined above. When E is oxygen, the sulfate cannot be attached to another chemical species, such as to form an oxygen-oxygen bond, or other unstable bonds, as understood by one of ordinary skill in the art. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfonate” refers to a sulfonyl, as defined above, wherein E is oxygen, alkoxy, aroxy, substituted alkoxy or substituted aroxy, as defined above, and R is independently hydrogen, substituted or unsubstituted alkyl, substituted or unsubstituted alkenyl, substituted or unsubstituted alkynyl, substituted or unsubstituted amino, substituted or unsubstituted cycloalkyl, substituted or unsubstituted heterocyclyl, substituted or unsubstituted aralkyl, substituted or unsubstituted alkylaryl, substituted or unsubstituted arylalkyl, substituted or unsubstituted aryl, substituted or unsubstituted heteroaryl, a substituted or unsubstituted polyaryl, a substituted or unsubstituted polyheteroaryl, —(CH₂)ₘ—R′″, R′″ represents a hydroxy group, substituted or unsubstituted carbonyl group, an aryl, a cycloalkyl ring, a cycloalkenyl ring, a heterocycle, an amido, an amino, or a polycycle; and m is zero or an integer ranging from 1 to 8. When E is oxygen, sulfonate cannot be attached to another chemical species, such as to form an oxygen-oxygen bond, or other unstable bonds, as understood by one of ordinary skill in the art. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “sulfamoyl” refers to a sulfonamide or sulfonamide represented by the formula

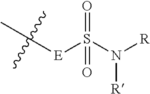

wherein E is absent, or E is substituted or unsubstituted alkyl, a substituted or unsubstituted alkenyl, a substituted or unsubstituted alkynyl, a substituted or unsubstituted aralkyl (e.g., a substituted or unsubstituted alkylaryl, a substituted or unsubstituted cycloalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, wherein independently of E, R and R′ each independently represent a hydrogen, a substituted or unsubstituted alkyl, a substituted or unsubstituted alkenyl, a substituted or unsubstituted alkynyl, a substituted or unsubstituted carbonyl, a substituted or unsubstituted heterocyclyl, a substituted or unsubstituted aralkyl (e.g. a substituted or unsubstituted alkylaryl, a substituted or unsubstituted arylalkyl, etc.), a substituted or unsubstituted aryl, a substituted or unsubstituted heteroaryl, a substituted or unsubstituted polyaryl, a substituted or unsubstituted polyheteroaryl, a substituted or unsubstituted heterocyclyl, a hydroxyl, an alkoxy, a phosphonium, a phosphanyl, an amido, an amino, or —(CH₂)ₘ—R′″, or R and R′ taken together with the N atom to which they are attached complete a heterocycle having from 3 to 14 atoms in the ring structure; R′″ represents a hydroxyl group, a substituted or unsubstituted carbonyl group, a substituted or unsubstituted aryl, a substituted or unsubstituted cycloalkyl, a substituted or unsubstituted cycloalkenyl, a substituted or unsubstituted heterocyclyl, a substituted or unsubstituted aryl, a substituted or unsubstituted heteroaryl, a substituted or unsubstituted polyaryl, a substituted or unsubstituted polyheteroaryl, an alkoxy, a phosphonium, a phosphanyl, an amido, or an amino; and m is zero or an integer ranging from 1 to 8. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof. It is understood by those of ordinary skill in the art, that the E groups listed above are divalent (e.g., methylene, ethane-1,2-diyl, ethene-1,2-diyl, 1,4-phenylene, cyclohexane-1,2-diyl).

The term “silyl group” as used herein is represented by the formula —SiRR′R,″ where R, R′, and R″ can be, independently, a hydrogen, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl (e.g. a substituted or unsubstituted alkylaryl, a substituted or unsubstituted arylalkyl, etc.), a substituted or unsubstituted polyaryl, a substituted or unsubstituted polyheteroaryl, a substituted or unsubstituted carbonyl, a phosphonium, a phosphanyl, a phosphonyl, a sulfinyl, a thiol, an amido, an amino, an alkoxy, or an oxo, described above. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

The terms “thiol” are used interchangeably and are represented by —SR, where R can be a hydrogen, a substituted or unsubstituted alkyl, a substituted or unsubstituted alkenyl, a substituted or unsubstituted alkynyl, a substituted or unsubstituted heterocyclyl, a substituted or unsubstituted aryl, a substituted or unsubstituted heteroaryl, a substituted or unsubstituted aralkyl (e.g. a substituted or unsubstituted alkylaryl, a substituted or unsubstituted arylalkyl, etc.), a substituted or unsubstituted polyaryl, a substituted or unsubstituted polyheteroaryl, a substituted or unsubstituted carbonyl, a phosphonium, a phosphanyl, an amido, an amino, an alkoxy, an oxo, a phosphonyl, a sulfinyl, or a silyl, described above. Such substituents can be any substituents described above, e.g., halogen, azide, alkyl, aralkyl, alkenyl, alkynyl, cycloalkyl, hydroxyl, carbonyl (such as a carboxyl, alkoxycarbonyl, formyl, or an acyl), silyl, ether, ester, thiocarbonyl (such as a thioester, a thioacetate, or a thioformate), alkoxyl, phosphoryl, phosphate, phosphonate, phosphinate, amino (e.g. quarternized amino), amido, amidine, imine, cyano, nitro, azido, sulfhydryl, alkylthio, sulfate, sulfonate, sulfamoyl, sulfonamido, sulfonyl, heterocyclyl, alkylaryl, haloalkyl, —CN, aryl, heteroaryl, polyaryl, polyheteroaryl, and combinations thereof.

The disclosed compounds and substituent groups, can, independently, possess two or more of the groups listed above. For example, if the compound or substituent group is a straight chain alkyl group, one of the hydrogen atoms of the alkyl group can be substituted with a hydroxyl group, an alkoxy group, etc. Depending upon the groups that are selected, a first group can be incorporated within second group or, alternatively, the first group can be pendant (i.e., attached) to the second group. For example, with the phrase “an alkyl group comprising an ester group,” the ester group can be incorporated within the backbone of the alkyl group. Alternatively, the ester can be attached to the backbone of the alkyl group. The nature of the group(s) that is (are) selected will determine if the first group is embedded or attached to the second group.

The compounds and substituents can be substituted, independently, with the substituents described above in the definition of “substituted.”

The numerical ranges disclose individually each possible number that such a range could reasonably encompass, as well as any sub-ranges and combinations of sub-ranges encompassed therein. For example, in a given range carbon range of C₃-C₉, the range also discloses C₃, C₄, C₅, C₆, C₇, Cs, and C₉, as well as any subrange between these numbers (for example, C₄-C₆), and any possible combination of ranges possible between these values. In yet another example, a given temperature range may be from about 25° C. to 30° C., where the range also discloses temperatures that can be selected independently from about 25, 26, 27, 28, 29, and 30° C., as well as any range between these numbers (for example, 26 to 28° C.), and any possible combination of ranges between these values.

Use of the term “about” is intended to describe values either above or below the stated value, which the term “about” modifies, to be within a range of approximately +/−10%. When the term “about” is used before a range of numbers (i.e., about 1-5) or before a series of numbers (i.e., about 1, 2, 3, 4, etc.) it is intended to modify both ends of the range of numbers and/or each of the numbers recited in the entire series, unless specified otherwise.

The disclosed compounds and substituent groups, can, independently, possess two or more of the groups listed above. For example, if the compound or substituent group is a straight chain alkyl group, one of the hydrogen atoms of the alkyl group can be substituted with a hydroxyl group, an alkoxy group, etc. Depending upon the groups that are selected, a first group can be incorporated within second group or, alternatively, the first group can be pendant (i.e., attached) to the second group. For example, with the phrase “an alkyl group comprising an ester group,” the ester group can be incorporated within the backbone of the alkyl group. Alternatively, the ester can be attached to the backbone of the alkyl group. The nature of the group(s) that is (are) selected will determine if the first group is embedded or attached to the second group.

The compounds and substituents can be substituted with, independently, with the substituents described above in the definition of “substituted.”

### II. Compositions

Described are a class of platinum(II) complexes (also referred to herein as Pt(II) complexes) that can emit in the blue regions with high efficiency. The Pt(II) complexes contain platinum(II) atoms complexed by ligands containing benzimidazole based NHC and phenolate moieties. In some forms, the phenolate moiety of the ligands contains one or more bulky substitutions, such as bulky phenyl groups, for example, 3,5-di-tertbutyl-phenyl (ditBuPh) and 2,6-dimethyl-phenyl (diMePh). The structure of the disclosed Pt(II) complexes allows for tremendous increment in the emission quantum yield and radiative decay rate constant, compared to the previously reported imidazole-based Pt(II)-O\hat{ }C*\hat{ }C*\hat{ }O complexes. For example, the Pt(II) complexes emit in blue spectral regions (e.g., at an emission maxima (λₘₐₓ) at 420 nm-490 nm, such as 441-454 nm) with a high emission quantum yield (i.e. Φₑₘ≥30%, such as from 30% to 90%, from 30% to 85%, or from 30% to 80%), a short emission lifetime (i.e. τₑₘ or τ≤5.5 μs or ≤5 μs and down to about 2 μs, such as about 2.25 μs), and/or a fast radiative decay rate (i.e. kᵣ>1.0×10⁵ s⁻¹ and up to about 6.0×10⁵ s⁻¹, such as about 3.4×10⁵ s⁻¹), measured in a thin film at room temperature. Without being bound to any theories, the improvement in the emission properties of the Pt(II) complexes may be ascribed to the geometry in these metal complexes (e.g., a reduced planarity and changed orientation between the NHC and the phenolate ring) and the extended π-conjugation of acceptor units.

Organic light-emitting components, such as light-emitting diodes (OLEDs), containing the platinum(II) blue emitters disclosed herein are also described. The Examples below demonstrated that doped OLEDs containing exemplary platinum(II) emitters disclosed herein show electroluminescence in the blue region (λₘₐₓ at about 420-490 nm, such as 470-480 nm) with an external quantum efficiencies (EQE) of at least 10%, at 1000 cd m⁻², such as 10-25%, at 1000 cd m⁻², e.g., about 20% at 1000 cd m⁻².

### A. Platinum(II) Complexes

In some forms, the disclosed platinum(II) complexes can have the structure of Formula I:

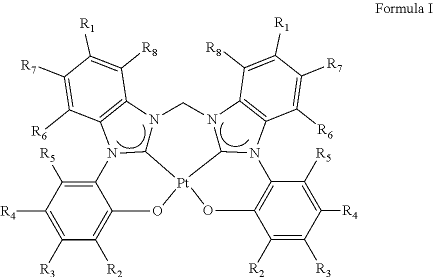

wherein: (i) each occurrence of R₁-R₈ can be independently hydrogen, a halide (e.g., fluoride, chloride, bromide, iodide, etc.), hydroxyl, amino, amido, thiol, cyano, nitro, alkoxy, carbonyl, a substituted or unsubstituted C₁-C₁₂ alkyl, a substituted or unsubstituted C₁-C₁₂ alkenyl, a substituted or unsubstituted C₁-C₁₂ alkynyl, a substituted or unsubstituted aryl (e.g., phenyl), a substituted or unsubstituted heteroaryl, a substituted or unsubstituted polyaryl, or a substituted or unsubstituted heteropolyaryl, or two neighboring R groups together with the carbon atoms to which they are attached can form a substituted or unsubstituted aryl, a substituted or unsubstituted heteroaryl, a substituted or unsubstituted polyaryl, or a substituted or unsubstituted heteropolyaryl; and (ii) the substituent(s), when present, can be independently an unsubstituted C₁-C₁₂ alkyl, an unsubstituted C₁-C₁₂ alkenyl, an unsubstituted C₁-C₁₂ alkynyl, an unsubstituted aryl (e.g., phenyl), a substituted aryl (e.g., phenyl) by unsubstituted aryl(s) (e.g., unsubstituted phenyls) and/or unsubstituted alkyl(s) (e.g., unsubstituted C₁-C₁₂ alkyl), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), an amino, or a halide.

In some forms, the platinum(II) complexes can have the structure of Formula II:

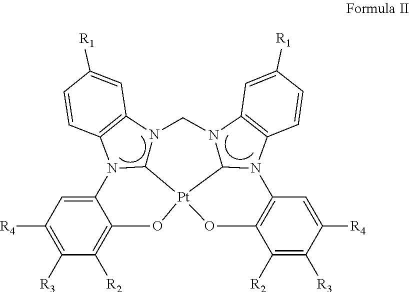

wherein R₁-R₄ and the substituents (when present) can be as defined for Formula I.

In some forms, the platinum(II) complexes can have a structure:

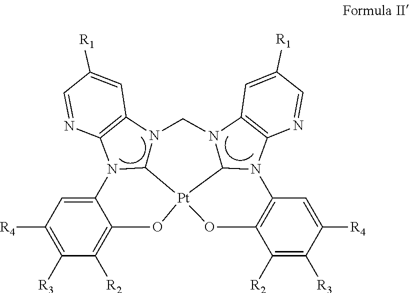

wherein R₁-R₄ can be as defined above for Formula I.

In some forms, the platinum(II) complexes can have the structure of Formula III:

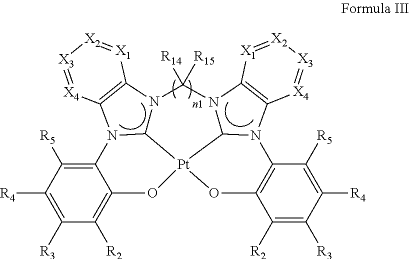

wherein R₂-R₅ and the substituents (when present) can be as defined for Formula I; each occurrence of X₁-X₄ is independently CR₁₆ or nitrogen and R₁₆ can be as defined for R₁-R₈ of Formula I; n1 is an integer from 1 to 6, from 1 to 5, from 1 to 4, from 1 to 3, or 1 or 2; R₁₄ and R₁₅ can be independently hydrogen, a substituted or unsubstituted C₁-C₁₂ alkyl, a substituted or unsubstituted C₁-C₁₂ alkenyl, or a substituted or unsubstituted C₁-C₁₂ alkynyl, or R₁₄ and R₁₅ of two neighboring carbon atoms, together with the carbon atoms to which they are attached, can form a substituted or unsubstituted aryl, a substituted or unsubstituted heteroaryl, a substituted or unsubstituted polyaryl, or a substituted or unsubstituted heteropolyaryl.

In some forms, nl can be 1 and R₁₄ and R₁₅ can be hydrogen. In some forms, nl can be 2, and R₁₄ and R₁₅ of two neighboring carbon atoms can be hydrogen or together with the carbon atoms to which they are attached can form a substituted or unsubstituted aryl, such as an unsubstituted aryl, for example, an unsubstituted phenyl.

In some forms, X₁ and/or X₄ can be nitrogen and X₂ and X₃ can be CR₁₆. In some forms, X₁ can be nitrogen and X₂-X₄ can be CR₁₆. In some forms, X₄ can be nitrogen and X₁-X₃ can be CR₁₆. In some forms, X₁-X₄ can be CR₁₆. In some forms, R₁₆ can be hydrogen, halide, a substituted or unsubstituted C₁-C₁₂ alkyl, or a substituted or unsubstituted aryl, where the substituent(s), when present, can be independently an unsubstituted C₁-C₁₂ alkyl, an unsubstituted aryl, a substituted aryl by unsubstituted aryl(s) or unsubstituted alkyl(s), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), an amino, or halide.

In some forms, X₁-X₃ can be CR₁₆ and X₄ can be independently nitrogen or CR₁₆, R₁₆ can be hydrogen, a halide, an unsubstituted C₁-C₁₂ alkyl (e.g., an unsubstituted C₁-C₆ alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or

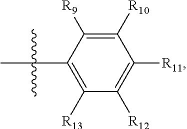

and R₉-R₁₃ can be independently hydrogen or an unsubstituted C₁-C₁₂ alkyl (e.g., methyl, ethyl, n-propyl, isopropyl, n-butyl, isobutyl, tert-butyl, etc.).

In some forms, for any of the formulae described herein, R₂-R₅ can be hydrogen, halide, amino, a substituted or unsubstituted C₁-C₁₂ alkyl, a substituted or unsubstituted aryl, a substituted or unsubstituted heteroaryl, a substituted or unsubstituted polyaryl, or a substituted or unsubstituted heteropolyaryl, or two neighboring R groups (such as R₂ and R₃, R₃ and R₄, or R₄ and R₅) together with the carbon atoms to which they are attached can form a substituted or unsubstituted aryl, a substituted or unsubstituted heteroaryl, a substituted or unsubstituted polyaryl, or a substituted or unsubstituted heteropolyaryl; and the substituent(s), when present, can be independently an unsubstituted C₁-C₁₂ alkyl, an unsubstituted aryl, a substituted aryl by unsubstituted aryl(s) and/or unsubstituted alkyl(s), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), an amino, or a halide.

In some forms, for any of the formulae described herein, n1, R₁₄, and R₁₅ can be in any form as defined herein; X₁ and X₄ can be nitrogen or CR₁₆; X₂ and X₃ can be CR₁₆; R₁₆ can be hydrogen, halide, an unsubstituted C₁-C₁₂ alkyl, an unsubstituted aryl, or an aryl substituted by unsubstituted C₁-C₁₂ alkyl(s); R₂-R₅ can be hydrogen, amino, an unsubstituted C₁-C₁₂ alkyl, a substituted or unsubstituted aryl, a substituted or unsubstituted heteroaryl, a substituted or unsubstituted polyaryl, or a substituted or unsubstituted heteropolyaryl, or two neighboring R groups (such as R₂ and R₃, R₃ and R₄, or R₄ and R₅) together with the carbon atoms to which they are attached can form a substituted or unsubstituted aryl, a substituted or unsubstituted heteroaryl, a substituted or unsubstituted polyaryl, or a substituted or unsubstituted heteropolyaryl; and the substituent(s), when present, can be independently an unsubstituted C₁-C₁₂ alkyl, an unsubstituted aryl (e.g., phenyl), a substituted aryl (e.g., phenyl) by unsubstituted aryl(s) (e.g., phenyls) and/or unsubstituted alkyl(s), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), or an amino.

In some forms, for any of the formulae described herein, each occurrence of R₁-R₈ can be independently hydrogen, a halide (e.g., fluoride, chloride, or bromide), hydroxyl, amino, amido, thiol, cyano, nitro, alkoxy, carbonyl, a substituted or unsubstituted C₁-C₁₂ alkyl, a substituted or unsubstituted C₁-C₁₂ alkenyl, a substituted or unsubstituted C₁-C₁₂ alkynyl, a substituted or unsubstituted aryl, a substituted or unsubstituted heteroaryl, a substituted or unsubstituted polyaryl, a substituted or unsubstituted polyaryl, or a substituted or unsubstituted heteropolyaryl; and the substituent(s), when present, can be independently an unsubstituted C₁-C₁₂ alkyl, an unsubstituted C₁-C₁₂ alkenyl, an unsubstituted C₁-C₁₂ alkynyl, or a halide.

In some forms, for any of the formulae described herein, each occurrence of R₁-R₈ can be independently hydrogen, a halide, a substituted or unsubstituted C₁-C₁₂ alkyl, a substituted or unsubstituted C₁-C₁₂ alkenyl, a substituted or unsubstituted C₁-C₁₂ alkynyl, a substituted or unsubstituted aryl, a substituted or unsubstituted heteroaryl, a substituted or unsubstituted polyaryl, a substituted or unsubstituted polyaryl, or a substituted or unsubstituted heteropolyaryl.

In some forms, for any of the formulae described herein, each occurrence of R₁-R₈ can be independently hydrogen, a halide, a substituted or unsubstituted C₁-C₁₂ alkyl, or a substituted or unsubstituted aryl.

In some forms, for any of the formulae described herein, each occurrence of R₁-R₈ can be independently hydrogen, a halide (e.g., fluoride, chloride, or bromide), an unsubstituted C₁-C₁₂ alkyl (e.g., an unsubstituted C₁-C₆ alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or

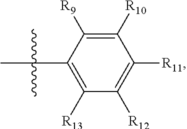

and wherein R₉-R₁₃ can be independently hydrogen, an unsubstituted C₁-C₁₂ alkyl (e.g., methyl, ethyl, n-propyl, isopropyl, n-butyl, isobutyl, tert-butyl, etc.), an unsubstituted phenyl, an unsubstituted heteropolyaryl, or an amino, such as hydrogen or an unsubstituted C₁-C₁₂ alkyl.

In some forms, for any of the formulae described herein, R₉-R₁₃ can be independently hydrogen or an unsubstituted C₁-C₆ alkyl (e.g., methyl, ethyl, n-propyl, isopropyl, n-butyl, isobutyl, tert-butyl, etc.) and R₉, R₁₁, and R₁₃ can be hydrogen.

In some forms, R₉-R₁₃ can be independently hydrogen or an unsubstituted C₁-C₆ alkyl (e.g., methyl, ethyl, n-propyl, isopropyl, n-butyl, isobutyl, tert-butyl, etc.). In some forms, R₉ and R₁₃ can be independently hydrogen or an unsubstituted C₁-C₆ alkyl (e.g., methyl, ethyl, n-propyl, isopropyl, n-butyl, isobutyl, tert-butyl, etc.) and R₁₀-R₁₂ can be hydrogen. In some forms, R₁₀ and R₁₂ can be independently hydrogen or an unsubstituted C₁-C₆ alkyl (e.g., methyl, ethyl, n-propyl, isopropyl, n-butyl, isobutyl, tert-butyl, etc.) and R₉, Ru, and R₁₃ can be hydrogen.

In some forms, for any of the formulae described herein, the substituted or unsubstituted aryl (as a R group and/or a substituent of a R group) can be a substituted or unsubstituted phenyl, such as

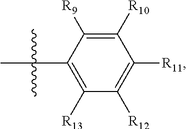

where R₉-R₁₃ can be independently hydrogen, an unsubstituted C₁-C₁₂ alkyl, an unsubstituted phenyl, an unsubstituted heteropolyaryl, or an amino.

In some forms, for any of the formulae described herein, the substituted or unsubstituted heteropolyaryl (as a R group or a substituent of a R group) can be

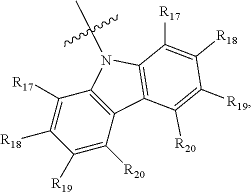

and each occurrence of R₁₇-R₂₀ can be hydrogen, an unsubstituted C₁-C₁₂ alkyl, an unsubstituted phenyl, or a substituted phenyl by one or more unsubstituted C₁-C₁₂ alkyls and/or unsubstituted phenyls.

In some forms, for any of the formulae described herein, R₂ and R₃ together, R₃ and R₄ together, or R₄ and R₅ together, can be

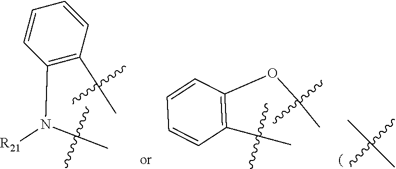

indicating point of attachment to the carbon atoms of the benzene ring); R₂₁ can be hydrogen, an unsubstituted C₁-C₁₂ alkyl, an unsubstituted phenyl, or a substituted phenyl by one or more unsubstituted C₁-C₁₂ alkyls and/or unsubstituted phenyls.

In some forms, for any of the formulae described herein, the amino (as a R group or a substituent of a R group) can be —NR₂₂R₂₃, where R₂₂ and R₂₃ can be independently hydrogen, an unsubstituted C₁-C₁₂ alkyl, an unsubstituted phenyl, or a substituted phenyl by one or more unsubstituted C₁-C₁₂ alkyls and/or unsubstituted phenyls.

In some forms, when the platinum(II) complex has the structure of Formula II or II′, R₁-R₄ can be independently hydrogen, a halide, an unsubstituted C₁-C₁₂ alkyl (e.g., an unsubstituted C₁-C₆ alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or

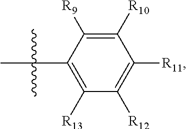

and wherein R₉-R₁₃ can be independently hydrogen, an unsubstituted C₁-C₁₂ alkyl (e.g., methyl, ethyl, n-propyl, isopropyl, n-butyl, isobutyl, tert-butyl, etc.), an unsubstituted phenyl, an unsubstituted heteropolyaryl, or an amino. In some forms, R₉-R₁₃ can be independently hydrogen or an unsubstituted C₁-C₆ alkyl (e.g., methyl, ethyl, n-propyl, isopropyl, n-butyl, isobutyl, tert-butyl, etc.). In some forms, R₉ and R₁₃ can be independently hydrogen or an unsubstituted C₁-C₆ alkyl (e.g., methyl, ethyl, n-propyl, isopropyl, n-butyl, isobutyl, tert-butyl, etc.) and Rio-R₁₂ can be hydrogen. In some forms, R₁₀ and R₁₂ can be independently hydrogen or an unsubstituted C₁-C₆ alkyl (e.g., methyl, ethyl, n-propyl, isopropyl, n-butyl, isobutyl, tert-butyl, etc.) and R₉, R₁₁, and R₁₃ can be hydrogen.

In some forms, when the platinum(II) complex has the structure of Formula II′, R₁-R₄ can be independently hydrogen, a halide, an unsubstituted C₁-C₁₂ alkyl (e.g., an unsubstituted C₁-C₆ alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or

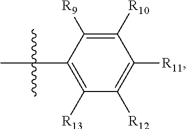

and wherein R₉-R₁₃ can be independently hydrogen, an unsubstituted C₁-C₁₂ alkyl (e.g., methyl, ethyl, n-propyl, isopropyl, n-butyl, isobutyl, tert-butyl, etc.), an unsubstituted phenyl, an unsubstituted heteropolyaryl, or an amino. Optionally, in these forms, at least one of R₁-R₄ is not hydrogen (e.g., R₄ can be a halide, an unsubstituted C₁-C₆ alkyl, or

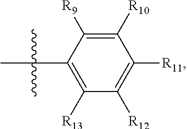

R₉-R₁₃ can be independently hydrogen or an unsubstituted C₁-C₆ alkyl).

For any of the formulae described herein, the alkyl (when present) can be a linear alkyl, a branched alkyl, or a cyclic alkyl (either monocyclic or polycyclic). The terms “cyclic alkyl” and “cycloalkyl” are used interchangeably herein. Exemplary alkyl include a linear C₁-C₁₂ alkyl, a branched C₄-C₁₂ alkyl, a cyclic C₃-C₁₂ alkyl, a linear C₁-C₁₀ alkyl, a branched C₄-C₁₀ alkyl, a cyclic C₃-C₁₀ alkyl, a linear C₁-C₈ alkyl, a branched C₄-C₈ alkyl, a cyclic C₃-C₈ alkyl, a linear C₁-C₆ alkyl, a branched C₄-C₆ alkyl, a cyclic C₃-C₆ alkyl, a linear C₁-C₄ alkyl, cyclic C₃-C₄ alkyl, such as a linear C₁-C₁₀, C₁-C₉, C₁-C₈, C₁-C₇, C₁-C₆, C₁-C₅, C₁-C₄, C₁-C₃, or C₁-C₂ alkyl group, a branched C₃-C₉, C₃-C₉, C₃-C₈, C₃-C₇, C₃-C₆, C₃-C₅, or C₃-C₄ alkyl group, or a cyclic C₃-C₉, C₃-C₉, C₃-C₈, C₃-C₇, C₃-C₆, C₃-C₅, or C₃-C₄ alkyl group. The cyclic alkyl can be a monocyclic or polycyclic alkyl, such as a C₄-C₁₂, C₄-C₁₀, C₄-C₉, C₄-C₈, C₄-C₇, C₄-C₆, or C₄-C₅ monocyclic or polycyclic alkyl group. In some forms, the alkyl can be a methyl, an ethyl, an isopropyl, a n-propyl, a tert-butyl, an isobutyl, or a n-butyl.

For any of the formulae described herein, the alkenyl (when present) can be a linear alkenyl, a branched alkenyl, or a cyclic alkenyl (either monocyclic or polycyclic). The terms “cyclic alkenyl” and “cycloalkenyl” are used interchangeably herein. Exemplary alkenyl include a linear C₂-C₁₂ alkenyl, a branched C₄-C₁₂ alkenyl, a cyclic C₃-C₁₂ alkenyl, a linear C₂-C₁₀ alkenyl, a branched C₄-C₁₀ alkenyl, a cyclic C₃-C₁₀ alkenyl, a linear C₂-C₈ alkenyl, a branched C₄-C₈ alkenyl, a cyclic C₃-C₈ alkenyl, a linear C₂-C₆ alkenyl, a branched C₄-C₆ alkenyl, a cyclic C₃-C₆ alkenyl, a linear C₂-C₄ alkenyl, cyclic C₃-C₄ alkenyl, such as a linear C₂-C₁₀, C₂-C₉, C₂-C₈, C₂-C₇, C₂-C₆, C₂-C₅, C₂-C₄, C₂-C₃ alkenyl group, a branched C₃-C₉, C₃-C₉, C₃-C₈, C₃-C₇, C₃-C₆, C₃-C₅, C₃-C₄ alkenyl group, or a cyclic C₃-C₉, C₃-C₉, C₃-C₈, C₃-C₇, C₃-C₆, C₃-C₅, C₃-C₄ alkenyl group. The cyclic alkenyl can be a monocyclic or polycyclic alkenyl, such as a C₄-C₁₂, C₄-C₁₀, C₄-C₉, C₄-C₈, C₄-C₇, C₄-C₆, or C₄-C₅ monocyclic or polycyclic alkenyl group.

For any of the formulae described herein, the alkynyl (when present) can be a linear alkynyl, a branched alkynyl, or a cyclic alkynyl (either monocyclic or polycyclic). The terms “cyclic alkynyl” and “cycloalkynyl” are used interchangeably herein. Exemplary alkynyl include a linear C₂-C₁₂ alkynyl, a branched C₄-C₁₂ alkynyl, a cyclic C₃-C₁₂ alkynyl, a linear C₂-C₁₀ alkynyl, a branched C₄-C₁₀ alkynyl, a cyclic C₃-C₁₀ alkynyl, a linear C₂-C₈ alkynyl, a branched C₄-C₈ alkynyl, a cyclic C₃-C₈ alkynyl, a linear C₂-C₆ alkynyl, a branched C₄-C₆ alkynyl, a cyclic C₃-C₆ alkynyl, a linear C₁-C₄ alkynyl, cyclic C₃-C₄ alkynyl, such as a linear C₂-C₁₀, C₂-C₉, C₂-C₈, C₂-C₇, C₂-C₆, C₂-C₅, C₂-C₄, C₂-C₃ alkynyl group, a branched C₃-C₉, C₃-C₉, C₃-C₈, C₃-C₇, C₃-C₆, C₃-C₅, C₃-C₄ alkynyl group, or a cyclic C₃-C₉, C₃-C₉, C₃-C₈, C₃-C₇, C₃-C₆, C₃-C₅, C₃-C₄ alkynyl group. The cyclic alkynyl can be a monocyclic or polycyclic alkynyl, such as a C₄-C₁₂, C₄-C₁₀, C₄-C₉, C₄-C₅, C₄-C₇, C₄-C₆, or C₄-C₅ monocyclic or polycyclic alkynyl group.

For any of the formulae described herein, the aryl (when present) can be a C₄-C₃₀ aryl, a C₄-C₂₀ aryl, a C₄-C₁₂ aryl, a C₄-C₁₁ aryl, a C₄-C₉ aryl, a C₅-C₃₀ aryl, a C₅-C₂₀ aryl, a C₅-C₁₂ aryl, a C₅-C₁₁ aryl, a C₅-C₉ aryl, a C₆-C₂₀ aryl, a C₆-C₁₂ aryl, a C₆-C₁₁ aryl, or a C₆-C₉ aryl. It is understood that the aryl can be a heteroaryl, such as a C₄-C₃₀ heteroaryl, a C₄-C₂₀ heteroaryl, a C₄-C₁₂ heteroaryl, a C₄-C₁₁ heteroaryl, a C₄-C₉ heteroaryl, a C₅-C₃₀ heteroaryl, a C₅-C₂₀ heteroaryl, a C₅-C₁₂ heteroaryl, a C₅-C₁₁ heteroaryl, a C₅-C₉ heteroaryl, a C₆-C₃₀ heteroaryl, a C₆-C₂₀ heteroaryl, a C₆-C₁₂ heteroaryl, a C₆-C₁₁ heteroaryl, or a C₆-C₉ heteroaryl.

For any of the formulae described herein, the polyaryl group can be a C₈-C₃₀ polyaryl, a C₈-C₂₀ polyaryl, a C₈-C₁₂ polyaryl, a C₈-C₁₁ polyaryl, a C₁₀-C₃₀ polyaryl, a C₁₀-C₂₀ polyaryl, a C₁₀-C₁₂ polyaryl, a C₁₀-C₁₁ polyaryl, or a C₁₂-C₂₀ polyaryl. It is understood that the aryl can be a heteropolyaryl, such as a C₁₀-C₃₀ heteropolyaryl, a C₁₀-C₂₀ heteropolyaryl, a C₁₀-C₁₂ heteropolyaryl, a C₁₀-C₁₁ heteropolyaryl, or a C₁₂-C₂₀ heteropolyaryl.

Exemplary platinum(II) complexes are presented below.

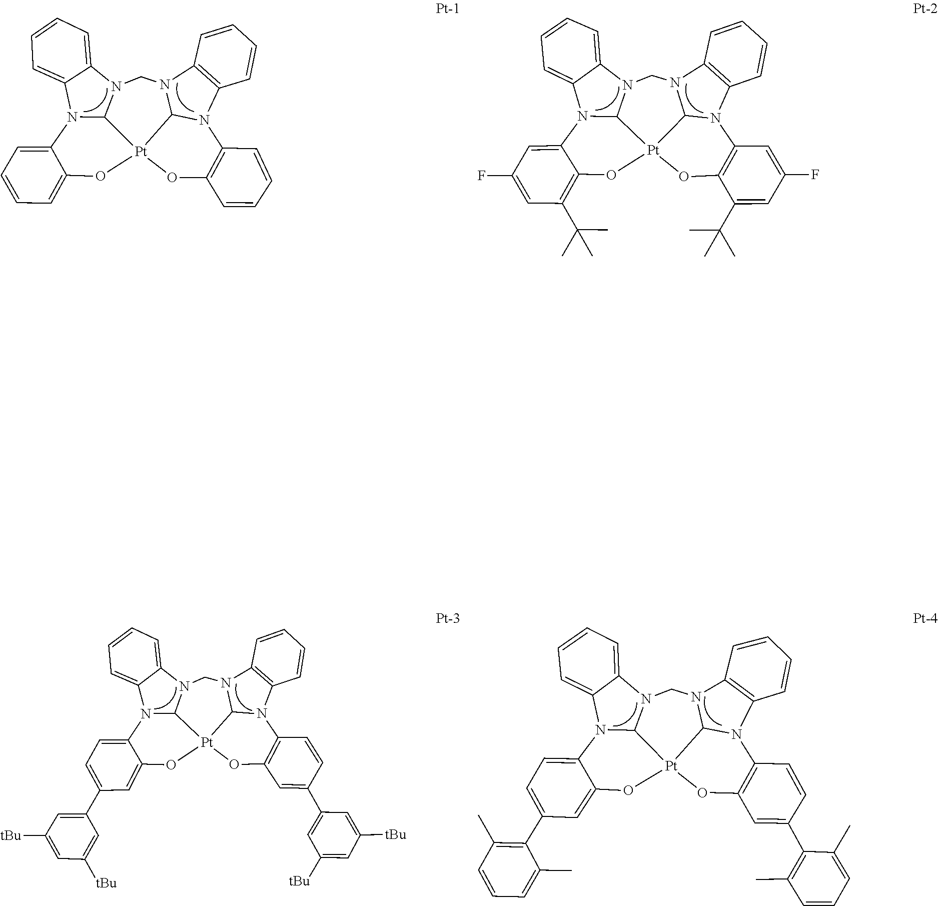

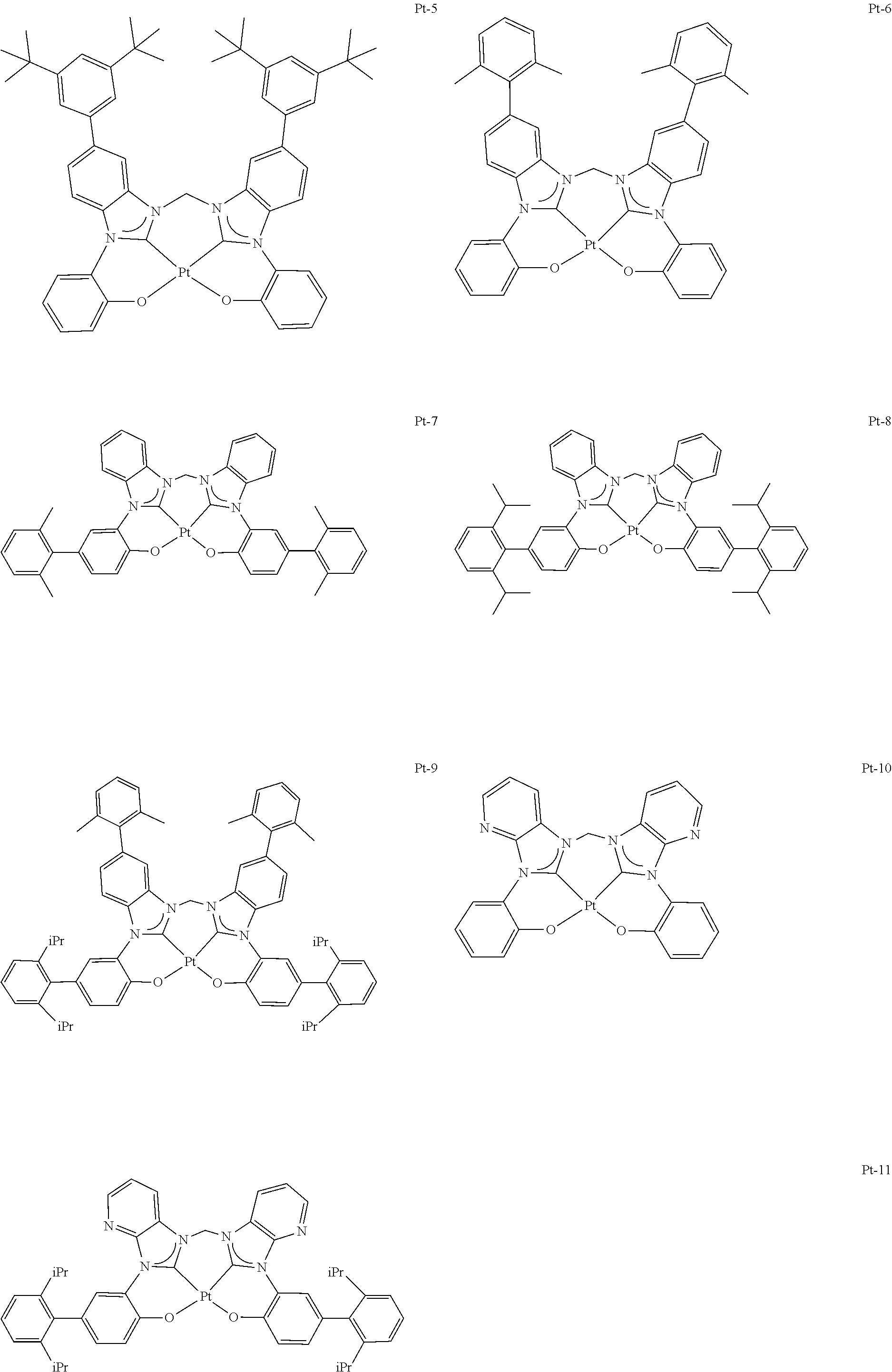

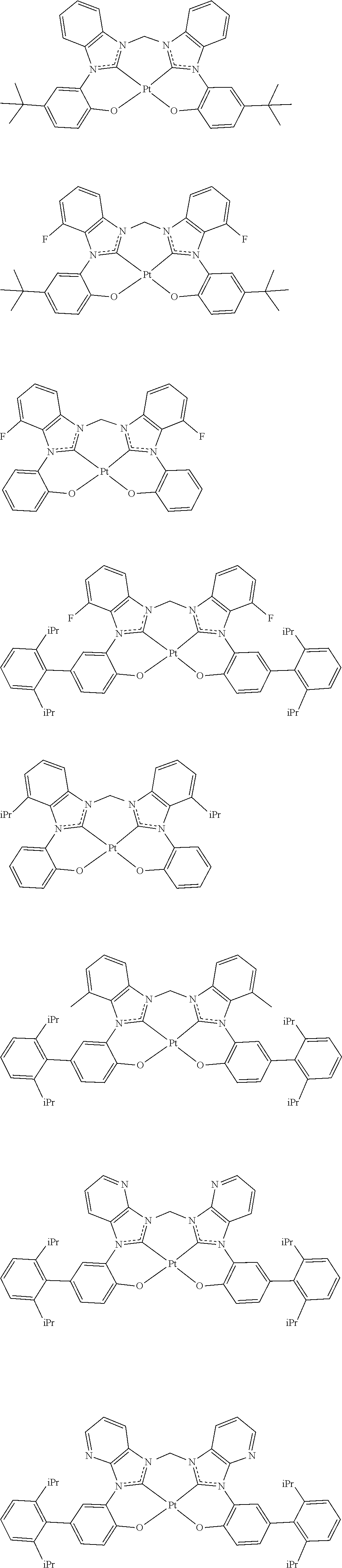

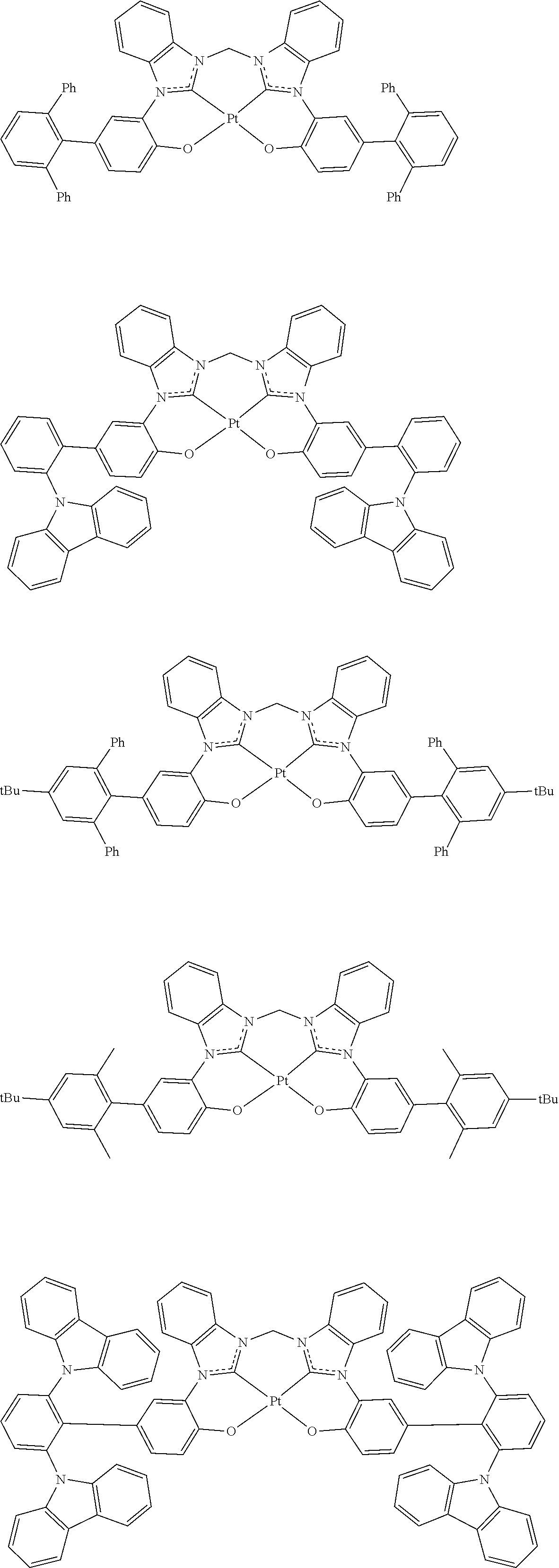

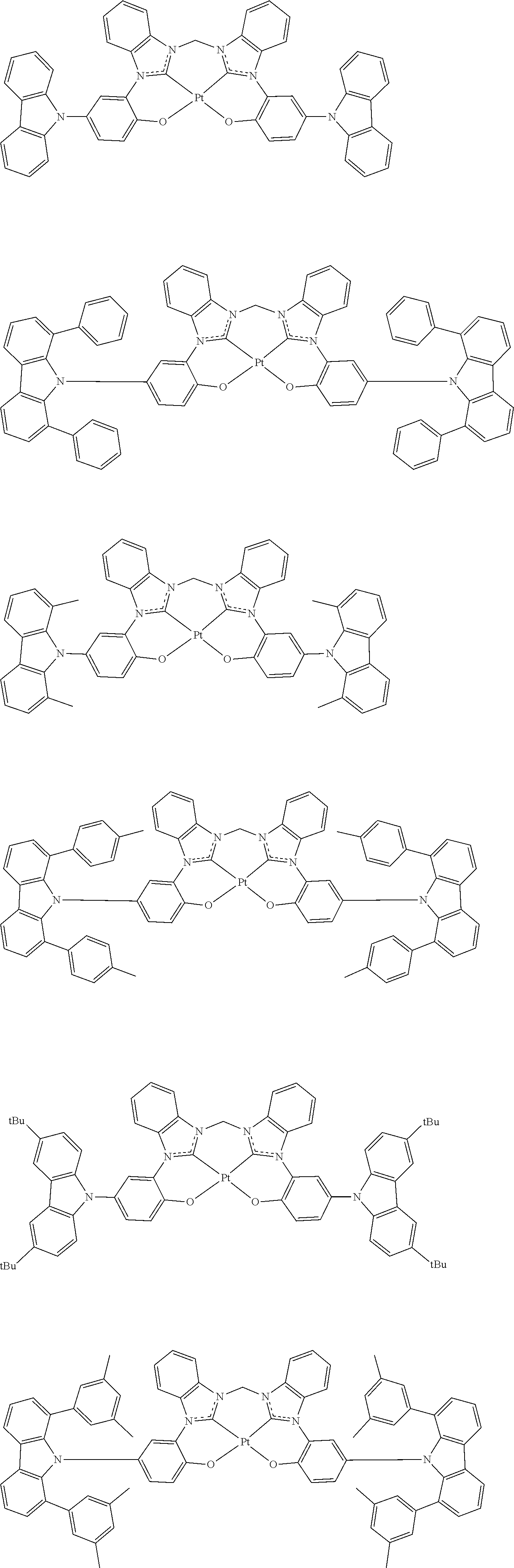

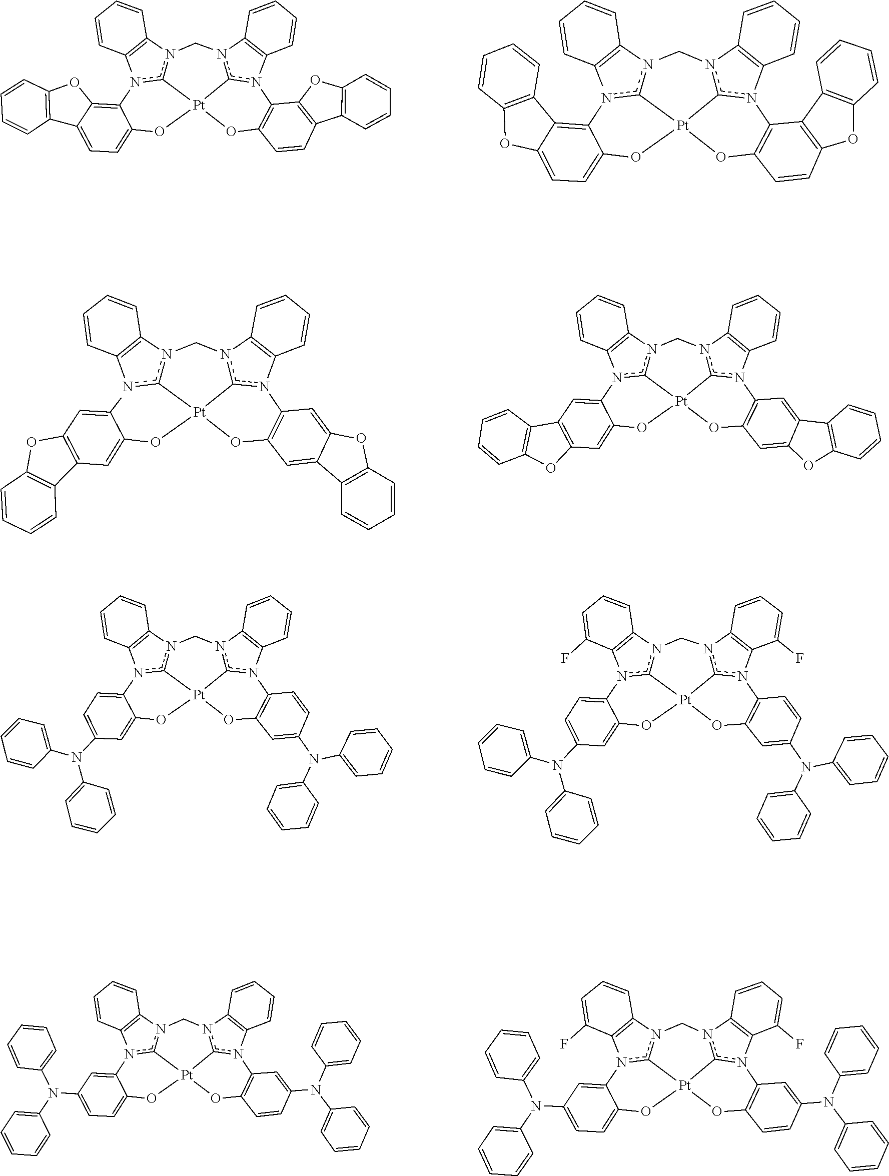

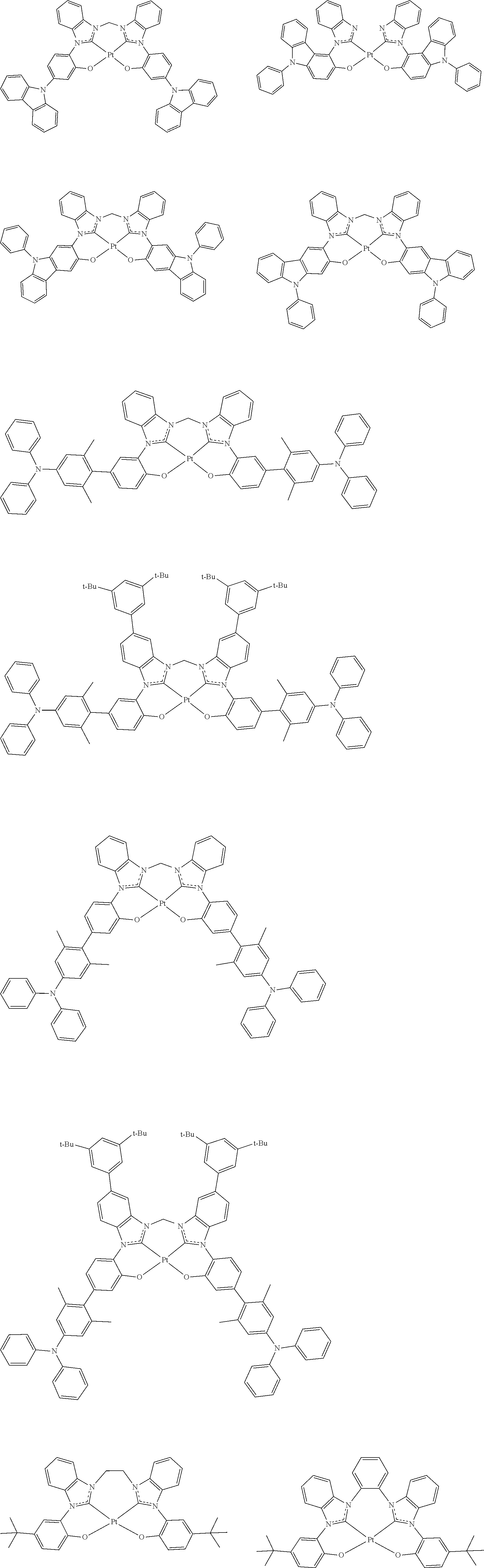

The photophysical properties of the platinum(II) complexes disclosed herein can be evaluated by a number of parameters, such as emission lifetime (“τₑₘ” or “τ”), radiative decay rate (“kᵣ”), emission quantum yield (“Φₑₘ”), and/or maximum emission wavelength (“λₘₐₓ”). Techniques for measuring the τₑₘ, kᵣ, Φₑₘ, and λₘₐₓ of the platinum(II) complexes are known. For example, these parameters can be obtained by measuring the emission spectra of a platinum(II) complex. For example, based on the measured emission decay graph, the τₑₘof the platinum(II) complex can be obtained as follows: (i) monitor the intensity of emission decay as a function of time using a Quanta Ray GCR 150-10 pulsed Nd:YAG laser system (pulse output: 355 nm), and (ii) determine the τₑₘby fitting the exponential decay of formula (1) using Origin software, where I₀ is the initial emission intensity, I(t) is the emission intensity at time t, τ is the emission lifetime, and t is the time.

$$I ( t ) = {I}_{0} {e}^{- t / τ} \qquad formula ( 1 )$$

The kᵣ of the platinum(II) complex can be obtained using kᵣ=Φₑₘ/τₑₘ. The Φₑₘ values of these Pt complexes can be measured by known methods, such as direct measurements or relative methods. For example, the Φₑₘ of the platinum(II) complexes in solutions or thin films, can be directly obtained by absolute measurement using Hamamatsu C₁₁₃₄₇ Quantaurus-QY Absolute PL quantum yield spectrometer (PL stands for photoluminescence). For example, the values for Φₑₘ are directly given by the software provided with the instrument. The λₘₐₓ of the platinum(II) complexes can be directly measured from the emission spectra.

Exemplary solutions suitable for measuring the τₑₘ, kᵣ, Φₑₘ, and/or λₘₐₓ of the platinum(II) complexes include those that contain an organic solvent. Exemplary organic solvents suitable for use to form the measurement solutions include, but are not limited to, dichloromethane, chloroform, tetrahydrofuran, N,N-dimethylformamide, chlorobenzene, and toluene, and a combination thereof. Optionally, the solutions for measuring the τₑₘ, kᵣ, Φₑₘ, and/or λₘₐₓ of the platinum(II) complexes is degassed with an inert gas, such as nitrogen, argon, or helium, or a combination thereof. Optionally, the solutions for measuring the τₑₘ, kᵣ, Φₑₘ, and/or λₘₐₓ of the platinum(II) complexes is deoxygenated by the known freeze-pump-thaw method.

Suitable thin films for measuring the τₑₘ, kᵣ, Φₑₘ, and/or λₘₐₓ of the platinum(II) complexes include films having a thickness between 10 nm and 50 μm, inclusive, between 10 nm and 10 μm, inclusive, between 10 nm and 5 μm, inclusive, between 10 nm and 1 μm, inclusive, between 10 nm and 500 nm, inclusive, or between 10 nm and 200 nm, inclusive. The films can also contain organic compounds as hot materials. Exemplary organic compounds that can be used as a host material in the films include, but are not limited to, 1,3-bis(N-carbazolyl)benzene (mCP), 3,3′-di(9H-carbazol-9-yl)-1,1′-biphenyl (mCBP), poly(methyl methacrylate) (PMMA), polystyrene (PS), 2,8-bis(diphenylphosphoryl)dibenzo[b,d]furan (PPF), bis[2-(diphenylphosphino)phenyl]ether oxide (DPEPO).

In some forms, the platinum(II) complexes disclosed herein can have a maximum emission wavelength (λₘₐₓ) in a range from 420 nm to 490 nm, from 430 nm to 490 nm, from 440 nm to 490 nm, from 450 nm to 490 nm, from 460 nm to 490 nm, from 430 nm to 465 nm, or from 440 nm to 470 nm, such as from 441 nm to 454 nm, optionally based on the emission spectra of the platinum(II) complexes as described above.

In some forms, the platinum(II) complexes disclosed herein can have an emission quantum yield (Φₑₘ) of at least 30%, at least 35%, at least 45%, at least 50%, at least 60%, at least 70%, in a range from 30% to 90%, from 30% to 85%, from 30% to 80%, from 35% to 85%, from 35% to 80%, from 45% to 85%, from 45% to 80%, from 50% to 85%, or from 50% to 80%, measured in films, at room temperature, optionally based on the emission spectra of the platinum(II) complexes as described above.

In some forms, the platinum(II) complexes disclosed herein can have an emission lifetime (τₑₘ) of ≤5.5 μs, ≤5 μs, ≤4 μs, ≤3 μs, ≤2 μs, ≤1 μs, in a range from 0.5 μs to 5 μs, from 1 μs to 5 μs, or from 2 μs to 5 μs, such as about 2.25 μs, measured in films, at room temperature, optionally based on the emission spectra of the platinum(II) complexes as described above.

In some forms, the platinum(II) complexes disclosed herein can have a radiative decay rate (kᵣ) of at least 1.0×10⁵ s⁻¹, at least 1.5×10⁵ s⁻¹, at least 2.0×10⁵ s⁻¹, in a range from 1.0×10⁵ s⁻¹ to 6.0×10⁵ s⁻¹, 1.0×10⁵ s⁻¹ to 5.0×10⁵ s⁻¹, 1.5×10⁵ s⁻¹ to 6.0×10⁵ s⁻¹, from 1.5×10⁵ s⁻¹ to 5.0×10⁵ s⁻¹, from 2.0×10⁵ s⁻¹ to 6.0×10⁵ s⁻¹, from 2.0×10⁵ s⁻¹ to 5.0×10⁵ s⁻¹, from 1.0×10⁵ s⁻¹ to 4.0×10⁵ s⁻¹, from 1.5×10⁵ s⁻¹ to 4.0×10⁵ s⁻¹, from 2.0×10⁵ s⁻¹ to 4.0×10⁵ s⁻¹, or from 3.0×10⁵ s⁻¹ to 6.0×10⁵ s⁻¹, such as about 3.4×10⁵ s⁻¹, measured in films, at room temperature, optionally based on the emission spectra of the platinum(II) complexes as described above.

In some forms, the platinum(II) complexes disclosed herein can have a τₑₘ, a kᵣ, a Φₑₘ, and/or a λₘₐₓ in any one of the above-described ranges.

### B. Devices Containing Platinum(II) Complexes

Organic light-emitting components, such as light-emitting diodes (OLEDs) or light-emitting electrochemical cell (“LEEC”), containing one or more of the platinum(II) complexes are described. Devices containing one or more OLEDs containing one or more of the platinum(II) complexes include, but are not limited to, stationary visual display units, mobile visual display units, and illumination devices, such as smart phones, televisions, monitors, digital cameras, tablet computers, and lighting fixtures that usually operate at room temperatures, wearable devices, and medical monitoring devices.

In some forms, the platinum(II) complexes can be incorporated in a light-emitting layer. The light-emitting layer may further contain one or more luminescent organic dyes. When an organic dye is incorporated in the light-emitting layer, the platinum(II) complexes and the dye can have any suitable weight ratios, such as 4:1, 8:1, 10:1, 12:1, 15:1, or 20:1. In some forms, the platinum(II) complexes in the light-emitting layer act as a sensitizer to transfer energy to the organic dye. In some forms, the platinum(II) complexes have a higher-lying singlet state than the organic dye.

In some forms, the light-emitting layer can be incorporated in an organic light-emitting component, such as an OLED. Organic light-emitting components can contain one or more light-emitting layers, where each light-emitting layer can contain one or more the disclosed platinum(II) complexes. In some forms, when two or more light-emitting layers are included in the organic light-emitting component, the light-emitting layer or each light-emitting layer further includes one or more host materials, such as those described above. Typically, the total concentration of the one or more host materials is greater than the total concentration of the one or more platinum(II) complexes in the light-emitting layer or each light-emitting layer of the two or more light-emitting layers. The term “total concentration of the one or more platinum(II) complexes” refers to the sum of the weight of the one or more platinum(II) complexes relative to the sum of the weights of all of the materials used in one light-emitting layer in an organic light-emitting device, such as an OLED. The term “total concentration of the one or more one or more host materials” refers to the sum of the weight of the one or more host materials relative to the sum of the weights of all of the materials used in one light-emitting layer in an organic light-emitting device, such as an OLED. The organic light-emitting devices can contain a suitable amount of the platinum(II) complexes in the light-emitting layer or each light-emitting layer of the two or more light-emitting layers of the device. For example, the total concentration of the one or more platinum(II) complexes in the light-emitting layer or each light-emitting layer of the two or more light-emitting layers is up to 20 wt %, up to 10 wt %, at least 1 wt %, in a range from about 1 wt % to about 20 wt %, from about 1 wt % to about 10 wt %, from about 2 wt % to about 20 wt %, or from about 2 wt % to about 10 wt %, such as about 2 wt %, about 6 wt %, or about 10 wt %.

In some forms, the organic light-emitting component, such as an OLED, can further include an anode, a cathode, a hole transport region, and/or an electron transport region. The hole transport region can include a hole injection layer and/or a hole transport layer, and optionally an electron blocking layer. The electron transport region can include an electron transport layer and/or an electron injection layer, and optionally a hole blocking layer. The light-emitting layer can be located in between the anode and the cathode. The hole transport region can be located in between the anode and the light-emitting layer. The electron transport region can be located in between the cathode and the light-emitting layer. The specific components and arrangement of the components in each of the hole transport region and the electron transport region depend on the specific use.

An exemplary OLED containing the disclosed platinum(II) complexes is illustrated in FIG. 6. As shown in FIG. 6, the exemplary OLED 100 includes multiple layers, which are, from bottom to top, a substrate 101, an anode 102, a hole injection layer 103, a hole transport layer 104, an optional electron blocking layer 105, an emission layer 106, an optional hole blocking layer 107, an electron transport layer 108, an electron injection layer 109, and a cathode 110. The emission layer 106 is formed by one or more of the platinum(II) complexes disclosed herein. Suitable materials for forming the anode, the hole injection layer, the hole transport layer, the optional electron blocking layer, the optional hole blocking layer, the electron transport layer, the electron injection layer, and the cathode are known in the art, see, for example, those described in Hong, et al., Adv. Mater. 2021, U.S. Pat. No. 2,005,630; Lee, et al., InfoMat. 2021, 3, 61-81; and Jou, et al., J. Mater. Chem. C, 2015, 3, 2974-3002. The dimensions of each layer in the OLED, such as the shape, the length, the width, and/or the thickness of each layer can be varied depending on the specific use of the OLED. More specific exemplary OLEDs are described in the Examples below.

These organic light-emitting devices containing the disclosed platinum(II) complexes can emit in blue regions (λₘₐₓ ranging from 420 nm to 490 nm, such as from 440 nm to 490 nm, from 450 nm to 490 nm, from 460 nm to 490 nm, from 430 nm to 480 nm, from 440 nm to 480 nm, from 450 nm to 480 nm, from 460 nm to 480 nm, or from 470 nm to 480 nm) with high performance. The performance of OLEDs containing the disclosed platinum(II) complexes can be evaluated using known parameters, such as maximum brightness (L), current efficiency (CE) at 1000 cd m⁻², power efficiency (PE) at 1000 cd m⁻², and/or external quantum efficiency (EQE) at 1000 cd m⁻².

Techniques for measuring the brightness, current efficiency, power efficiency, and/or external quantum efficiency are known. For example, maximum brightness is measured at which any increase in voltage does not lead to an increase in brightness (the device may burn out if the voltage is further increased). For example, the EQE, CE, and PE of an electroluminescence device can be obtained by using a Keithley 2400 source-meter and an absolute external quantum efficiency measurement system (C9920-12, Hamamatsu Photonics), where all devices can be encapsulated in a 200-nm-thick Al₂O₃ thin film deposited by atomic layer deposition (ALD) in a Kurt J. Lesker SPECTROS ALD system before measurements.

In some forms, OLEDs containing from 2 wt % to 10 wt % of the disclosed platinum(II) complexes can emit in the blue region (λₘₐₓ in a range from about 420 nm to about 490 nm, such as from 470 nm to 480 nm) with a maximum brightness (L) of at least 3000 cd m⁻², at least 4000 cd m⁻², at least 5000 cd m⁻², at least 6000 cd m⁻², at least 8000 cd m⁻², in a range from 3000 cd m⁻² to 50000 cd m⁻², from 3000 cd m⁻² to 40000 cd m⁻², from 3000 cd m⁻² to 30000 cd m⁻², from 3000 cd m⁻² to 25000 cd m⁻², or from 3000 cd m⁻² to 15000 cd m².

In some forms, OLEDs containing from 2 wt % to 10 wt % of the disclosed platinum(II) complexes can emit in the blue region (λₘₐₓ in a range from about 420 nm to about 490 nm, such as from 470 nm to 480 nm) with a CE at 1000 cd m⁻² of at least 20 cd A⁻¹, at least 25 cd/A, in a range from 20 cd/A to 50 cd/A, or from 20 cd/A to 45 cd/A.

In some forms, OLEDs containing from 2 wt % to 10 wt % of the disclosed platinum(II) complexes can emit in the blue region (λₘₐₓ in a range from about 420 nm to about 490 nm, such as from 470 nm to 480 nm) with a PE at 1000 cd/m² of at least 20 lm/W, in a range from 20 lm/W to 50 lm/W, or from 20 lm/W to 45 lm/W.

In some forms, OLEDs containing from 2 wt % to 10 wt % of the disclosed platinum(II) complexes can emit in the blue region (λₘₐₓ in a range from about 420 nm to about 490 nm, such as from 470 nm to 480 nm) with an EQE at 1000 cd/m² of at least 10%, at least 15%, in a range from 10% to 35%, from 10% to 30%, from 10% to 25%, from 15% to 35%, from 15% to 30%, from 15% to 25%, from 20% to 30%, or from 15% to 20%, such as about 20%.

In some forms, OLEDs containing from 2 wt % to 10 wt % of the disclosed platinum(II) complexes can emit in blue region (λₘₐₓ in a range from about 420 nm to about 490 nm, such as from 470 nm to 480 nm) with a maximum brightness (L), a CE at 1000 cd m⁻², a PE at 1000 cd/m², and/or an EQE at 1000 cd/m² in any of the ranges described above.

More specific examples of the maximum brightness, current efficiency, power efficiency, and external quantum efficiency of exemplary OLEDs containing exemplary platinum(II) complexes are described in the Examples below.

### III. Methods of Making and Reagents therefor

### A. Platinum (II) Complexes

The platinum(II) complexes and the ligands described herein can be synthesized using methods known in the art of organic chemical synthesis. For example, ligands can be purchased from commercial chemical manufacturers or may be prepared according to procedures reported and/or adapted from the literature. The selection of appropriate synthetic conditions, reagents, reaction workup conditions, purification techniques (as needed) are known to those in the field of synthesis.

Exemplary syntheses of carbene ligands L1 through L8 and Pt(II) complexes Pt-1 through Pt-8 are shown below and discussed in the Examples.

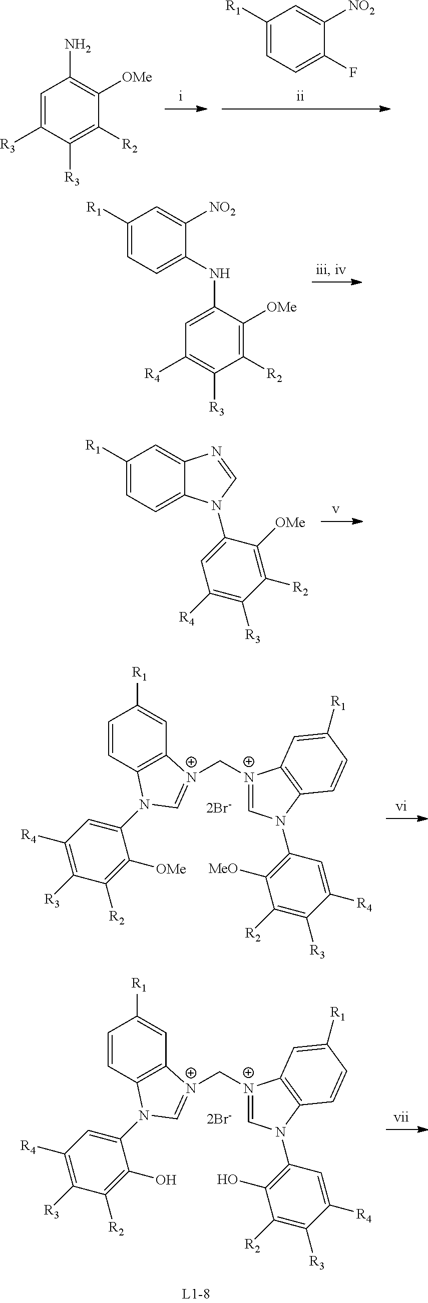

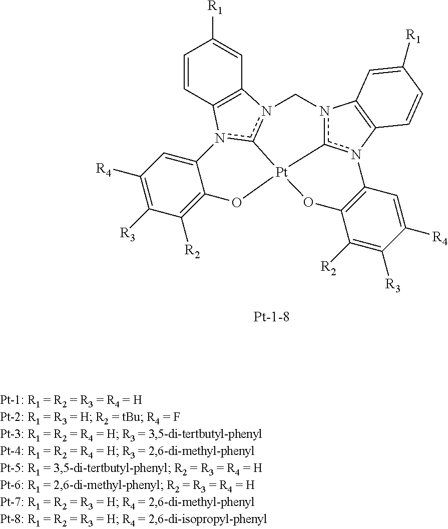

where the reaction conditions are as follows: (i) NaH, room temp. 0.5 h, DMF; (ii) room temp. overnight; (iii) H₂, Pd/C, EtOH, room temp. 2 h; (iv) HCOOH, reflux, 12 h; (v) CH₂Br₂, 120° C., 72 h; (vi) BBr₃, DCM, 0° C. to room temp., 12 h; (vii) Pt(COD)Cl₂, NEt₃, EtOH, reflux, 6h.

### B. Organic Light-Emitting Components

Also described are methods of making organic light-emitting components, such as OLEDs, containing one or more platinum(II) complexes described herein. Methods of preparing OLEDs containing one or more platinum(II) complexes, as described above, are well-known in the art of organic electronics. Such method of making OLEDs can involve vacuum deposition or solution processing techniques, such as spin-coating and ink-jet printing. The selection of suitable materials (anode, cathode, hole transport layer, electron transport layer, etc.) and fabrication parameters (such as deposition conditions or solvent selections) needed to fabricate OLEDs containing the platinum(II) complexes described herein are known in the art. In some forms, preparation of the OLEDs can be via vacuum deposition or solution processing techniques such as spin-coating and ink printing (such as, ink-jet printing or roll-to-roll printing). An exemplary and non-limiting method of making an OLED containing one or more platinum(II) complexes is described in the Examples.

### IV. Methods of Use

The platinum(II) complexes described herein are emissive in the blue spectral region (λₘₐₓ at 420 nm-490 nm, such as 441-454 nm), with a high emission quantum yield (i.e. Φₑₘ≥>30%, such as from 30% to 90%, from 30% to 85%, or from 30% to 80%), a short emission lifetime (i.e. τₑₘ or τ≤5.5 μs or ≤5 μs and down to about 2 μs, such as about 2.25 μs), and/or a fast radiative decay rate (i.e. kᵣ≥1.0×10⁵ s⁻¹ and up to about 6.0×10⁵ s⁻¹, such as about 3.4×10⁵ s⁻¹), measured in thin films at room temperature or other low temperatures, such as at a temperature in the range from 285 K to 300 K.

The platinum(II) blue emitters can be incorporated into organic electronic components including, but not limited to, OLEDs or a light-emitting electrochemical cell (LEEC). OLEDs using the platinum(II) complexes can emit electroluminescence in the blue spectral region (λₘₐₓ at about 400-500 nm, such as 470-480 nm) with a high EQE of at least 10% at 1000 cd m⁻², such as 10-35% at 1000 cd m⁻², e.g., about 20% at 1000 cd m⁻² Such OLEDs can be used in commercial applications such smart phones, televisions, monitors, digital cameras, tablet computers, lighting fixtures that usually operate at room temperatures, a fixed visual display unit, mobile visual display unit, illumination unit, keyboard, clothes, ornaments, garment accessary, wearable devices, medical monitoring devices, wall paper, tablet PC, laptop, advertisement panel, panel display unit, household appliances, and office appliances.

The disclosed Pt(II) complexes, devices, and methods can be further understood through the following enumerated paragraphs.

Paragraph 1. A platinum(II) complex having a structure:

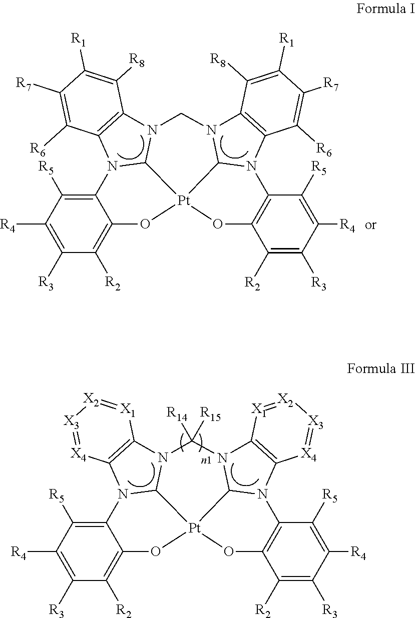

wherein:
(i) each occurrence of X₁-X₄ is independently nitrogen or CR₁₆;
(ii) each occurrence of R₁-R₈ and R₁₆ is independently hydrogen, a halide (e.g., fluoride, chloride, bromide, iodide, etc.), hydroxyl, amino, amido, thiol, cyano, nitro, alkoxy, carbonyl, a substituted or unsubstituted C₁-C₁₂ alkyl, a substituted or unsubstituted C₁-C₁₂ alkenyl, a substituted or unsubstituted C₁-C₁₂ alkynyl, a substituted or unsubstituted aryl (e.g., phenyl), a substituted or unsubstituted heteroaryl, a substituted or unsubstituted polyaryl, or a substituted or unsubstituted heteropolyaryl, or two neighboring R groups together with the carbon atoms to which they are attached can form a substituted or unsubstituted aryl, a substituted or unsubstituted heteroaryl, a substituted or unsubstituted polyaryl, or a substituted or unsubstituted heteropolyaryl;
(iii) n1 is an integer from 1 to 6, from 1 to 5, from 1 to 4, from 1 to 3, or 1 or 2;
(iv) R₁₄ and R₁₅ are independently hydrogen, a substituted or unsubstituted C₁-C₁₂ alkyl, a substituted or unsubstituted C₁-C₁₂ alkenyl, or a substituted or unsubstituted C₁-C₁₂ alkynyl, or R₁₄ and R₁₅ of two neighboring carbon atoms, together with the carbon atoms to which they are attached, can form a substituted or unsubstituted aryl, a substituted or unsubstituted heteroaryl, a substituted or unsubstituted polyaryl, or a substituted or unsubstituted heteropolyaryl; and
(v) the substituent(s), when present, are independently an unsubstituted C₁-C₁₂ alkyl, an unsubstituted C₁-C₁₂ alkenyl, an unsubstituted C₁-C₁₂ alkynyl, an unsubstituted aryl (e.g., phenyl), a substituted aryl (e.g., phenyl) by unsubstituted aryl(s) (e.g., unsubstituted phenyls) and/or unsubstituted alkyl(s) (e.g., unsubstituted C₁-C₁₂ alkyl), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), an amino, or a halide.

Paragraph 2. The platinum(II) complex of paragraph 1, wherein the platinum(II) has a structure:

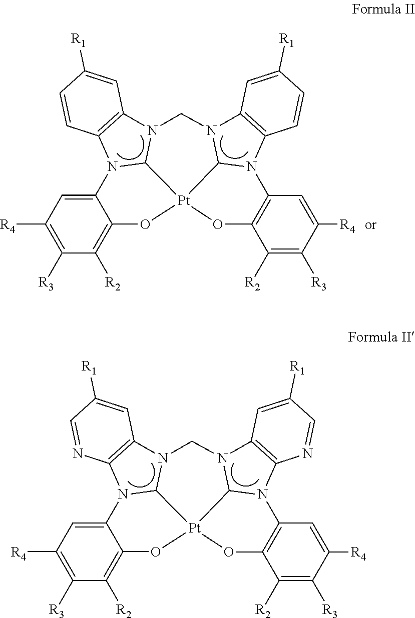

Paragraph 3. The platinum(II) complex of paragraph 1, wherein X₁ and X₄ are independently nitrogen or CR₁₆; X₂ and X₃ are CR₁₆; R₁₆ is hydrogen, halide, an unsubstituted C₁-C₁₂ alkyl, an unsubstituted aryl, or an aryl substituted by unsubstituted C₁-C₁₂ alkyl(s); R₂-R₅ are independently hydrogen, amino, an unsubstituted C₁-C₁₂ alkyl, a substituted or unsubstituted aryl, a substituted or unsubstituted heteroaryl, a substituted or unsubstituted polyaryl, or a substituted or unsubstituted heteropolyaryl, or R₂ and R₃, R₃ and R₄, or R₄ and R₅ together with the carbon atoms to which they are attached form a substituted or unsubstituted aryl, a substituted or unsubstituted heteroaryl, a substituted or unsubstituted polyaryl, or a substituted or unsubstituted heteropolyaryl; and the substituent(s), when present, are independently an unsubstituted C₁-C₁₂ alkyl, an unsubstituted aryl (e.g., phenyl), a substituted aryl (e.g., phenyl) by unsubstituted aryl(s) (e.g., phenyls) and/or unsubstituted alkyl(s), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), or an amino.

Paragraph 4. The platinum(II) complex of paragraph 1 or 2, wherein each occurrence of R₁-R₈ is independently hydrogen, a halide, a substituted or unsubstituted C₁-C₁₂ alkyl, a substituted or unsubstituted C₁-C₁₂ alkenyl, a substituted or unsubstituted C₁-C₁₂ alkynyl, a substituted or unsubstituted aryl, a substituted or unsubstituted heteroaryl, a substituted or unsubstituted polyaryl, a substituted or unsubstituted polyaryl, or a substituted or unsubstituted heteropolyaryl.

Paragraph 5. The platinum(II) complex of paragraph 4, wherein each occurrence of R₁-R₈ is independently hydrogen, a halide, a substituted or unsubstituted C₁-C₁₂ alkyl, or a substituted or unsubstituted aryl.

Paragraph 6. The platinum(II) complex of paragraph 4 or 5, wherein each occurrence of R₁-R₈ is independently hydrogen, a halide (e.g., fluoride, chloride, or bromide), an unsubstituted C₁-C₁₂ alkyl (e.g., an unsubstituted C₁-C₆ alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or

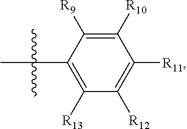

and wherein R₉-R₁₃ are independently hydrogen, an unsubstituted C₁-C₁₂ alkyl, an unsubstituted phenyl, an unsubstituted heteropolyaryl, or an amino, optionally wherein R₉-R₁₃ are independently hydrogen or an unsubstituted C₁-C₆ alkyl (e.g., methyl, ethyl, n-propyl, isopropyl, n-butyl, isobutyl, tert-butyl, etc.).

Paragraph 7. The platinum(II) complex of any one of paragraphs 1-6, wherein the platinum(II) complex has any one of the structures:

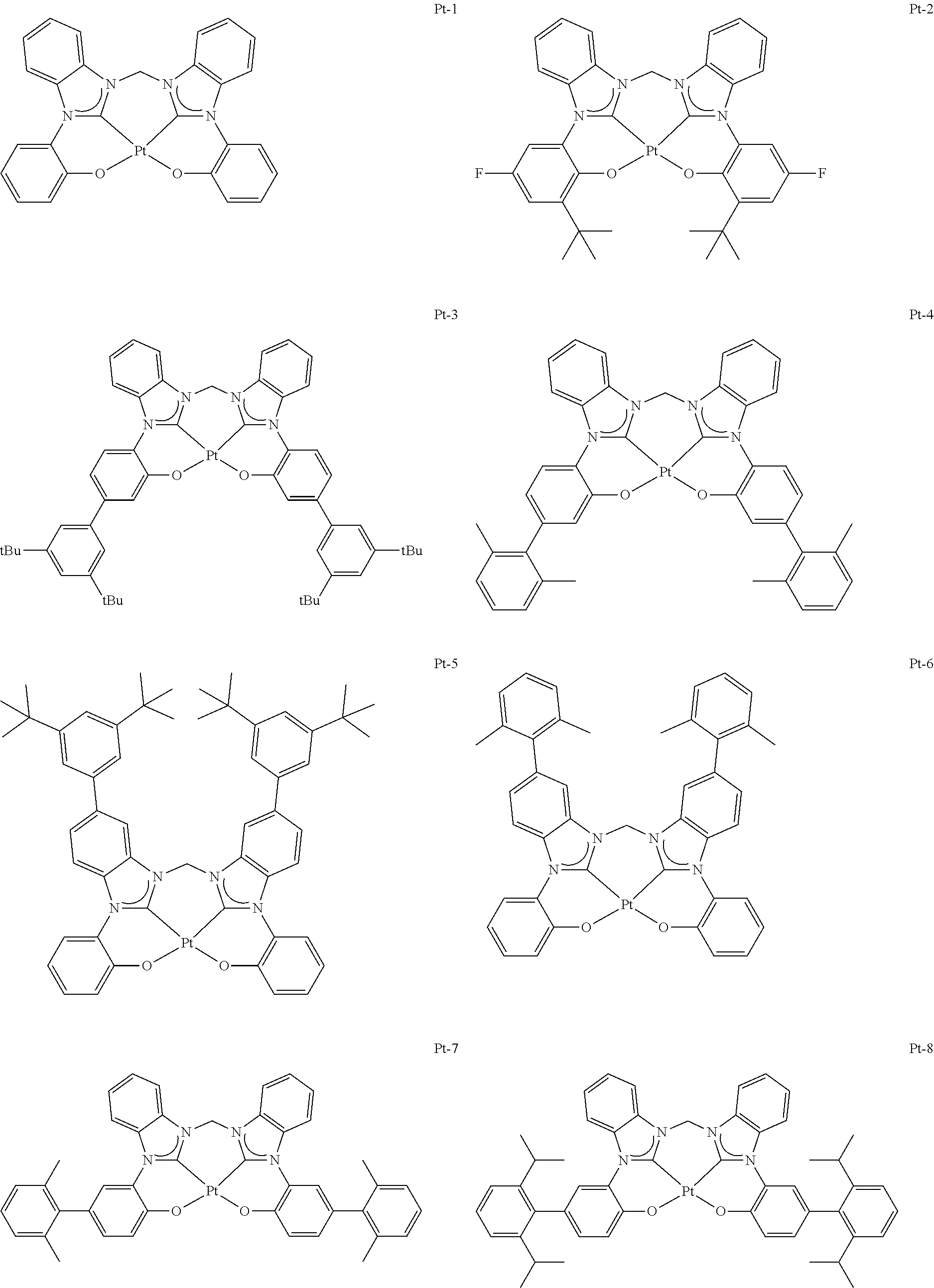

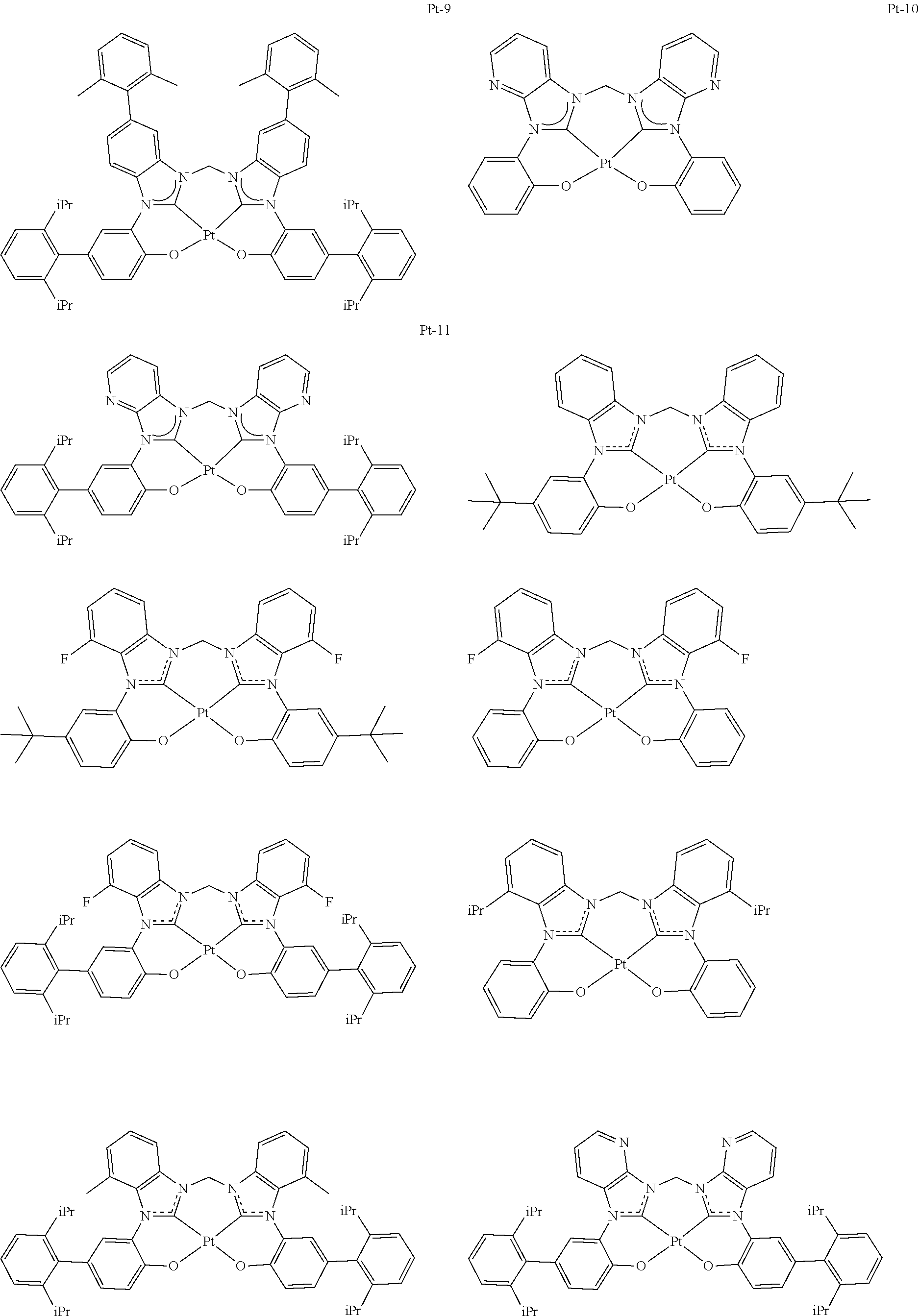

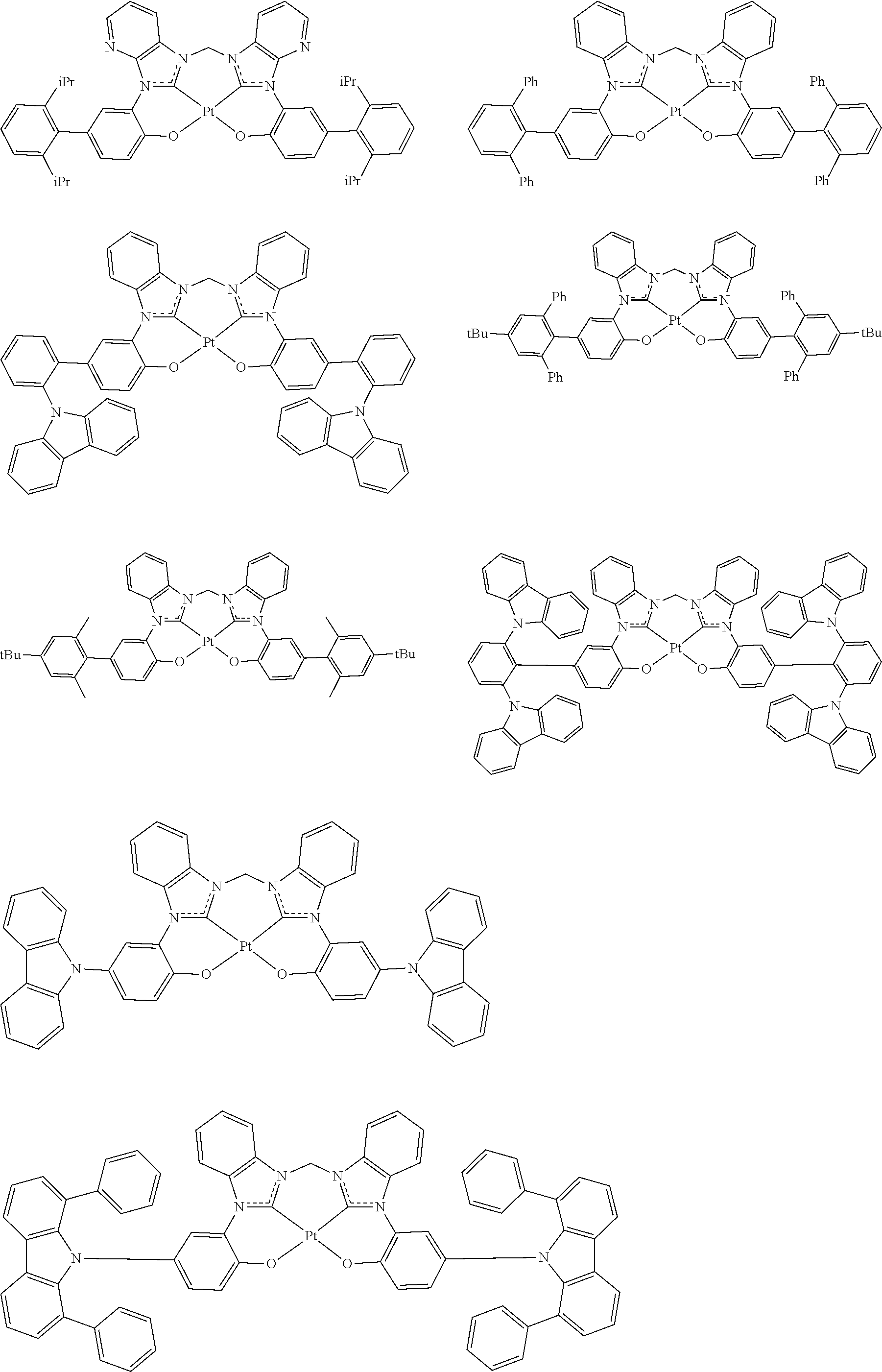

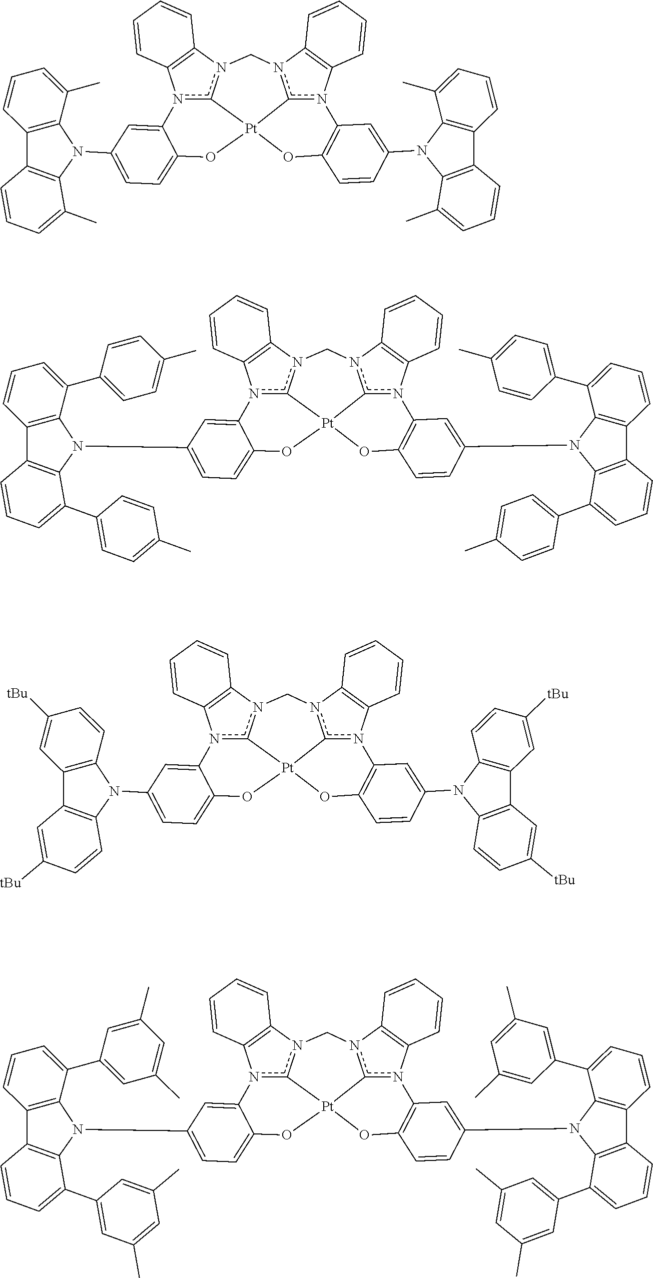

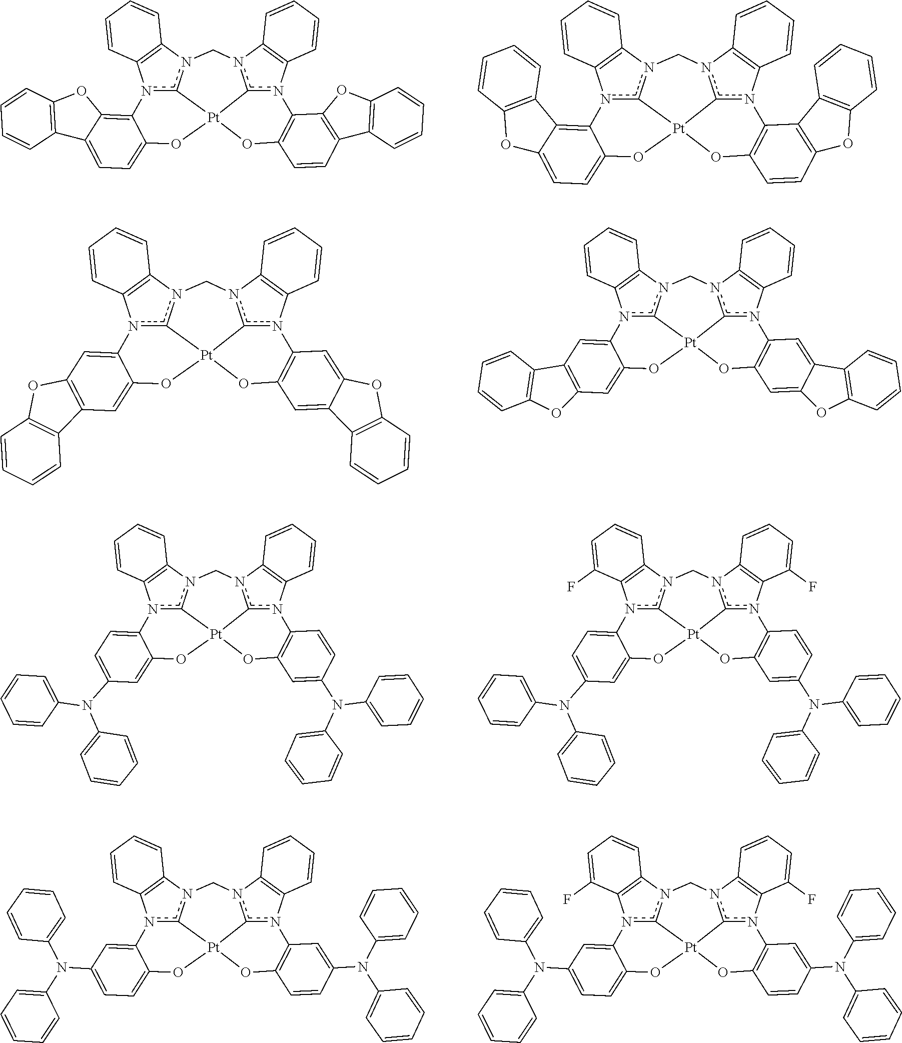

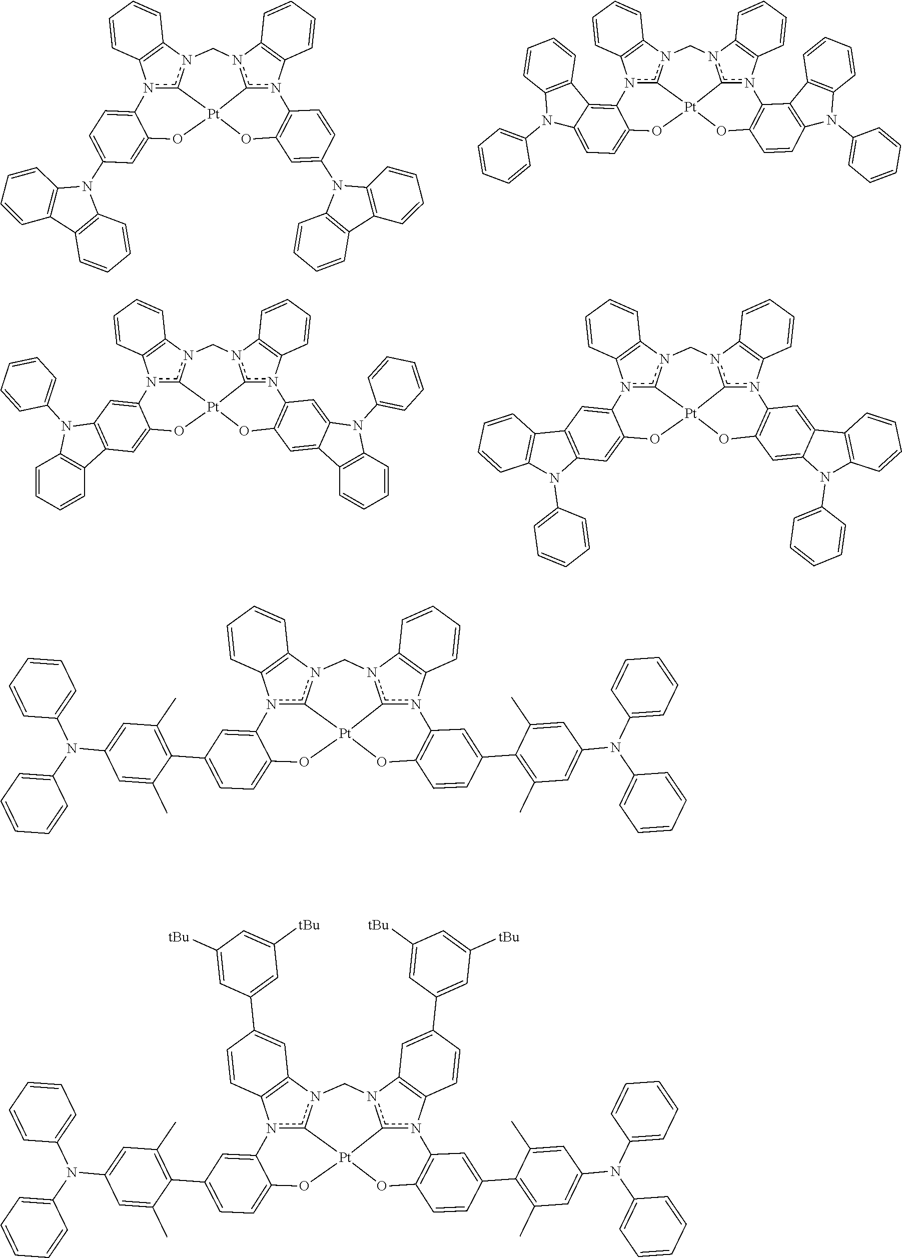

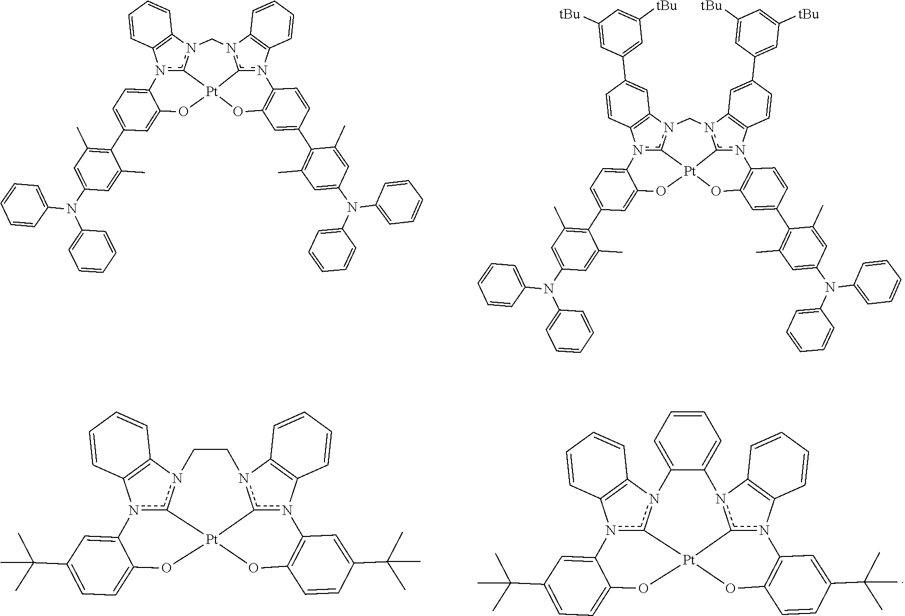

Paragraph 8. The platinum(II) complex of any one of paragraphs 1-7, wherein the platinum(II) complex has a maximum emission wavelength (λₘₐₓ) in a range from 420 nm to 490 nm, from 430 nm to 490 nm, from 440 nm to 490 nm, from 450 nm to 490 nm, from 460 nm to 490 nm, from 430 nm to 465 nm, or from 440 nm to 470 nm, such as from 441 nm to 454 nm.

Paragraph 9. The platinum(II) complex of any one of paragraphs 1-8, wherein the platinum(II) complex has an emission quantum yield (Φₑₘ) of at least 30%, at least 35%, at least 45%, at least 50%, at least 60%, at least 70%, in a range from 30% to 90%, from 30% to 85%, from 30% to 80%, from 35% to 85%, from 35% to 80%, from 45% to 85%, from 45% to 80%, from 50% to 85%, or from 50% to 80%, measured in films, at room temperature.

Paragraph 10. The platinum(II) complex of any one of paragraphs 1-9, wherein the platinum(II) complex has an emission lifetime (τₑₘ) of ≤5.5 μs or ≤5 μs, ≤4 μs, ≤3 μs, ≤2 μs, ≤1 μs, in a range from 0.5 μs to 5 μs, from 1 μs to 5 μs, or from 2 μs to 5 μs, such as about 2.25 μs, measured in films, at room temperature.

Paragraph 11. The platinum(II) complex of any one of paragraphs 1-10, wherein the platinum(II) complex has a radiative decay rate (kᵣ) of at least 1.0×10⁵ s⁻¹, at least 1.5×10⁵ s⁻¹, at least 2.0×10⁵ s⁻¹, in a range from 1.0×10⁵ s⁻¹ to 6.0×10⁵ s⁻¹, 1.0×10⁵ s⁻¹ to 5.0×10⁵ s⁻¹, 1.5×10⁵ s⁻¹ to 6.0×10⁵ s⁻¹, from 1.5×10⁵ s⁻¹ to 5.0×10⁵ s⁻¹, from 2.0×10⁵ s⁻¹ to 6.0×10⁵ s⁻¹, from 2.0×10⁵ s⁻¹ to 5.0×10⁵ s⁻¹, from 1.0×10⁵ s⁻¹ to 4.0×10⁵ s⁻¹, from 1.5×10⁵ s⁻¹ to 4.0×10⁵ s⁻¹, from 2.0×10⁵ s⁻¹ to 4.0×10⁵ s⁻¹, or from 3.0×10⁵ s⁻¹ to 6.0×10⁵ s⁻¹, such as about 3.4×10⁵ s⁻¹, measured in films, at room temperature.

Paragraph 12. An organic light-emitting component comprising a light-emitting layer or two or more light-emitting layers, wherein the light-emitting layer or each light-emitting layer of the two or more light-emitting layers comprises one or more platinum(II) complexes of any one of paragraphs 1-11, optionally wherein the organic light-emitting component emits light in the blue spectral region.

Paragraph 13. The organic light-emitting component of paragraph 12, wherein the total concentration of the one or more platinum(II) complexes in the light-emitting layer or each light-emitting layer of the two or more light-emitting layers is up to 20 wt %, up to 10 wt %, at least 1 wt %, in a range from about 1 wt % to about 20 wt %, from about 1 wt % to about 10 wt %, from about 2 wt % to about 20 wt %, or from about 2 wt % to about 10 wt %, such as about 2 wt %, about 6 wt %, or about 10 wt %.

Paragraph 14. The organic light-emitting component of paragraph 12 or 13 further comprising an anode, a cathode, a hole transport region, and an electron transport region,
wherein the hole transport region comprises a hole injection layer and/or a hole transport layer, and optionally an electron blocking layer,
wherein the electron transport region comprises an electron transport layer and/or an electron injection layer, and optionally a hole blocking layer,
wherein the light emitting layer is located in between the anode and the cathode,
wherein the hole transport region is located in between the anode and the light-emitting layer, and
wherein the electron transport region is located in between the cathode and the light emitting layer.

Paragraph 15. The organic light-emitting component of any one of paragraphs 12-14, wherein the organic light-emitting component emits light in the blue region, optionally at λₘₐₓ in a range from 420 nm to 490 nm, such as from 440 nm to 490 nm, from 450 nm to 490 nm, from 460 nm to 490 nm, from 430 nm to 480 nm, from 440 nm to 480 nm, from 450 nm to 480 nm, from 460 nm to 480 nm, or from 470 nm to 480 nm.

Paragraph 16. The organic light-emitting component of any one of paragraphs 12-15, wherein the organic light-emitting component has a maximum brightness (L) of at least 3000 cd m⁻², at least 4000 cd m⁻², at least 5000 cd m⁻², at least 6000 cd m⁻², at least 8000 cd m⁻², in a range from 3000 cd m⁻² to 50000 cd m⁻², from 3000 cd m⁻² to 40000 cd m⁻², from 3000 cd m⁻² to 30000 cd m⁻², from 3000 cd m⁻² to 25000 cd m⁻², or from 3000 cd m⁻² to 15000 cd m⁻².

Paragraph 17. The organic light-emitting component of any one of paragraphs 12-16, wherein the organic light-emitting component has a current efficiency (CE) at 1000 cd/m² of at least 20 cd A⁻¹, at least 25 cd/A, in a range from 20 cd/A to 50 cd/A, or from 20 cd/A to 45 cd/A.

Paragraph 18. The organic light-emitting component of any one of paragraphs 12-17, wherein the organic light-emitting component has a power efficiency (PE) at 1000 cd/m² of at least 20 lm/W, in a range from 20 lm/W to 50 lm/W, or from 20 lm/W to 45 lm/W.

Paragraph 19. The organic light-emitting component of any one of paragraphs 12-18, wherein the organic light-emitting component has an external quantum efficiency (EQE) at 1000 cd/m² of at least 10%, at least 15%, in a range from 10% to 35%, from 10% to 30%, from 10% to 25%, from 15% to 35%, from 15% to 30%, from 15% to 25%, from 20% to 30%, or from 15% to 20%, such as about 20%.

Paragraph 20. The organic light-emitting component of any one of paragraphs 12-19, wherein the organic light-emitting component is an organic light-emitting diode (“OLED”) or a light-emitting electrochemical cell (“LEEC”).

Paragraph 21. The organic light-emitting component of any one of paragraphs 12-20, wherein the light emitting layer or each light-emitting layer of the two or more light-emitting layers further comprises an organic dye, and wherein the one or more platinum(II) complexes act as a sensitizer to transfer energy to the organic dye.

Paragraph 22. The organic light-emitting component of any one of paragraphs 12-20, wherein the light emitting layer or each light-emitting layer of the two or more light-emitting layers further comprises an organic dye, and wherein the one or more platinum(II) complexes have a higher-lying singlet state than the organic dye.

Paragraph 23. The organic light-emitting component of any one of paragraphs 12-22, wherein the light-emitting layer or each of the light-emitting layer of the two or more light-emitting layers is formed by vacuum-evaporation deposition, spin-coating, ink-printing, or roll-to-roll printing.

Paragraph 24. A device comprising one or more organic light-emitting components of any one of paragraphs 12-23, wherein the device is a stationary visual display unit, a mobile visual display unit, an illumination device, a wearable device, a phototherapy device, or a medical monitoring device.

### EXAMPLES

### Example 1. Synthesis and Characterization of Exemplary Platinum(II) Complexes and OLEDs Incorporating the Same

The efficient blue emitters are based on platinum(II) complexes containing platinum(II) atoms complexed by ligands containing benzimidazole based NHC and phenolate moieties. In some forms, the phenolate moiety of the ligands contains one or more bulky substitutions, such as bulky phenyl groups, for example, 3,5-di-tertbutyl-phenyl (ditBuPh) and 2,6-dimethyl-phenyl (diMePh). Without being bound to any theories, the geometry in these Pt(II) complexes (e.g., a reduced planarity and changed orientation between the NHC and the phenolate ring) and the extended π-conjugation of acceptor units allow for improved emission properties of the Pt(II) complexes, such as increment in emission quantum yield and radiative decay rate constant, compared to the previously reported imidazole-based Pt(II)-O\hat{ }C*\hat{ }C*\hat{ }O complexes. The exemplary Pt(II) complexes described herein demonstrate emission of this class of Pt(II) complexes in blue regions with a high emission quantum yield (i.e. Φₑₘ≥30% measured in thin films, such as from 30% to 90%, from 30% to 85%, or from 30% to 80%), a short emission lifetime (i.e. τₑₘ or τ≤5.5 μs or ≤5 μs and down to about 2 μs, such as about 2.25 μs), and/or a fast radiative decay rate (i.e. kᵣ≥1.0×10⁵ s⁻¹ and up to about 6.0×10⁵ s⁻¹, such as about 3.4×10⁵ s⁻¹), measured in thin films at room temperature. Results of the doped OLEDs using the exemplary platinum(II) emitters demonstrate electroluminescence in the blue spectral region (λₘₐₓ at about 420-490 nm, such as 470-480 nm) with an EQE of 10-35%, at 1000 cd m⁻², such as about 20% at 1000 cd m⁻².

### Materials and Methods

### Synthesis and Characterization of Exemplary Platinum(II) Complexes

The solvents used for synthesis were analytical grade unless specified. The anhydrous solvents were available commercially from J&K Scientific Co. Ltd, Beijing. NMR spectra were recorded on Advance Neo 400, Advance III HD 500, and Advance Neo 600 Bruker FT-NMR spectrometers. The chemical shift was calibrated relative to the solvent residual signal or signal from the tetramethylsilane. All the NMR measurements were carried out at room temperature. The high-resolution mass spectra (ESI-MS) were measured on Bruker impact II Q TOF mass spectrometer. Elemental analyses were performed at the Institute of Chemistry, Chinese Academy of Sciences, Beijing.

In the synthesis step described below, the precursors of 4 were illustrated as an exemplar procedure, and the precursors of the corresponding step in other complexes were followed as illustrated in 5, unless otherwise noted.

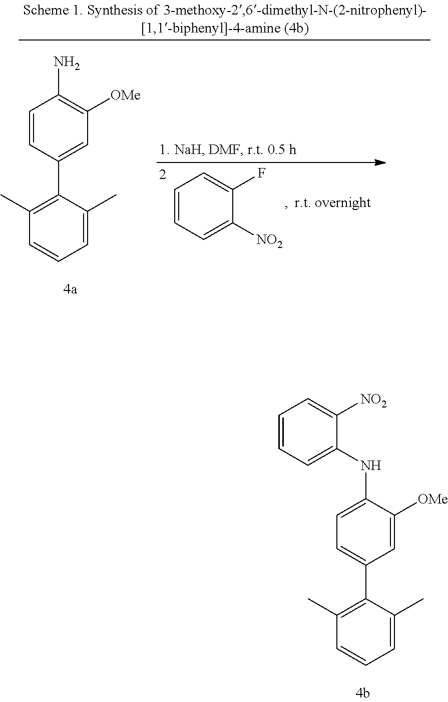 [SMILES: COc1cc(-c2c(C)cccc2C)ccc1N ; O=[N+]([O-])c1ccccc1F ; COc1cc(-c2c(C)cccc2C)ccc1Nc1ccccc1[N+](=O)[O-]]

In a 250 mL three-neck round bottom flask 1.45 g (6.38 mmol, 1 equiv), 3-methoxy-2′, 6′-dimethyl-[1,1′-biphenyl]-4-amine (4a) was dissolved in 25 mL anhydrous DMF. 0.57 g (14.3 mmol, 2.2 equiv, 60 wt % in mineral oil) NaH was added slowly into the solution in 10 min with an Argon flow protection at room temperature. The suspension was stirred for 0.5h and 0.81 mL (7.66 mol, 1.2 equiv) of 1-fluoro-2-nitrobenzene was added dropwise in 10 min to obtain a purple suspension. After stirring for 16 h at room temperature, the mixture was diluted with diethyl ether and quenched with saturated NH₄Cl solution. The organic layer was diluted with 200 mL ether, washed with saturated NaCl solution three times, combined, dried over MgSO₄, and purified using a silica gel column (eluent: n-Hexane: DCM=5/1). After evaporation, an orange solid was obtained with 1.79 g (Yield: 81%). ¹H NMR (500 MHz, CDCl₃) δ 9.52 (s, 1H), 8.22 (d, J=8.6 Hz, 1H), 7.42 (dd, J=14.6, 7.4 Hz, 2H), 7.36 (d, J=8.6 Hz, 1H), 7.23-7.16 (m, 1H), 7.14 (d, J=7.3 Hz, 2H), 6.85-6.72 (m, 3H), 3.85 (s, 3H), 2.11 (s, 6H).

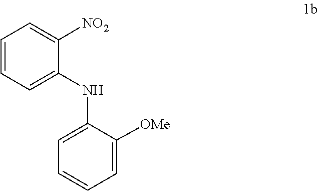 [SMILES: COc1ccccc1Nc1ccccc1[N+](=O)[O-]]

Yield: 49%. ¹H NMR (400 MHz, CDCl₃) δ 9.45 (s, 1H), 8.20 (dd, J=8.6, 1.5 Hz, 1H), 7.43-7.33 (m, 2H), 7.29-7.23 (m, 1H), 7.22-7.14 (m, 1H), 7.08-6.88 (m, 2H), 6.77 (ddd, J=8.4, 6.9, 1.2 Hz, 1H), 3.88 (s, 3H).

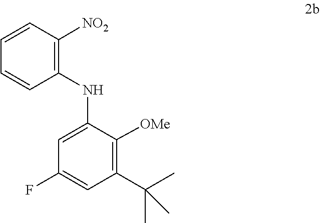 [SMILES: COc1c(Nc2ccccc2[N+](=O)[O-])cc(F)cc1C(C)(C)C]

Yield: 93%. ¹H NMR (400 MHz, CDCl₃) δ 9.37 (s, 1H), 8.23 (dd, J=8.6, 1.3 Hz, 1H), 7.49-7.38 (m, 1H), 7.24-7.19 (m, 1H), 6.95 (dd, J=8.5, 3.0 Hz, 1H), 6.90 (dd, J=10.7, 3.1 Hz, 1H), 6.87-6.81 (m, 1H), 3.71 (s, 3H), 1.40 (s, 9H). ¹⁹F NMR (377 MHz, CDCl₃) δ −117.36-−117.50 (m).

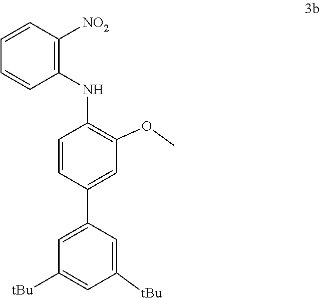 [SMILES: COc1cc(-c2cc(C(C)(C)C)cc(C(C)(C)C)c2)ccc1Nc1ccccc1[N+](=O)[O-]]

Yield: 58%. ¹H NMR (400 MHz, CDCl₃) δ 9.51 (s, 1H), 8.22 (dd, J=8.6, 1.4 Hz, 1H), 7.46 (t, J=1.8 Hz, 1H), 7.44 (d, J=7.9 Hz, 1H), 7.41 (d, J=1.8 Hz, 2H), 7.40-7.33 (m, 2H), 3.95 (s, 3H), 1.40 (s, 18H).

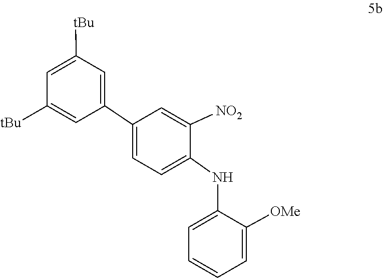 [SMILES: COc1ccccc1Nc1ccc(-c2cc(C(C)(C)C)cc(C(C)(C)C)c2)cc1[N+](=O)[O-]]

Yield: 18%. ¹H NMR (500 MHz, CDCl₃) δ 9.48 (s, 1H), 8.43 (d, J=2.2 Hz, 1H), 7.65 (dd, J=8.9, 2.2 Hz, 1H), 7.45-7.41 (m, 2H), 7.37 (dd, J=8.9, 5.3 Hz, 3H), 7.21-7.16 (m, 1H), 7.03-6.97 (m, 2H), 3.90 (s, 3H), 1.38 (s, 18H).

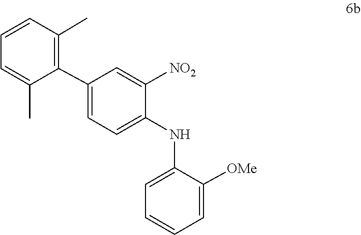 [SMILES: COc1ccccc1Nc1ccc(-c2c(C)cccc2C)cc1[N+](=O)[O-]]

Yield: 41%. ¹H NMR (500 MHz, CDCl₃) δ 9.50 (s, 1H), 8.02 (s, 1H), 7.46 (d, J=7.6 Hz, 1H), 7.37 (d, J=8.8 Hz, 1H), 7.18 (dd, J=11.6, 7.8 Hz, 3H), 7.11 (d, J=7.3 Hz, 2H), 7.02 (d, J=8.4 Hz, 2H), 3.91 (s, 3H), 2.08 (s, 6H).

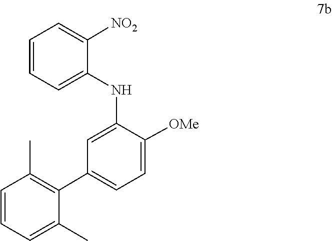 [SMILES: COc1ccc(-c2c(C)cccc2C)cc1Nc1ccccc1[N+](=O)[O-]]

Yield: 71%. ¹H NMR (500 MHz, CDCl₃) δ 9.52 (s, 1H), 8.19 (dd, J=8.6, 1.4 Hz, 1H), 7.38-7.32 (m, 1H), 7.30 (dd, J=8.6, 1.2 Hz, 1H), 7.21-7.14 (m, 2H), 7.11 (d, J=7.4 Hz, 2H), 7.05 (d, J=8.3 Hz, 1H), 6.94 (dd, J=8.3, 2.0 Hz, 1H), 6.75 (ddd, J=8.4, 6.8, 1.4 Hz, 1H), 3.93 (s, 3H), 2.10 (s, 6H). HRMS (ESI) for [M+H]⁺: m/z calcd 349.1554, found 349.1544.

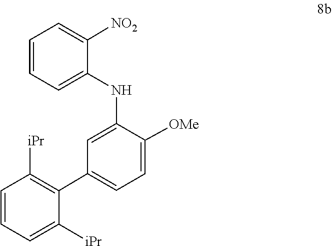 [SMILES: COc1ccc(-c2c(C(C)C)cccc2C(C)C)cc1Nc1ccccc1[N+](=O)[O-]]

Yield: 70%. ¹H NMR (400 MHz, CDCl₃) δ 9.50 (s, 1H), 8.19 (d, J=8.5 Hz, 1H), 7.39-7.27 (m, 3H), 7.20 (d, J=7.3 Hz, 3H), 7.03 (d, J=8.3 Hz, 1H), 6.94 (d, J=8.3 Hz, 1H), 6.75 (t, J=7.6 Hz, 1H), 3.95 (s, 3H), 2.73 (dt, J=13.7, 6.8 Hz, 2H), 1.12 (dd, J=6.7, 2.6 Hz, 12H). HRMS (ESI) for [M+H]⁺: m/z calcd 405.2180, found 405.2170.

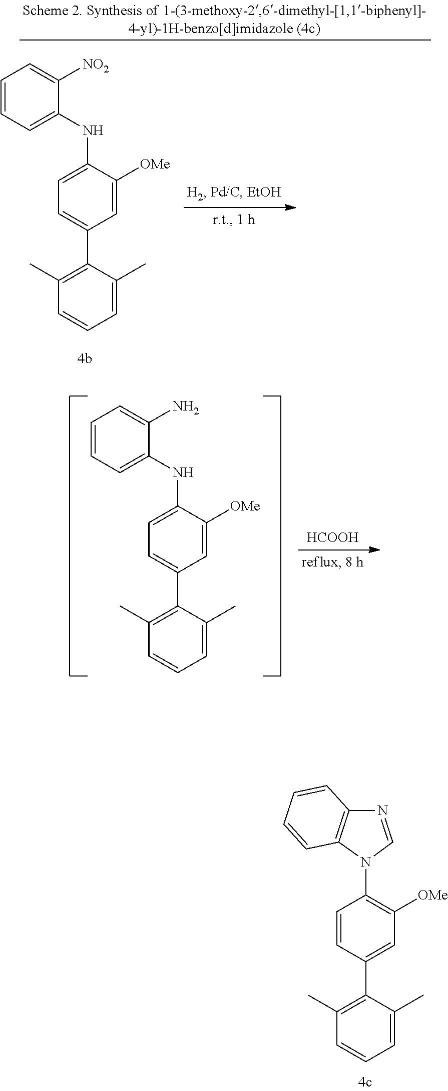

In a 300 mL round-bottom flask, 3.58 g (10.3 mmol, 1 equiv) of 3-methoxy-2′, 6′-dimethyl-N-(2-nitrophenyl)-[1,1′-biphenyl]-4-amine (4b) was dissolved in 150 mL ethanol and 0.79 g of Pd/C(10 wt %) was added. The mixture was purged with hydrogen and stirred at room temperature for 1 h. After the full conversion of 4b, the mixture was passed through ciliate with DCM as eluent and concentrated under reduced pressure. 25 mL (0.66 mol, 64 equiv) of HCOOH was added and refluxed for 12 h. After confirming completion via TLC, the reaction was quenched with NaHCO₃ solution, extracted with DCM three times, and dried under Na₂SO₄. The solvent was removed under reduced pressure and the product was purified by flash chromatography on silica gel (eluent: n-hexane/acetone=4/1), affording an off-white solid. (Yield: 2.89 g, 86%). ¹H NMR (400 MHz, CDCl₃) δ 8.19 (s, 1H), 7.89 (d, J=7.1 Hz, 1H), 7.48 (d, J=8.2 Hz, 1H), 7.42-7.37 (m, 1H), 7.37-7.31 (m, 2H), 7.25-7.20 (m, 1H), 7.17 (d, J=7.4 Hz, 2H), 6.92 (d, J=6.5 Hz, 2H), 3.78 (s, 3H), 2.14 (s, 6H).

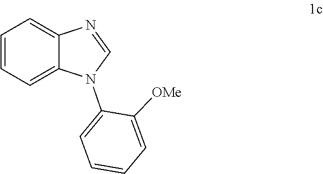 [SMILES: COc1ccccc1-n1cnc2ccccc21]

Yield: 93%. ¹H NMR (400 MHz, CDCl₃) δ 8.08 (s, 1H), 7.87 (d, J=8.5 Hz, 1H), 7.50-7.38 (m, 2H), 7.31 (s, 1H), 7.29 (t, J=1.8 Hz, 2H), 7.13 (d, J=7.9 Hz, 2H), 3.80 (s, 3H).

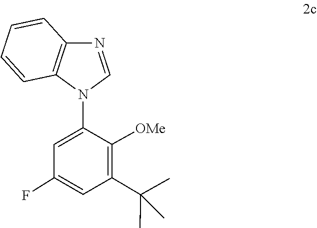 [SMILES: COc1c(-n2cnc3ccccc32)cc(F)cc1C(C)(C)C]

Yield: 85%. ¹H NMR (400 MHz, CDCl₃) δ 8.16 (s, 1H), 7.94-7.85 (m, 1H), 7.43-7.34 (m, 3H), 7.17 (dd, J=10.5, 3.1 Hz, 1H), 7.03 (dd, J=7.6, 3.1 Hz, 1H), 3.06 (s, 3H), 1.44 (s, 9H). ¹⁹F NMR (377 MHz, CDCl₃) δ −116.83 (dd, J=10.5, 7.8 Hz).

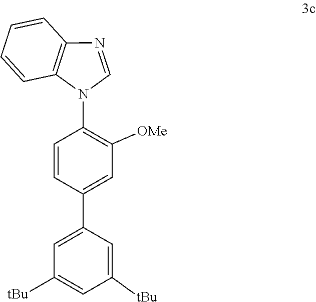 [SMILES: COc1cc(-c2cc(C(C)(C)C)cc(C(C)(C)C)c2)ccc1-n1cnc2ccccc21]

Yield: 97%. ¹H NMR (400 MHz, CDCl₃) δ 8.12 (s, 1H), 7.93-7.83 (m, 1H), 7.52 (t, J=1.7 Hz, 1H), 7.48 (d, J=8.0 Hz, 1H), 7.45 (d, J=1.7 Hz, 2H), 7.37 (d, J=2.5 Hz, 1H), 7.32 (dt, J=4.2, 2.3 Hz, 2H), 7.30 (d, J=1.6 Hz, 1H), 7.29 (s, 1H), 3.87 (s, 3H), 1.42 (s, 18H).

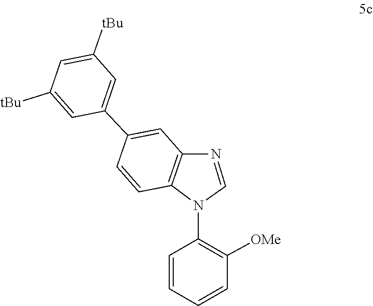 [SMILES: COc1ccccc1-n1cnc2cc(-c3cc(C(C)(C)C)cc(C(C)(C)C)c3)ccc21]

Yield: 87%. ¹H NMR (400 MHz, CDCl₃) δ 8.13 (s, 1H), 8.10 (d, J=0.7 Hz, 1H), 7.54 (d, J=8.5 Hz, 1H), 7.51 (d, J=1.7 Hz, 2H), 7.49-7.42 (m, 3H), 7.35 (d, J=8.5 Hz, 1H), 7.15 (t, J=7.4 Hz, 2H), 3.84 (s, 3H), 1.40 (s, 18H).

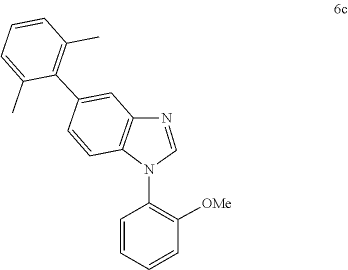 [SMILES: COc1ccccc1-n1cnc2cc(-c3c(C)cccc3C)ccc21]

Yield: 58%. ¹H NMR (400 MHz, CDCl₃) δ 8.14 (s, 1H), 7.64 (s, 1H), 7.53-7.43 (m, 2H), 7.37 (d, J=8.2 Hz, 1H), 7.21-7.11 (m, 5H), 7.06 (d, J=8.3 Hz, 1H), 3.86 (s, 3H), 2.07 (s, 6H).

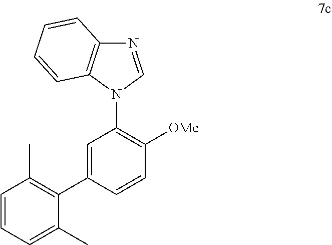 [SMILES: COc1ccc(-c2c(C)cccc2C)cc1-n1cnc2ccccc21]

Yield: 88%. ¹H NMR (400 MHz, CDCl₃) δ 8.17 (s, 1H), 7.87 (d, J=7.6 Hz, 1H), 7.32 (t, J=6.7 Hz, 3H), 7.22-7.15 (m, 2H), 7.13 (d, J=7.2 Hz, 2H), 3.87 (s, 3H), 2.13 (s, 6H). HRMS (ESI) for [M+H]⁺: m/z calcd 329.1656, found 329.1647.

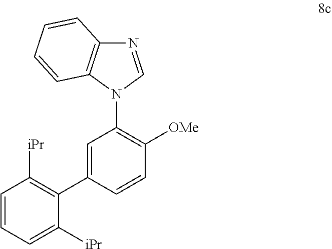 [SMILES: COc1ccc(-c2c(C(C)C)cccc2C(C)C)cc1-n1cnc2ccccc21]

Yield: 80%. ¹H NMR (400 MHz, CDCl₃) δ 8.18 (s, 1H), 7.87 (d, J=7.8 Hz, 1H), 7.34 (dt, J=13.2, 6.8 Hz, 3H), 7.28 (d, J=6.9 Hz, 2H), 7.22 (d, J=7.9 Hz, 3H), 7.18 (d, J=8.4 Hz, 1H), 3.88 (s, 3H), 2.73 (dt, J=13.6, 6.8 Hz, 2H), 1.22-1.06 (m, 12H).

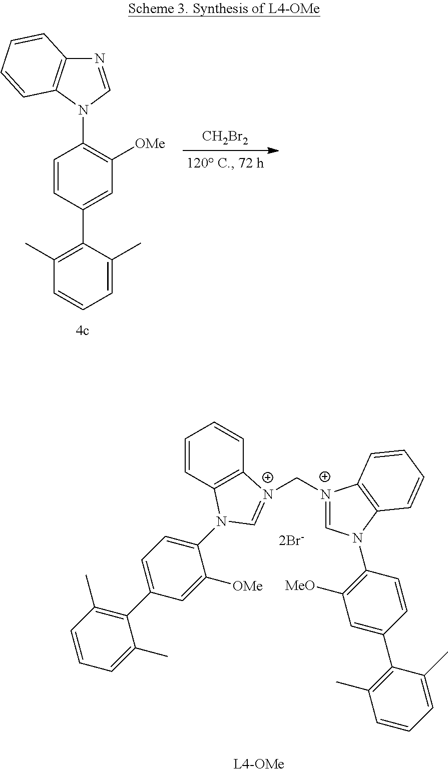

In a 50 mL seal tube, 2.89 mg (8.81 mmol, 1 equiv) of 1-(3-methoxy-2′, 6′-dimethyl-[1,1′-biphenyl]-4-yl)-1H-benzo[d]imidazole (4c) was dissolved in 7 mL CH₂Br₂ (0.1001 mol, 11.4 equiv.) affording a clear solution, and stirred under 120° C. for 72 h. The mixture was then cooled to room temperature, added to 150 mL THF, and flittered. The resulting solid was washed with THF and ether and then dried under vacuum, affording an off-white solid of 1.81 g (Yield: 49%). ¹H NMR (400 MHz, DMSO) δ 10.77 (s, 1H), 8.60 (d, J=8.2 Hz, 1H), 7.90 (d, J=7.2 Hz, 1H), 7.85-7.68 (m, 3H), 7.64 (s, 1H), 7.29 (s, 1H), 7.21 (dd, J=16.6, 6.6 Hz, 3H), 7.09 (d, J=7.6 Hz, 1H), 3.85 (s, 3H), 2.09 (s, J=8.5 Hz, 6H). HRMS (ESI) for [M²⁺-2Br-]: m/z calcd 335.1648, found 335.1647.

Working-up method for Ln-OMe: after the reaction, the mixture was added to excess ether, and off-white solid formed. The solid was separated using centrifugation and dissolved in a small amount of DCM. Ether was added into the DCM solution to precipitate the solid, and the dissolve-precipitation was repeated three times, obtaining a white solid.

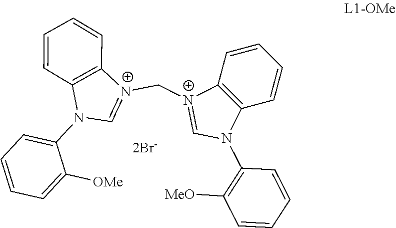 [SMILES: COc1ccccc1-n1c[n+](C[n+]2cn(-c3ccccc3OC)c3ccccc32)c2ccccc21]

Yield: 64%. ¹H NMR (500 MHz, DMSO) δ 10.67 (s, 1H), 8.55 (d, J=8.5 Hz, 1H), 7.87 (t, J=7.8 Hz, 1H), 7.75 (t, J=7.9 Hz, 2H), 7.70 (t, J=9.4 Hz, 2H), 7.59 (s, 1H), 7.51 (d, J=8.4 Hz, 1H), 7.31 (t, J=7.6 Hz, 1H), 3.85 (s, 3H).

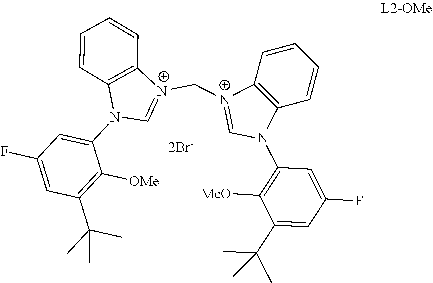 [SMILES: COc1c(-n2c[n+](C[n+]3cn(-c4cc(F)cc(C(C)(C)C)c4OC)c4ccccc43)c3ccccc32)cc(F)cc1C(C)(C)C]

Yield: 77%. ¹H NMR (400 MHz, DMSO) δ 10.81 (s, 1H), 8.58 (d, J=8.2 Hz, 1H), 7.90 (t, 1H), 7.79 (d, J=7.6 Hz, 1H), 7.73 (s, 1H), 7.71 (s, 1H), 7.53 (d, J=11.0 Hz, 1H), 7.47 (d, J=8.0 Hz, 1H), 3.19 (s, 3H), 1.43 (s, 9H).

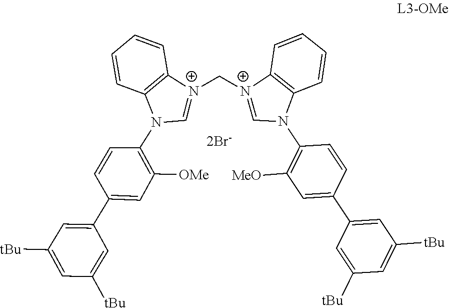 [SMILES: COc1cc(-c2cc(C(C)(C)C)cc(C(C)(C)C)c2)ccc1-n1c[n+](C[n+]2cn(-c3ccc(-c4cc(C(C)(C)C)cc(C(C)(C)C)c4)cc3OC)c3ccccc32)c2ccccc21]

Yield: 37%. ¹H NMR (500 MHz, DMSO) δ 10.79 (d, J=8.0 Hz, 1H), 8.62 (d, J=8.5 Hz, 1H), 7.92-7.87 (m, 1H), 7.83-7.79 (m, 2H), 7.78 (s, 1H), 7.68 (s, 1H), 7.63 (s, 1H), 7.54 (t, J=8.5 Hz, 4H), 3.98 (s, 2H), 1.39 (s, 18H).

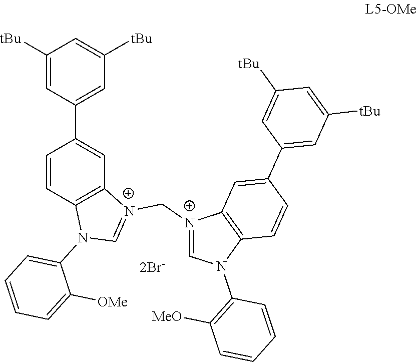 [SMILES: COc1ccccc1-n1c[n+](C[n+]2cn(-c3ccccc3OC)c3ccc(-c4cc(C(C)(C)C)cc(C(C)(C)C)c4)cc32)c2cc(-c3cc(C(C)(C)C)cc(C(C)(C)C)c3)ccc21]

Yield: 84%. ¹H NMR (400 MHz, DMSO) δ 10.79 (s, 1H), 8.65 (s, 1H), 8.00 (d, J=8.7 Hz, 1H), 7.80 (d, J=7.8 Hz, 1H), 7.75 (d, J=6.5 Hz, 1H), 7.73 (s, 1H), 7.70 (s, 1H), 7.47 (d, J=3.7 Hz, 4H), 7.31 (t, 1H), 3.74 (s, 3H), 1.27 (s, 18H).

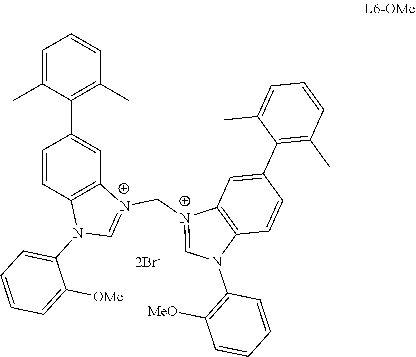 [SMILES: COc1ccccc1-n1c[n+](C[n+]2cn(-c3ccccc3OC)c3ccc(-c4c(C)cccc4C)cc32)c2cc(-c3c(C)cccc3C)ccc21]

Yield: 36%. ¹H NMR (500 MHz, DMSO) δ 10.76 (s, 1H), 8.34 (s, 1H), 7.75 (d, J=8.4 Hz, 3H), 7.60 (s, 1H), 7.51 (dd, J=8.4, 3.7 Hz, 2H), 7.32 (t, J=7.6 Hz, 1H), 7.28-7.21 (m, 1H), 7.15 (d, J=7.6 Hz, 3H), 3.83 (s, 3H), 1.89 (s, 6H).

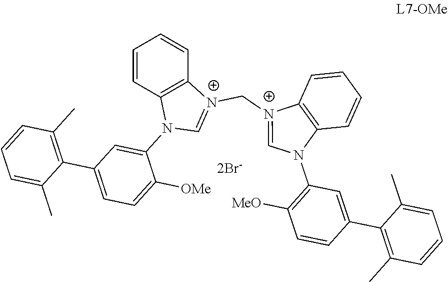 [SMILES: COc1ccc(-c2c(C)cccc2C)cc1-n1c[n+](C[n+]2cn(-c3cc(-c4c(C)cccc4C)ccc3OC)c3ccccc32)c2ccccc21]

Yield: 68%. ¹H NMR (500 MHz, DMSO) δ 10.69 (s, 1H), 8.53 (d, J=8.3 Hz, 1H), 7.88 (t, J=7.8 Hz, 1H), 7.77 (t, J=7.7 Hz, 1H), 7.72 (d, J=8.6 Hz, 1H), 7.56 (dd, J=15.1, 8.4 Hz, 4H), 7.19 (d, J=7.7 Hz, 1H), 7.14 (d, J=7.6 Hz, 2H), 3.88 (s, 3H), 2.07 (d, J=12.5 Hz, 6H).

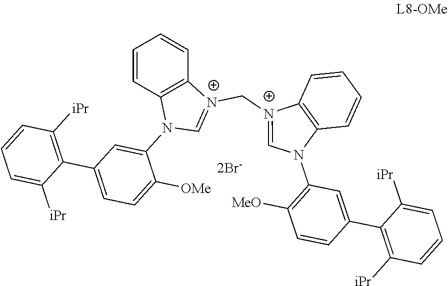 [SMILES: COc1ccc(-c2c(C(C)C)cccc2C(C)C)cc1-n1c[n+](C[n+]2cn(-c3cc(-c4c(C(C)C)cccc4C(C)C)ccc3OC)c3ccccc32)c2ccccc21]

Yield: 65%. ¹H NMR (500 MHz, DMSO) δ 10.78 (s, 1H), 8.59 (t, J=6.7 Hz, 1H), 7.86 (dd, J=15.7, 7.8 Hz, 1H), 7.77 (t, J=7.7 Hz, 1H), 7.69-7.63 (m, 2H), 7.56 (s, 1H), 7.53 (d, J=8.9 Hz, 1H), 7.43-7.34 (m, 2H), 7.23 (t, J=8.4 Hz, 3H), 3.88 (s, J=5.4 Hz, 3H), 2.61(dt, J=13.7, 7.2 Hz, 2H), 1.06 (t, J=12.6 Hz, 12H).

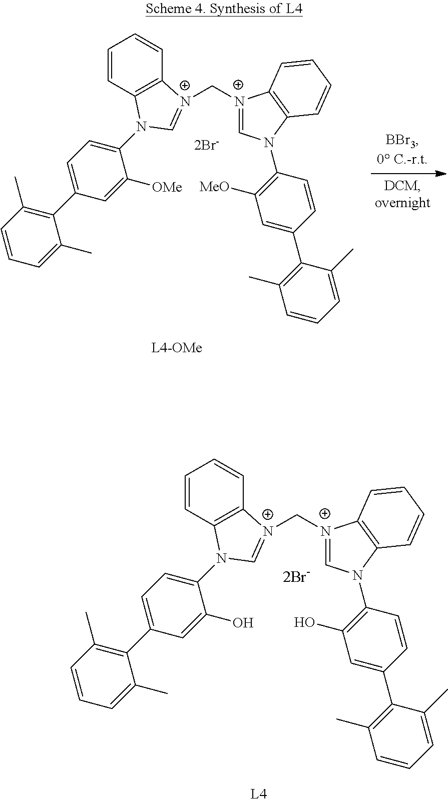

An oven-dried 50 mL Schlenk flask with a stirring bar was pump-refill-pump three times. Under the protection of argon, 290 mg (0.349 mmol, 1 equiv.) of L4-OMe was added and then pump-refilled again to ensure an inert atmosphere. 30 mL of anhydrous DCM was added under the protection of argon to afford a white suspension. 3 mL of BBr₃ solution (6.98 mmol, 20 equiv 2 mol/L dissolved in DCM) was added dropwise under an ice bath in 15 min and the solution turned clear. The mixture was then stirred at room temperature for 12 h. After the reaction, methanol (5 mL) was added slowly to quench the reaction under an ice bath, and the solvent was then removed under reduced pressure. The remaining solid was washed with water, acetone, and ether, affording a white solid of 240 mg (Yield: 86%). ¹H NMR (400 MHz, DMSO) δ 11.11 (s, 1H), 10.79 (s, 1H), 8.62 (d, J=8.5 Hz, 1H), 7.89 (t, J=7.6 Hz, 1H), 7.77 (dt, J=22.1, 8.2 Hz, 3H), 7.67 (s, 1H), 7.19 (dd, J=16.9, 6.6 Hz, 3H), 7.00 (s, 1H), 6.94 (d, J=8.1 Hz, 1H), 2.08 (s, 6H).

Working-up method for other ligands: the quenched reaction mixture was rotated to dryness as illustrated in L4. The remaining brown solid was dissolved in DCM and washed with saturated NaCl solution three times. The DCM phase was dried with MgSO₄, filtered, and concentrated. Ether was added into the DCM solution to precipitate the solid, and the dissolve-precipitation was repeated three times, obtaining a white solid.

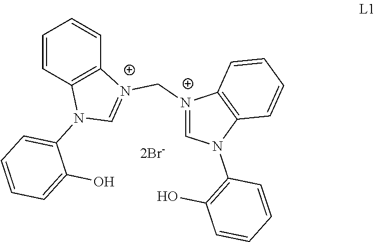 [SMILES: Oc1ccccc1-n1c[n+](C[n+]2cn(-c3ccccc3O)c3ccccc32)c2ccccc21]

Yield: 35%. ¹H NMR (400 MHz, DMSO) δ 10.92 (s, 1H), 10.81 (s, 1H), 8.62 (d, J=8.4 Hz, 1H), 7.85 (t, J=7.8 Hz, 1H), 7.75 (t, J=7.8 Hz, 1H), 7.71 (s, 1H), 7.69-7.63 (m, 2H), 7.61-7.52 (m, 1H), 7.29 (d, J=8.0 Hz, 1H), 7.15 (t, J=7.6 Hz, 1H).

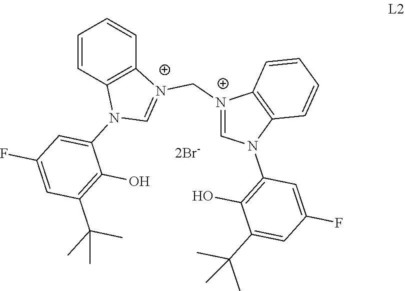 [SMILES: CC(C)(C)c1cc(F)cc(-n2c[n+](C[n+]3cn(-c4cc(F)cc(C(C)(C)C)c4O)c4ccccc43)c3ccccc32)c1O]

Yield: 78%. ¹H NMR (500 MHz, DMSO) δ 10.68 (s, 1H), 9.49 (s, 1H), 8.56 (d, J=8.1 Hz, 1H), 7.88 (s, 1H), 7.77 (s, 2H), 7.56 (d, J=8.1 Hz, 1H), 7.48 (d, J=4.8 Hz, 1H), 7.40 (d, J=9.7 Hz, 1H), 1.42 (s, 9H). ¹⁹F NMR (377 MHz, DMSO) δ −121.57 (t, J=9.1 Hz).

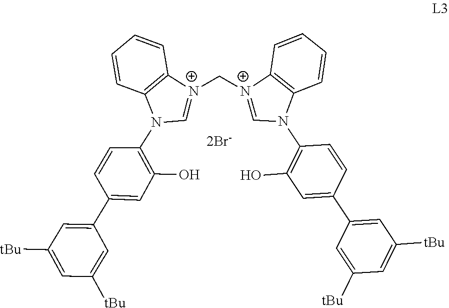 [SMILES: CC(C)(C)c1cc(-c2ccc(-n3c[n+](C[n+]4cn(-c5ccc(-c6cc(C(C)(C)C)cc(C(C)(C)C)c6)cc5O)c5ccccc54)c4ccccc43)c(O)c2)cc(C(C)(C)C)c1]

Yield: 53%. 1H NMR (400 MHz, DMSO) δ 11.09 (s, 1H), 10.72 (s, 1H), 8.60 (d, J=8.3 Hz, 1H), 7.87 (d, J=8.2 Hz, 1H), 7.77 (d, J=6.5 Hz, 2H), 7.71 (d, J=8.3 Hz, 1H), 7.66 (s, 1H), 7.51 (s, 1H), 7.46 (dd, J=6.1, 4.7 Hz, 4H), 1.37 (s, 18H).

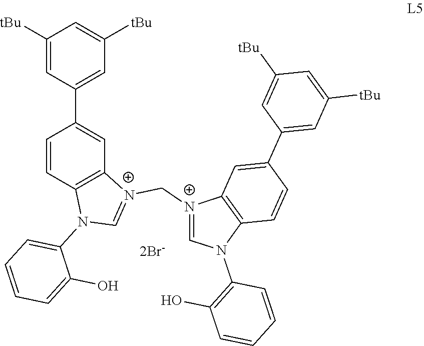 [SMILES: CC(C)(C)c1cc(-c2ccc3c(c2)[n+](C[n+]2cn(-c4ccccc4O)c4ccc(-c5cc(C(C)(C)C)cc(C(C)(C)C)c5)cc42)cn3-c2ccccc2O)cc(C(C)(C)C)c1]

Yield: 87%. ¹H NMR (500 MHz, DMSO) δ 10.96 (s, 1H), 10.68 (s, 1H), 8.68 (s, 1H), 8.01 (d, J=8.5 Hz, 1H), 7.77-7.64 (m, 3H), 7.59 (t, J=7.6 Hz, 1H), 7.47 (s, 3H), 7.27 (d, J=8.0 Hz, 1H), 7.16 (t, J=7.5 Hz, 1H), 1.27 (s, 18H).

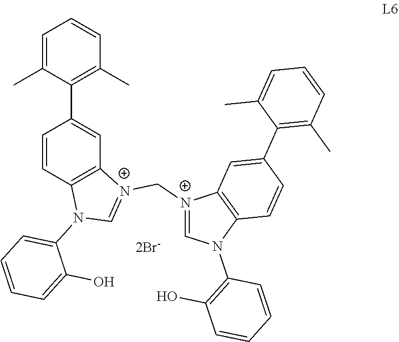 [SMILES: Cc1cccc(C)c1-c1ccc2c(c1)[n+](C[n+]1cn(-c3ccccc3O)c3ccc(-c4c(C)cccc4C)cc31)cn2-c1ccccc1O]

Yield: 99%. ¹H NMR (400 MHz, DMSO) δ 10.97 (s, 1H), 10.69 (s, 1H), 8.41 (s, 1H), 7.73 (d, J=8.5 Hz, 1H), 7.62 (d, J=8.3 Hz, 1H), 7.60-7.54 (m, 2H), 7.52 (d, J=8.5 Hz, 1H), 7.28 (d, J=8.2 Hz, 1H), 7.24 (d, J=7.4 Hz, 1H), 7.16 (d, J=6.8 Hz, 3H), 1.91 (s, 6H).

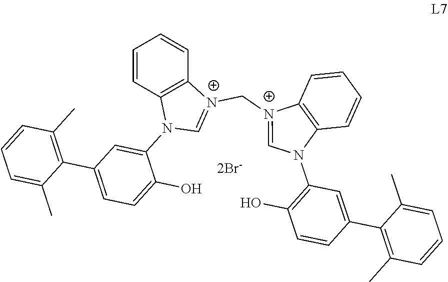 [SMILES: Cc1cccc(C)c1-c1ccc(O)c(-n2c[n+](C[n+]3cn(-c4cc(-c5c(C)cccc5C)ccc4O)c4ccccc43)c3ccccc32)c1]

Yield: 84%. ¹H NMR (400 MHz, DMSO) δ 11.00 (s, 1H), 10.75 (s, 1H), 8.57 (d, J=8.4 Hz, 1H), 7.85 (d, J=7.9 Hz, 1H), 7.77 (t, J=7.7 Hz, 1H), 7.69 (d, J=8.3 Hz, 1H), 7.64 (s, 1H), 7.46 (s, 1H), 7.35 (s, 2H), 7.15 (dd, J=17.8, 6.8 Hz, 3H), 2.06 (s, 6H).

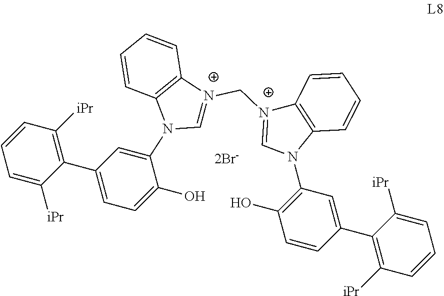 [SMILES: CC(C)c1cccc(C(C)C)c1-c1ccc(O)c(-n2c[n+](C[n+]3cn(-c4cc(-c5c(C(C)C)cccc5C(C)C)ccc4O)c4ccccc43)c3ccccc32)c1]

Yield: 87%. ¹H NMR (500 MHz, DMSO) δ 11.05 (s, 1H), 10.63 (s, 1H), 8.56 (d, J=8.4 Hz, 1H), 7.86 (t, J=7.8 Hz, 1H), 7.78 (t, J=7.8 Hz, 1H), 7.63 (d, J=8.3 Hz, 1H), 7.60 (s, 1H), 7.36 (ddd, J=24.3, 11.6, 6.3 Hz, 4H), 7.21 (d, J=7.8 Hz, 2H), 2.67-2.60 (m, 2H), 1.04 (dd, J=30.4, 6.9 Hz, 12H).

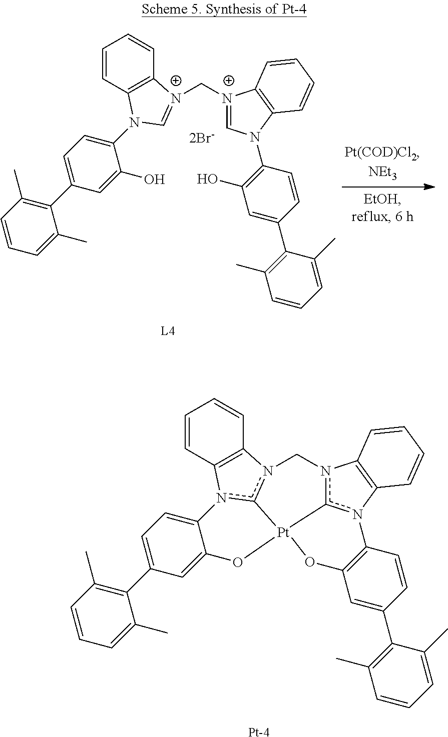

To a 50 mL flame-dried two-neck flask filled with argon, the 100 mg of L4 (0.125 mmol, 1 equiv.) and 47 mg of Pt(COD)Cl₂ (0.126 mmol, 1.01 eq) was suspended in 8 mL EtOH. 0.42 mL Et₃N (3.01 mmol, 24 equiv.) was added and the mixture was dissolved and refluxed under an inert atmosphere overnight. After the completion of the reaction, the mixture was cooled to room temperature as a white suspension. The solid was filtered, and washed with cold EtOH and ether. After high vacuum drying, the product was obtained as a white powder. (Yield: 40%)¹H NMR (500 MHz, CD₂Cl₂) δ 8.13 (d, J=7.8 Hz, 1H), 7.78 (d, J=8.1 Hz, 1H), 7.73 (d, J=7.8 Hz, 1H), 7.47 (dd, J=16.8, 8.0 Hz, 2H), 7.12 (dd, J=16.6, 6.4 Hz, 3H), 6.92 (s, 1H), 6.70 (s, 1H), 6.49 (d, J=8.1 Hz, 1H), 2.16 (s, 6H). HRMS (ESI) for [M+H]⁺: m/z calcd 834.2410, found 834.2399. Anal calcd. C₄₃H₃₄N₄O₂Pt·4C₂H₅OH·CH₂Cl₂ C 57.03%, H 4.79%, N 5.54%, found C 57.78%, H 4.37%, N 5.58%

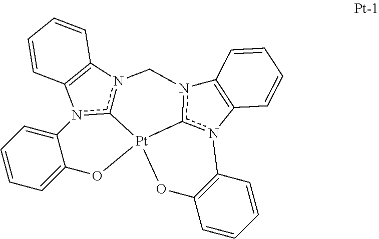

Yield: 15%. ¹H NMR (400 MHz, CD₂Cl₂) δ 8.16 (d, J=8.2 Hz, 1H), 7.78 (d, J=8.2 Hz, 1H), 7.71 (d, J=8.2 Hz, 1H), 7.55 (s, 1H), 7.49 (s, 1H), 7.13 (s, 2H), 6.72 (s, 1H), 6.52 (s, 1H). HRMS (ESI) for [M+H]⁺: m/z calcd 625.1180, found 626.1141. Anal calcd. C₂₇H₁₈N₄O₂Pt·H₂O C 50.36%, H 3.33%, N 7.99%, found C 50.22%, H 3.29%, N 7.99%

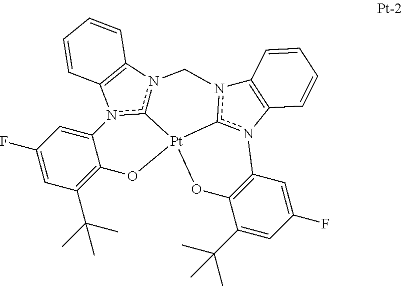

Yield: 10%. ¹H NMR (600 MHz, CD₂Cl₂) δ 8.18 (d, J=8.2 Hz, 1H), 7.68 (d, J=8.0 Hz, 1H), 7.56 (t, J=7.5 Hz, 1H), 7.52 (t, J=7.8 Hz, 1H), 7.48 (dd, J=9.4, 3.1 Hz, 1H), 7.06 (dd, J=10.5, 3.1 Hz, 1H), 6.48 (s, 1H), 1.56 (s, 9H). ¹⁹F NMR (377 MHz, CD₂Cl₂) δ −131.28 (t, J=10.1 Hz). HRMS (ESI) for [M+H]⁺: m/z calcd 774.2221, found 774.2248.

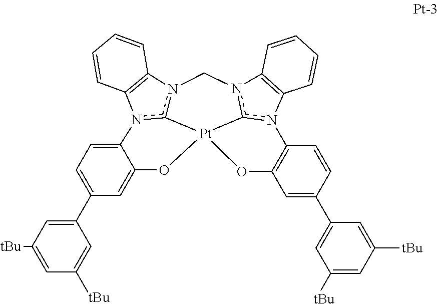

Yield: 81%. ¹H NMR (600 MHz, CD₂Cl₂) δ 8.24 (d, J=7.9 Hz, 1H), 7.88 (d, J=8.3 Hz, 1H), 7.73 (d, J=7.9 Hz, 1H), 7.60-7.48 (m, 5H), 7.45 (s, 1H), 7.01 (d, J=8.3 Hz, 1H), 6.55 (s, 1H), 1.41 (s, 18H). HRMS (ESI) for C₅₅H₅₈N₄O₂Pt [M+H]⁺: m/z calcd 1002.4288, found 1002.4284.

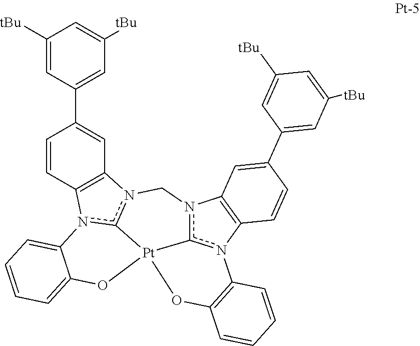

Yield: 52%. ¹H NMR (500 MHz, CD₂Cl₂) δ 7.97 (d, J=8.7 Hz, 1H), 7.87 (s, 1H), 7.66 (d, J=7.6 Hz, 1H), 7.62-7.54 (m, 4H), 6.93 (d, J=8.7 Hz, 2H), 6.71 (d, J=7.9 Hz, 1H), 6.57 (t, 1H), 1.47 (s, 18H). HRMS (ESI) for [M+H]⁺: m/z calcd 1002.4288, found 1002.4248.

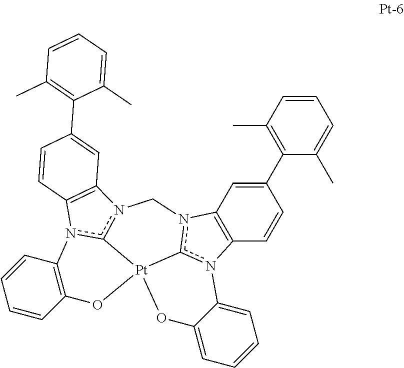

Yield: 10%. ¹H NMR (500 MHz, CD₂Cl₂) δ 8.19 (d, J=8.5 Hz, 1H), 7.84 (d, J=8.0 Hz, 1H), 7.42 (s, 1H), 7.26 (d, J=8.5 Hz, 1H), 7.20 (d, J=6.7 Hz, 1H), 7.14 (dd, J=12.1, 7.4 Hz, 3H), 7.08 (s, 1H), 6.72 (s, 1H), 6.53 (s, 1H), 2.07 (s, 6H). HRMS (ESI) for [M+H]⁺: m/z calcd 834.2410, found 834.2411.

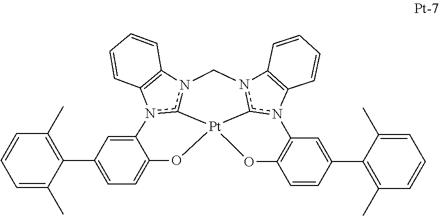

Yield: 21%. ¹H NMR (400 MHz, DMSO) δ 8.26 (d, J=9.1 Hz, 1H), 7.96 (d, J=9.1 Hz, 1H), 7.60 (d, J=6.6 Hz, 1H), 7.55 (d, J=8.0 Hz, 1H), 7.50 (s, 1H), 7.13 (s, 4H), 6.99 (s, 1H), 6.91 (d, J=8.4 Hz, 1H), 2.10 (s, 6H). HRMS (ESI) for [M+H]⁺: m/z calcd 834.2410, found 834.2380. Anal calcd. 5C₄₃H₃₄N₄O₂Pt·15CH₂Cl₂·2C₄H₁₀O C 51.13%, H 3.96%, N 5.01%, found C 51.06%, H 3.69%, N 5.05%.

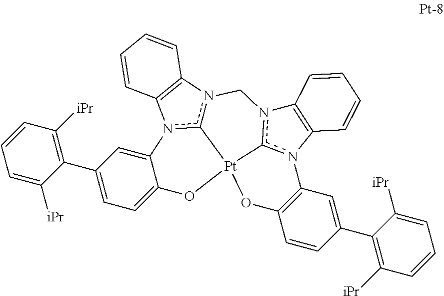

Yield: 21%. ¹H NMR (500 MHz, CD₂Cl₂) δ 7.86 (d, J=8.3 Hz, 1H), 7.75 (d, J=8.1 Hz, 1H), 7.47 (t, J=7.8 Hz, 1H), 7.43 (s, 1H), 7.34-7.26 (m, 2H), 7.19 (d, J=7.7 Hz, 2H), 7.06 (d, J=8.3 Hz, 1H), 6.87 (d, J=8.4 Hz, 1H), 6.77 (s, 1H), 2.93-2.82 (m, 2H), 1.11 (t, J=7.0 Hz, 12H). HRMS (ESI) for [M+H]⁺: m/z calcd 946.3662, found 946.3648.

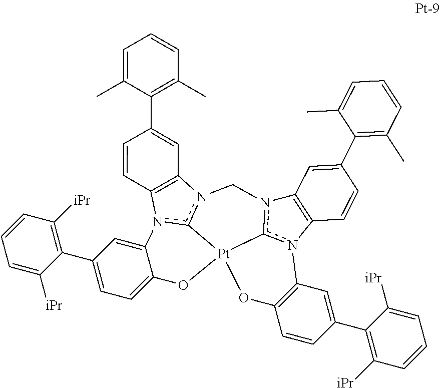

Yield: 18%. ¹H NMR (60 MHz, CD₂Cl₂) δ=8.03 (d, J=8.4 Hz, 2H), 7.60 (d, J=2.1 Hz, 2H), 7.41 (d, J=1.5 Hz, 2H), 7.31 (t, J=7.7 Hz, 2H), 7.24-7.14 (m, 10H), 7.12 (t, J=8.3 Hz, 4H), 6.95 (d, J=8.1 Hz, 2H), 6.56 (s, 2H), 3.04-2.78 (m, 4H), 2.08-1.93 (m, 12H), 1.21-0.97 (m, 24H).

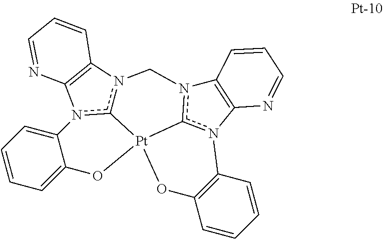

Yield: 22%. ¹H NMR (600 MHz, DMSO-d₆) δ 9.28 (dd, J=8.3, 1.7 Hz, 2H), 8.63 (dq, J=4.9, 1.5 Hz, 4H), 7.70 (dd, J=7.9, 4.9 Hz, 2H), 7.27-7.02 (m, 2H), 7.03-6.80 (m, 4H), 6.67 (ddd, J=8.4, 6.9, 1.6 Hz, 2H).

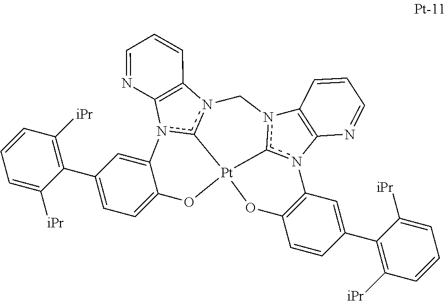

Yield: 20%. ¹H NMR (600 MHz, CD₂Cl₂) δ 8.95 (d, J=2.2 Hz, 2H), 8.47 (dd, J=4.8, 1.4 Hz, 2H), 8.04 (dd, J=8.2, 1.4 Hz, 2H), 7.43 (dd, J=8.1, 4.8 Hz, 2H), 7.32 (t, J=7.8 Hz, 2H), 7.21 (d, J=8.0 Hz, 6H), 6.97 (dd, J=8.3, 2.1 Hz, 2H), 6.61 (s, 2H), 2.95-2.86 (m, 4H), 1.12 (dd, J=6.8, 1.2 Hz, 24H).

### Fabrication and Characterization of OLEDs

OLEDs were fabricated in a Kurt J. Lesker SPECTROS vacuum deposition system with a base pressure of 10⁻⁸ mbar. In the vacuum chamber, organic materials were thermally deposited in sequence at a rate of ˜0.1 nm s⁻¹. The doping process in the emitting layer was realized by co-deposition technology. LiF (1.2 nm) and Al (100 nm) were thermally deposited at rates of 0.03 and 0.2 nm s⁻¹, respectively. Film thicknesses were determined in situ by calibrated oscillating quartz-crystal sensors. EL spectra, J-L-V characteristics, CIE coordinates, EQE, CE and PE were measured using a Keithley 2400 source-meter and an absolute external quantum efficiency measurement system (C9920-12, Hamamatsu Photonics). All devices were characterized at room temperature without encapsulation.

### Results

### Photophysical Properties of Platinum(II) Complexes

A series of Pt(II)-O\hat{ }C*\hat{ }C*\hat{ }O complexes were prepared and characterized. The Pt(II) complexes contain: (i) benzimidazole based NHC (e.g., Pt-1 to Pt-8); (ii) phenolate with different bulky substitutions (e.g., Pt-3, Pt-4, Pt-7, and Pt-8); and (iii) two types of bulky phenyl groups, 3,5-di-tertbutyl-phenyl (ditBuPh) and 2,6-dimethyl-phenyl (diMePh), in addition to the p-extension at NHC (e.g., Pt-5 and Pt-6). The structural features of the Pt(II) complexes lead to tremendous increment in PLQY and radiative decay rate constant, compared to the previously reported imidazole-based Pt(II)-O\hat{ }C*\hat{ }C*\hat{ }O complexes, see, e.g., Chem. Commun. 2011, 47, 9075; Chem. Sci. 2013, 4, 2630. Without being bound to any theories, the improvement in the emission properties of the Pt(II) complexes may be ascribed to the geometrical changes in metal complexes and the extended π-conjugation of acceptor units.

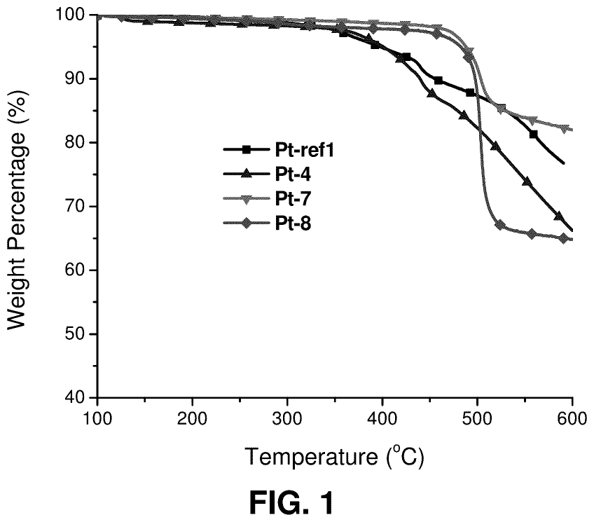

The thermal stability of complexes Pt-4, Pt-7, and Pt-8, in comparison with the reference complex Pt-ref1, was examined using thermogravimetric analysis (TGA). As shown in FIG. 1 and the data in Table 1, Pt-7 and Pt-8 were thermally stable compared to their counterparts, with a decomposition temperature τ_{d}≥400° C.

TABLE 1
Estimated T_{d} of Pt-4, Pt-7, and
Pt-8, in comparison with Pt-ref1.

| Complex | T_{d} (° C.) |
|---|---|
| Pt-ref1 | 398 |
| Pt-4 | 403 |
| Pt-7 | 486 |
| Pt-8 | 483 |

T_{d} refers to the temperature at which the weight percentage loss reaches 5%

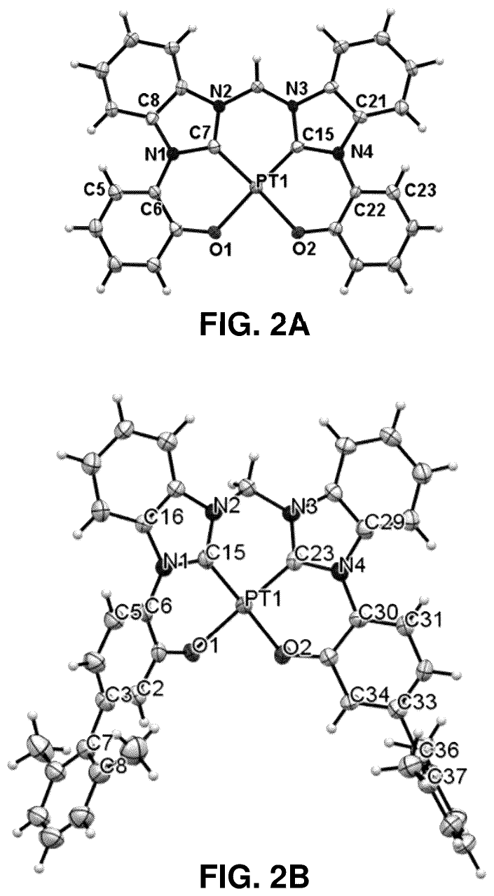

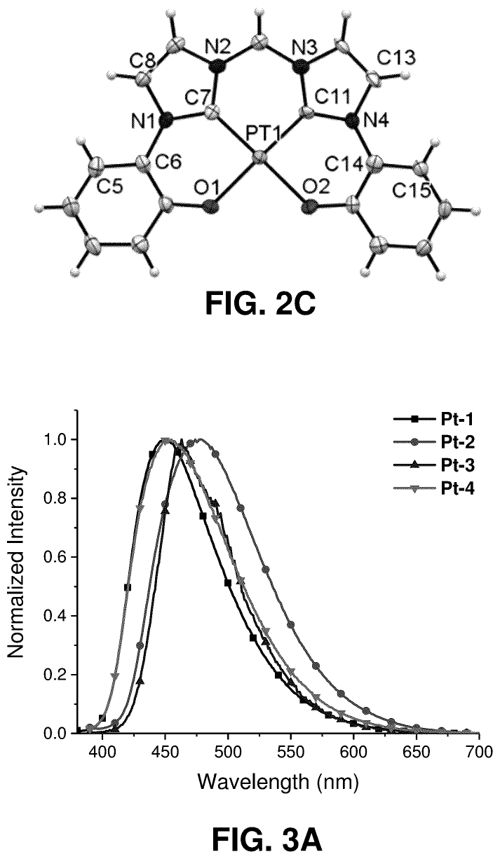

The X-ray single crystal structures of Pt-1 and Pt-4, in comparison with a reference Pt(II) complex, Pt-ref1, are illustrated in FIGS. 2A-2C. The bond length and bond angles of Pt-1 and Pt-4, in comparison with reference complexes, Pt-ref1 and Pt-ref2, are shown in Tables 2-5.

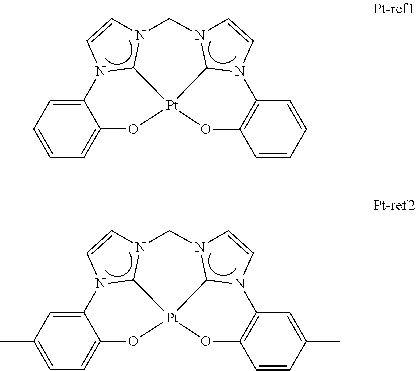

Pt-1 and Pt-4 show a slightly distorted square planar structure with the C—Pt—O angles of ˜176°, smaller than that of complex Pt-ref1, ˜178°. The two Pt-C and two Pt-O bonds in Pt-1 and Pt-4 are shortened compared to those in Pt-ref1, indicating stronger metal-ligand bonds in Pt-1 and Pt-4. Different from Pt-ref1, whose NHC and phenolate moieties are arranged on the same side of the coordinative plane with the dihedral angle at 9.08° and −5.69°, the two moieties in Pt-1 and Pt-4 are arranged on different sides of the coordinative plane and are more twisted with a dihedral angle at 24.57° and −26.14° between the two moieties for Pt-1 and −21.56° and 31.20° for Pt-4. These result in the reduced planarity and changed orientation between the NHC and the phenolate ring observed in Pt-1 and Pt-4.

TABLE 2
Selected bond lengths (Å),
bond angles (°) of Pt-1
Pt-1

| Bond Lengths (Å) | | | |
|---|---|---|---|
| Pt-O1 | 2.028 | Pt-Pt | 3.269 |
| Pt-O2 | 2.031 | | |
| Pt-C7 | 1.907 | | |
| Pt-C15 | 1.919 | | |
| Bond Angles (°) | | | |
| C15-Pt-C7 | 91.20 | C15-Pt1-O1 | 175.68 |
| C7-Pt-01 | 91.31 | C7-Pt1-O2 | 175.80 |
| O1-Pt-O2 | 85.17 | | |
| O2-Pt-C15 | 92.18 | | |

TABLE 3
Selected bond lengths (Å), bond angles
(°), and dihedral angles (°) of Pt-4
Pt-4

| Bond Lengths (Å) | | | |
|---|---|---|---|
| Pt-O1 | 2.008 | Pt-Pt | 7.205 |
| Pt-O2 | 2.045 | | |
| Pt-C7 | 1.909 | | |
| Pt-C11 | 1.915 | | |
| Bond Angles (°) | | | |
| C15-Pt-C7 | 91.11 | C15-Pt1-O1 | 177.96 |
| C7-Pt-O1 | 91.35 | C7-Pt1-O2 | 176.81 |
| O1-Pt-O2 | 87.24 | | |
| O2-Pt-C15 | 90.25 | | |
| Dihedral Angles (°) | | | |
| C16-N1-C6-C5 | −21.56 | C29-N4-C30-C31 | 31.20 |
| C2-C3-C7-C8 | 110.44 | C34-C33-C36-C37 | −101.75 |

TABLE 4
Selected bond lengths (Å), bond angles (°) of Pt-ref1
Pt-ref1

| Bond Lengths (Å) | | | |
|---|---|---|---|
| Pt-O1 | 2.042 | Pt-Pt | 3.579 |
| Pt-O2 | 2.050 | | |
| Pt-C7 | 1.926 | | |
| Pt-C11 | 1.917 | | |
| Bond Angles (°) | | | |
| C11-Pt-C7 | 90.50 | C11-Pt1-O1 | 177.47 |
| C7-Pt-O1 | 90.60 | C7-Pt1-O2 | 178.15 |
| O1-Pt-O2 | 88.71 | | |
| O2-Pt-C11 | 90.11 | | |

TABLE 5
Selected bond lengths (Å), bond angles (°) of Pt-ref2
(data from Chem. Commun. 2011, 47, 9075-9077)
Pt-ref2

| Bond Lengths (Å) | |
|---|---|
| Pt-O1 | 2.053(5) |
| Pt-C10 | 1.933(8) |
| Bond Angles (°) | |
| C10-Pt-C10 | 91.5(4) |
| C10-Pt-O1 | 90.3(3) |
| O1-Pt-O1 | 87.8(3) |

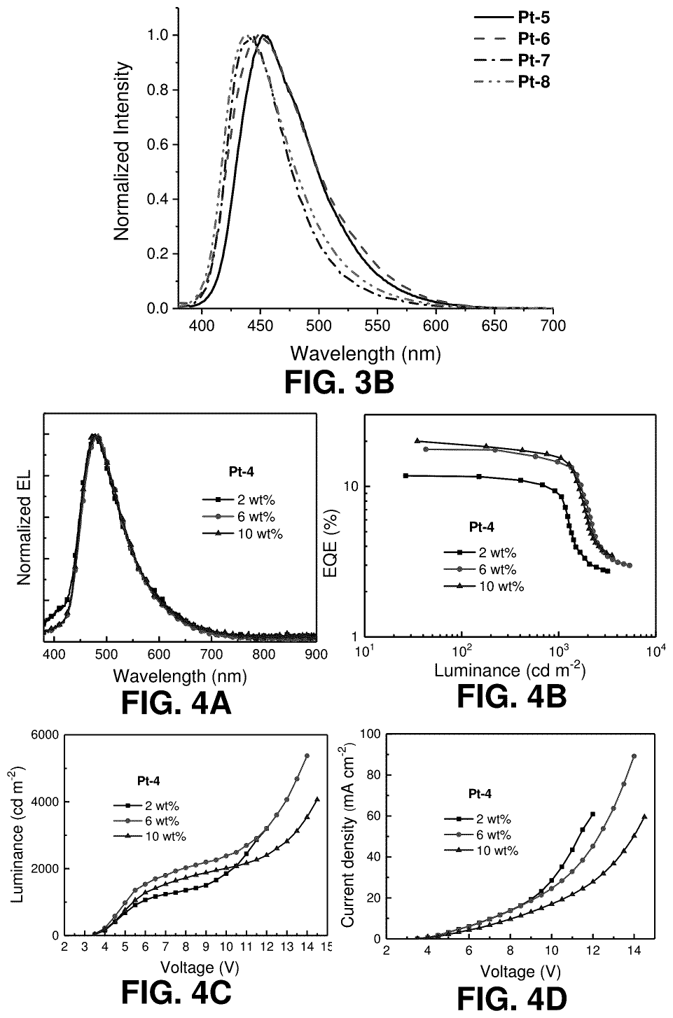

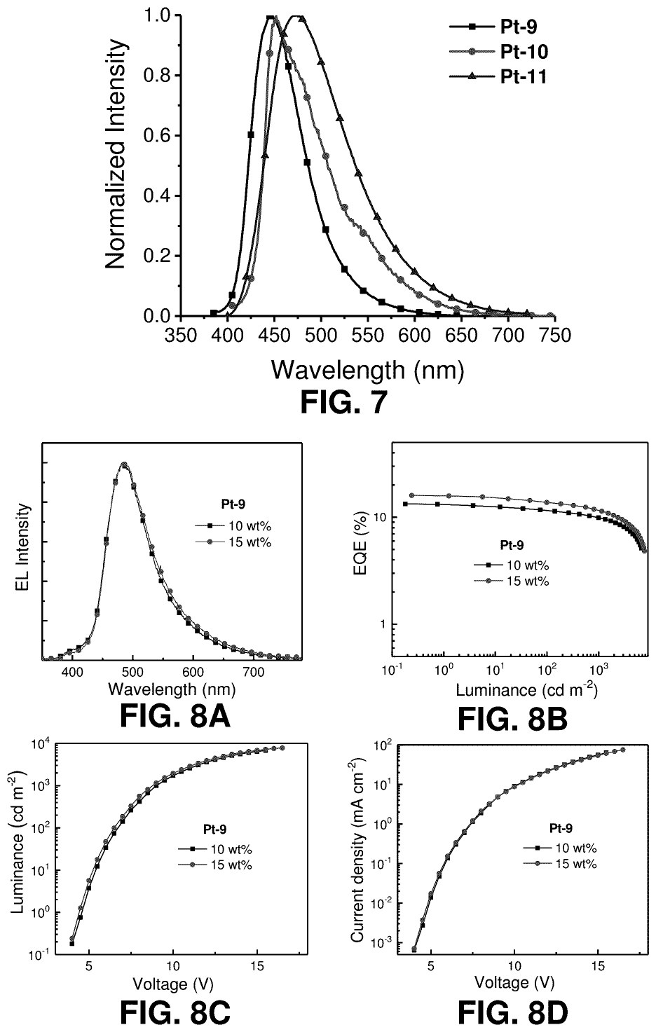

The emission data for the exemplary Pt(II) blue emitters are shown in FIGS. 3A and 31B, and summarized in Table 6. The Pt(II) complexes showed blue emission in PMMA thin film with high PLQY up to 83% and fast radiative rate (kᵣ>10⁵ s⁻¹ for Pt-1, Pt-4, Pt-7, and Pt-8). The emission bandwidths of Pt-7 and Pt-8 were narrower than those of Pt-1, Pt-4, and Pt-6. In particular, Pt-7 showed a PLQY reaching 80% with a radiative decay rate at 3.4×10⁵ s⁻¹ which is suitable as a light-emitting dopant or sensitizer in blue OLEDs. The emission data for additional exemplary Pt(II) blue emitters are shown in FIG. 7, and summarized in Table 9.

TABLE 6
Summary of emission data for Pt-blue emitters

| Emitter | Medium | λₑₘ [nm] | FWHM [nm] | Φ | τ [μs] | kᵣ [×10⁴ s⁻¹] |
|---|---|---|---|---|---|---|
| Pt-1 | 1 wt % | 449 | 81 | 33 | 3.00 | 11.0 |
| | in PMMA | | | | | |
| Pt-2 | 1 wt % | 474 | 97 | 49 | 7.95 | 6.2 |
| | in PMMA | | | | | |
| Pt-3 | 1 wt % | 463 | 68 | 36 | 48.7 | 0.74 |
| | in PMMA | | | | | |
| Pt-4 | 1 wt % | 454 | 92 | 62 | 5.3 | 11.7 |
| | in PMMA | | | | | |
| Pt-5 | 1 wt % | 453 | 70 | 50 | 20.9 | 2.4 |
| | in PMMA | | | | | |
| Pt-6 | 1 wt % | 449 | 79 | 33 | 4.93 | 6.7 |
| | in PMMA | | | | | |
| Pt-7 | 1 wt % | 444 | 57 | 80 | 2.34 | 34.2 |
| | in PMMA | | | | | |
| Pt-8 | 1 wt % | 441 | 64 | 83 | 4.66 | 17.8 |
| | in PMMA | | | | | |
| Pt-ref1 | 1 wt % | 443 | 87 | 27 | 7.81 | 3.5 |
| | in PMMA | | | | | |

TABLE 9
Summary of emission data for Pt-9, Pt-10, and Pt-11

| Emitter | Medium | λₑₘ [nm] | FWHM [nm] | Φ | τ [μs] | kᵣ [×10⁴ s⁻¹] |
|---|---|---|---|---|---|---|
| Pt-9 | 1 wt % | 447 | 65 | 85 | 5.09 | 16.7 |
| | in PMMA | | | | | |
| Pt-10 | 1 wt % | 454 | 70 | 24 | 0.55 | 43.6 |
| | in PMMA | | | | | |
| Pt-11 | 1 wt % | 473 | 97 | 81 | 4.04 | 20.0 |
| | in PMMA | | | | | |

### OLED Performance

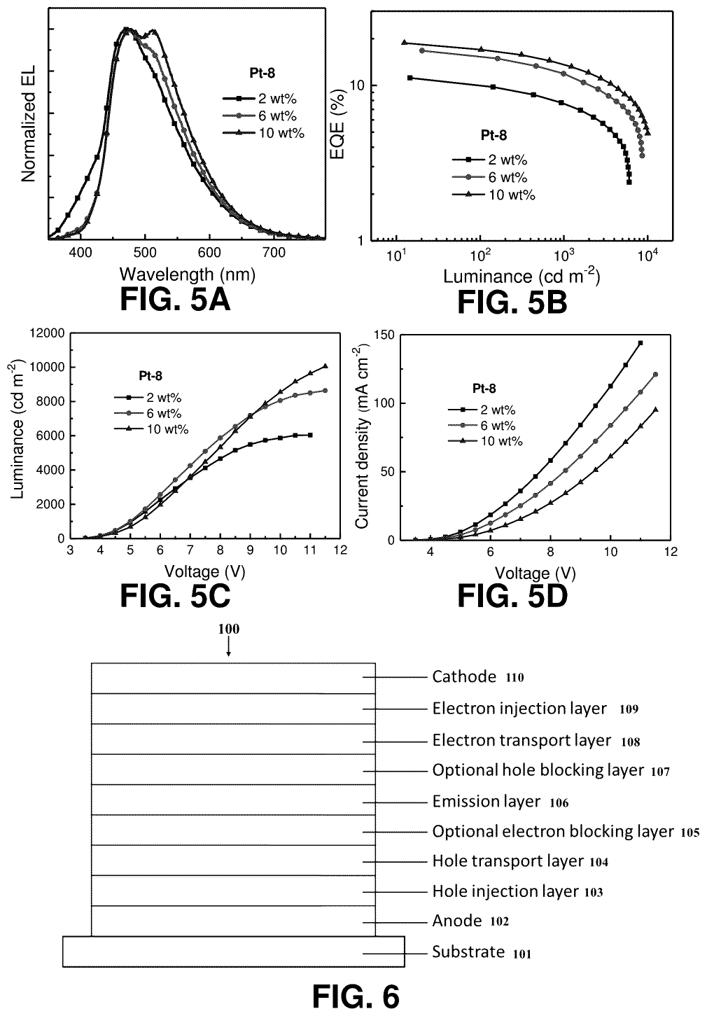

OLED devices fabricated with Pt-4 were tested, and the performance data are shown in FIGS. 4A-4D and summarized in Table 7. OLED devices fabricated with Pt-8 were tested, and the performance data are shown in FIGS. 5A-5D and summarized in Table 8. OLED devices fabricated with Pt-9 were tested, and the performance data are shown in FIGS. 8A-8D and summarized in Table 10.

TABLE 7
Summary of performance of OLEDs* based on Pt-4.

| | | Lₘₐₓ^{a} | CE^{b} | PE^{c} | EQE^{d} | λ_{EL}^{e} | FWHM^{f} | CIE^{g} |
|---|---|---|---|---|---|---|---|---|
| Dopant | | [cd m⁻²] | [cd A⁻¹] | [lm W⁻¹] | [%] | [nm] | [nm] | [(x, y)] |
| 2 | wt % | 3200 | 25.0/17.5 | 22.4/9.16 | 11.8/8.55 | 472 | 93 | (0.22, 0.31) |
| 6 | wt % | 5400 | 38.7/31.5 | 34.7/19.8 | 17.6/14.5 | 480 | 92 | (0.22, 0.33) |
| 10 | wt % | 4060 | 43.4/32.8 | 38.9/18.7 | 20.0/15.4 | 478 | 91 | (0.22, 0.32) |

^{a}Maximum luminance:
^{b}Current efficiency maximum/at 1000 cd m⁻²;
^{c}Power efficiency maximum/at 1000 cd m⁻²;
^{d}External quantum efficiency maximum/at 1000 cd m⁻²;
^{e}EL wavelength;
^{f}Full width at half maximum;
^{g}Commission International de L'Eclairage (CIE) coordinates.
*Device structure: ITO/HAT-CN (5 nm)/TAPC (30 nm)/TCTA (5 nm)/CzSi (3 nm)/Pt-4: CzSi: BCPO (18 nm)/TSPO1 (30 nm)/LiF(1.2 nm)/Al (100 nm)

TABLE 8
Summary of performance of OLEDs* based on Pt-8.

| | | Lₘₐₓ^{a} | CE^{b} | PE^{c} | EQE^{d} | λ_{EL}^{e} | FWHM^{f} | CIE^{g} |
|---|---|---|---|---|---|---|---|---|
| Dopant | | [cd m⁻²] | [cd A⁻¹] | [lm W⁻¹] | [%] | [nm] | [nm] | [(x, y)] |
| 2 | wt % | 6040 | 23.9/15.4 | 21.4/9.71 | 11.2/7.66 | 471 | 118 | (0.22, 0.30) |
| 6 | wt % | 8630 | 38.2/26.3 | 34.3/16.5 | 16.7/11.9 | 475 | 122 | (0.23, 0.34) |
| 10 | wt % | 10500 | 45.1/32.1 | 40.5/19.4 | 18.7/13.8 | 478 | 131 | (0.24, 0.36) |

^{a}Maximum luminance;
^{b}Current efficiency maximum/at 1000 cd m⁻²;
^{c}Power efficiency maximum/at 1000 cd m⁻²;
^{d}External quantum efficiency maximum/at 1000 cd m⁻²;
^{e}EL wavelength;
^{f}Full width at half maximum;
^{g}Commission International de L'Eclairage (CIE) coordinates.
*Device structure: ITO/HAT-CN (5 nm)/TAPC (30 nm)/TCTA (5 nm)/CzSi (3 nm)/Pt-8: CzSi: BCPO (32 nm)/TSPO1 (30 nm)/LiF(1.2 nm)/Al (100 nm)

TABLE 10
Summary of performance of OLEDs* based on Pt-9.

| | | Lₘₐₓ^{a} | CE^{b} | PE^{c} | EQE^{d} | λ_{EL}^{e} | FWHM^{f} | CIE^{g} |
|---|---|---|---|---|---|---|---|---|
| Dopant | | [cd m⁻²] | [cd A⁻¹] | [lm W⁻¹] | [%] | [nm] | [nm] | [(x, y)] |
| 10 | wt % | 6800 | 27.8/20.6 | 21.8/7.21 | 13.3/9.90 | 482 | 82 | (0.21, 0.34) |
| 15 | wt % | 7740 | 33.9/24.7 | 26.7/8.84 | 16.0/11.6 | 483 | 86 | (0.22, 0.35) |

^{a}Maximum luminance;
^{b}Current efficiency maximum/at 1000 cd m⁻²;
^{c}Power efficiency maximum/at 1000 cd m⁻²;
^{d}External quantum efficiency maximum/at 1000 cd m⁻²;
^{e}EL wavelength;
^{f}Full width at half maximum;
^{g}Commission International de L'Eclairage (CIE) coordinates.
*Device structure: ITO/HAT-CN (5 nm)/TAPC (40 nm)/TCTA (7 nm)/CzSi (3 nm)/Pt-9: CzSi (20 nm)/TSPO1 (30 nm)/LiF (1.2 nm)/Al (100 nm)

Unless defined otherwise, all technical and scientific terms used herein have the same meanings as commonly understood by one of skill in the art to which the disclosed invention belongs. Publications cited herein and the materials for which they are cited are specifically incorporated by reference. Further, unless otherwise indicated, use of the expression “wt %” refers to “wt/wt %.”

Those skilled in the art will recognize, or be able to ascertain using no more than routine experimentation, many equivalents to the specific embodiments of the invention described herein. Such equivalents are intended to be encompassed by the following claims.

We claim:

1. A platinum(II) complex having a structure: 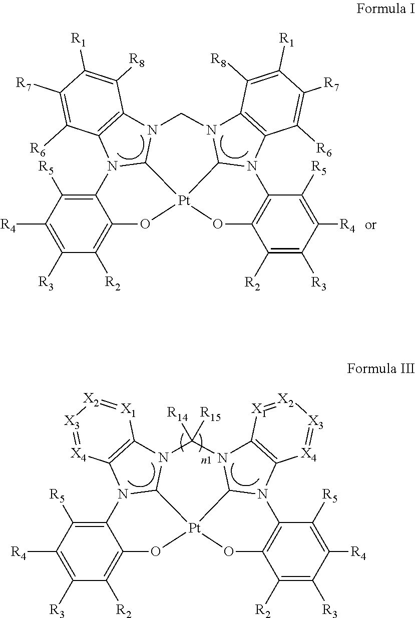
wherein:
(i) each occurrence of X₁-X₄ is independently nitrogen or CR₁₆;
(ii) each occurrence of R₁-R₈ and R₁₆ is independently hydrogen, a halide (e.g., fluoride, chloride, bromide, iodide, etc.), hydroxyl, amino, amido, thiol, cyano, nitro, alkoxy, carbonyl, a substituted or unsubstituted C₁-C₁₂ alkyl, a substituted or unsubstituted C₁-C₁₂ alkenyl, a substituted or unsubstituted C₁-C₁₂ alkynyl, a substituted or unsubstituted aryl (e.g., phenyl), a substituted or unsubstituted heteroaryl, a substituted or unsubstituted polyaryl, or a substituted or unsubstituted heteropolyaryl, or two neighboring R groups together with the carbon atoms to which they are attached can form a substituted or unsubstituted aryl, a substituted or unsubstituted heteroaryl, a substituted or unsubstituted polyaryl, or a substituted or unsubstituted heteropolyaryl;
(iii) n1 is an integer from 1 to 6, from 1 to 5, from 1 to 4, from 1 to 3, or 1 or 2;
(iv) R₁₄ and R₁₅ are independently hydrogen, a substituted or unsubstituted C₁-C₁₂ alkyl, a substituted or unsubstituted C₁-C₁₂ alkenyl, or a substituted or unsubstituted C₁-C₁₂ alkynyl, or R₁₄ and R₁₅ of two neighboring carbon atoms, together with the carbon atoms to which they are attached, can form a substituted or unsubstituted aryl, a substituted or unsubstituted heteroaryl, a substituted or unsubstituted polyaryl, or a substituted or unsubstituted heteropolyaryl; and
(v) the substituent(s), when present, are independently an unsubstituted C₁-C₁₂ alkyl, an unsubstituted C₁-C₁₂ alkenyl, an unsubstituted C₁-C₁₂ alkynyl, an unsubstituted aryl (e.g., phenyl), a substituted aryl (e.g., phenyl) by unsubstituted aryl(s) (e.g., unsubstituted phenyls) and/or unsubstituted alkyl(s) (e.g., unsubstituted C₁-C₁₂ alkyl), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), an amino, or a halide.

2. The platinum(II) complex of claim 1, wherein the platinum(II) has a structure:

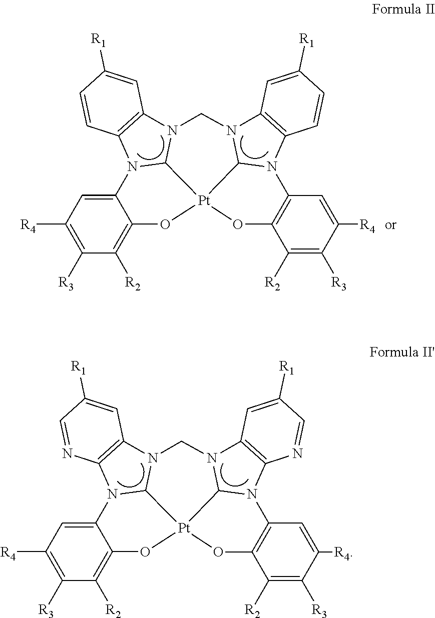

3. The platinum(II) complex of claim 1, wherein X₁ and X₄ are independently nitrogen or CR₁₆; X₂ and X₃ are CR₁₆; R₁₆ is hydrogen, halide, an unsubstituted C₁-C₁₂ alkyl, an unsubstituted aryl, or an aryl substituted by unsubstituted C₁-C₁₂ alkyl(s); R₂-R₅ are independently hydrogen, amino, an unsubstituted C₁-C₁₂ alkyl, a substituted or unsubstituted aryl, a substituted or unsubstituted heteroaryl, a substituted or unsubstituted polyaryl, or a substituted or unsubstituted heteropolyaryl, or R₂ and R₃, R₃ and R₄, or R₄ and R₅ together with the carbon atoms to which they are attached form a substituted or unsubstituted aryl, a substituted or unsubstituted heteroaryl, a substituted or unsubstituted polyaryl, or a substituted or unsubstituted heteropolyaryl; and the substituent(s), when present, are independently an unsubstituted C₁-C₁₂ alkyl, an unsubstituted aryl (e.g., phenyl), a substituted aryl (e.g., phenyl) by unsubstituted aryl(s) (e.g., phenyls) and/or unsubstituted alkyl(s), an unsubstituted heteroaryl, a substituted heteroaryl by unsubstituted aryl(s) and/or unsubstituted alkyl(s), an unsubstituted polyaryl, a substituted polyaryl by unsubstituted aryl(s) and/or unsubstituted alkyl(s), an unsubstituted heteropolyaryl, a substituted heteropolyaryl by unsubstituted aryl(s) and/or unsubstituted alkyl(s), or an amino.

4. The platinum(II) complex of claim 1, wherein each occurrence of R₁-R₈ is independently hydrogen, a halide, a substituted or unsubstituted C₁-C₁₂ alkyl, a substituted or unsubstituted C₁-C₁₂ alkenyl, a substituted or unsubstituted C₁-C₁₂ alkynyl, a substituted or unsubstituted aryl, a substituted or unsubstituted heteroaryl, a substituted or unsubstituted polyaryl, a substituted or unsubstituted polyaryl, or a substituted or unsubstituted heteropolyaryl.

5. The platinum(II) complex of claim 4, wherein each occurrence of R₁-R₈ is independently hydrogen, a halide, a substituted or unsubstituted C₁-C₁₂ alkyl, or a substituted or unsubstituted aryl.

6. The platinum(II) complex of claim 4, wherein each occurrence of R₁-R₈ is independently hydrogen, a halide (e.g., fluoride, chloride, or bromide), an unsubstituted C₁-C₁₂ alkyl (e.g., an unsubstituted C₁-C₆ alkyl, an unsubstituted C₁-C₄ alkyl, or an unsubstituted C₁-C₃ alkyl, such as methyl, ethyl, n-propyl, isopropyl, n-butyl, isobutyl, tert-butyl, etc.), or 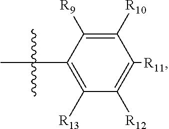
and wherein R₉-R₁₃ are independently hydrogen, an unsubstituted C₁-C₁₂ alkyl, an unsubstituted phenyl, an unsubstituted heteropolyaryl, or an amino,
optionally wherein R₉-R₁₃ are independently hydrogen or an unsubstituted C₁-C₆ alkyl (e.g., methyl, ethyl, n-propyl, isopropyl, n-butyl, isobutyl, tert-butyl, etc.).

7. The platinum(II) complex of claim 1, wherein the platinum(II) complex has any one of the structures:

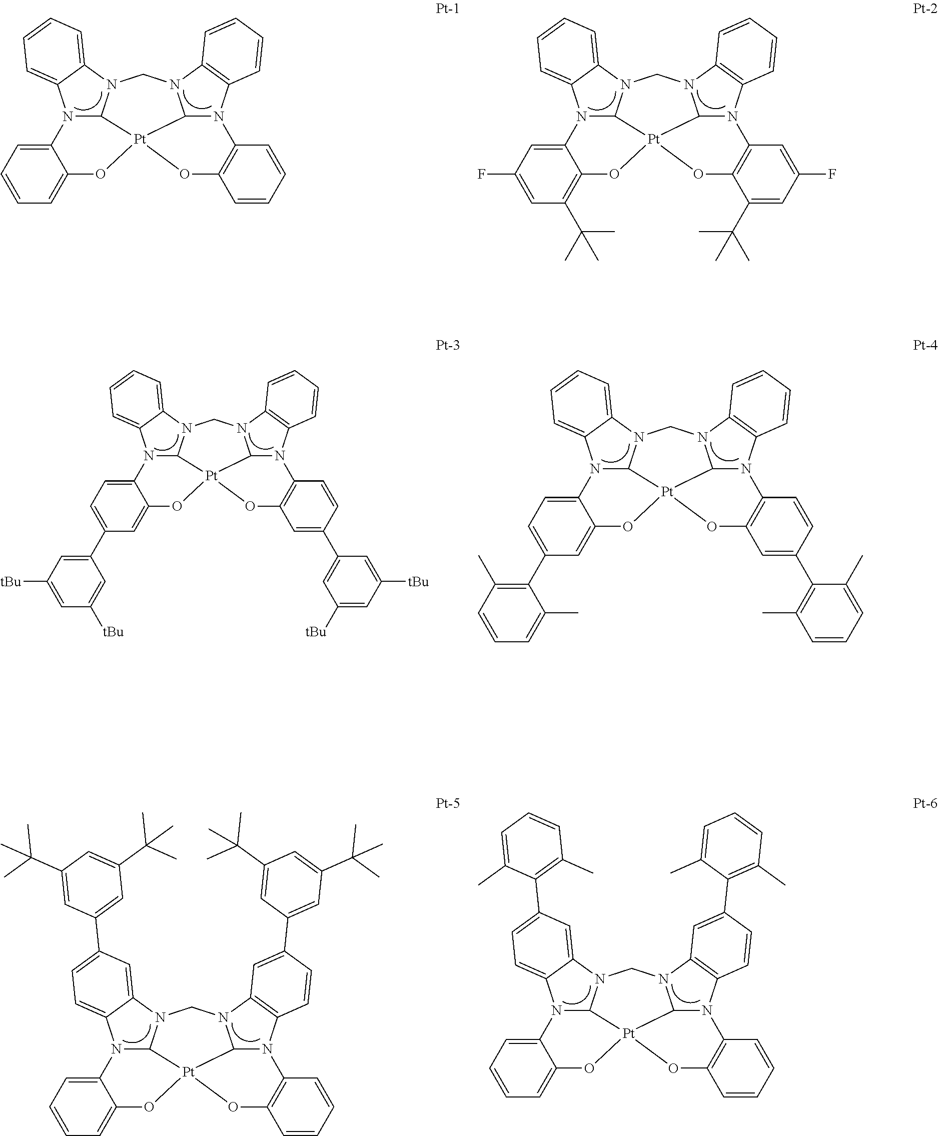

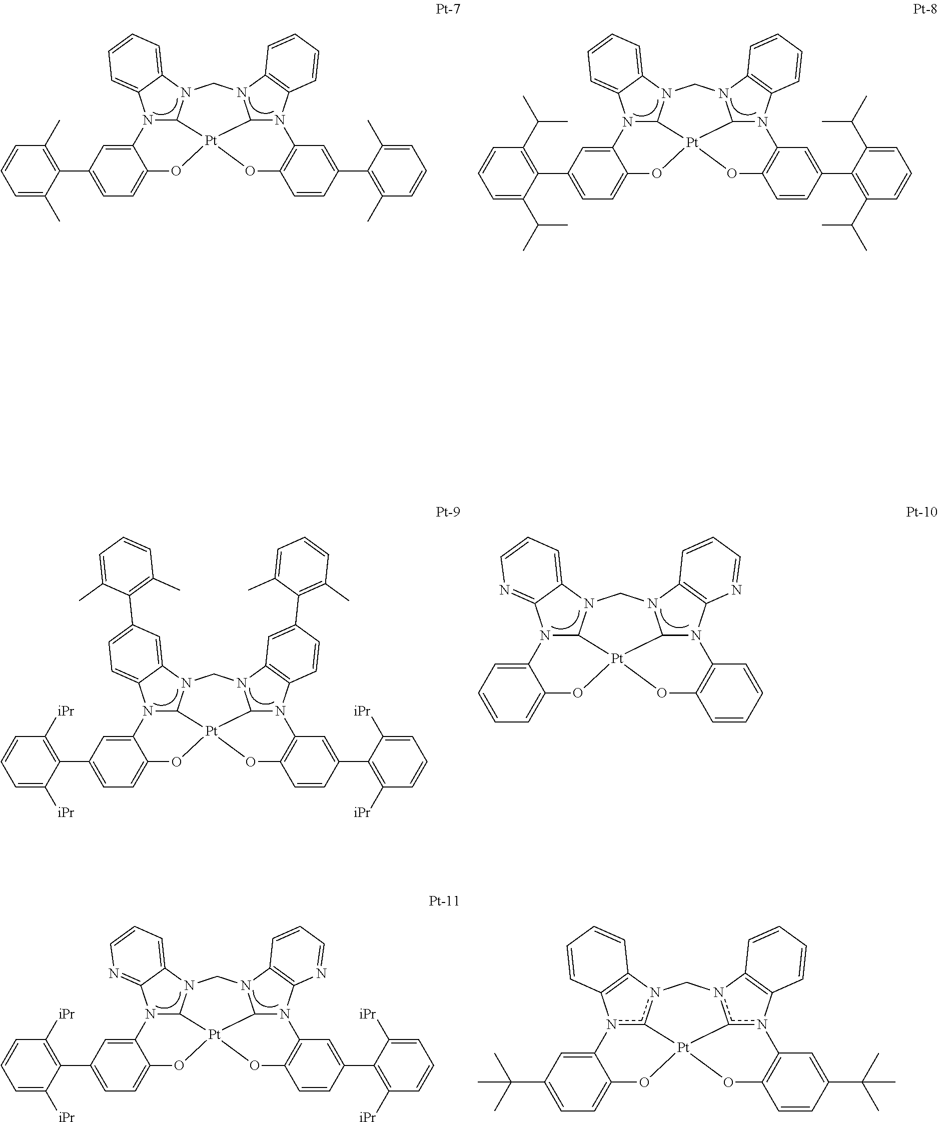

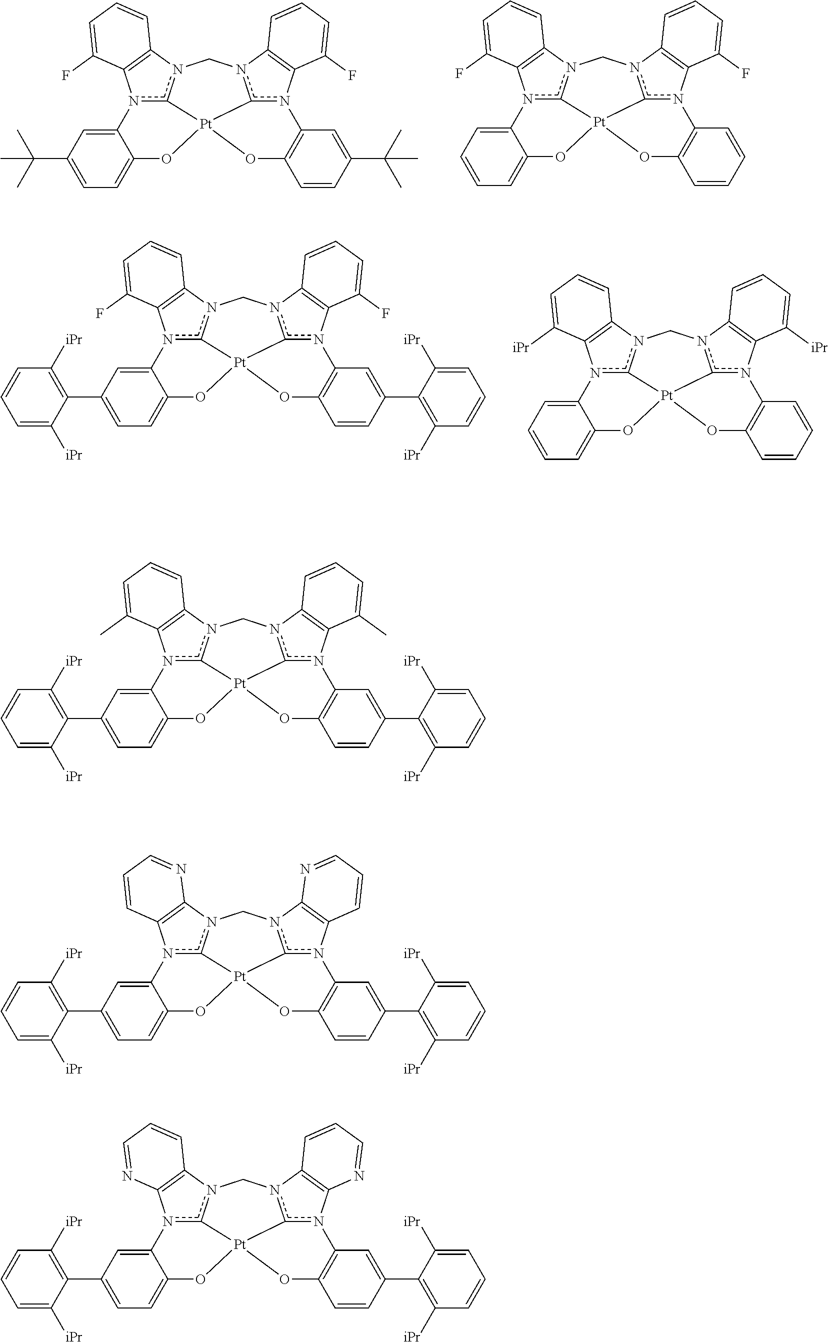

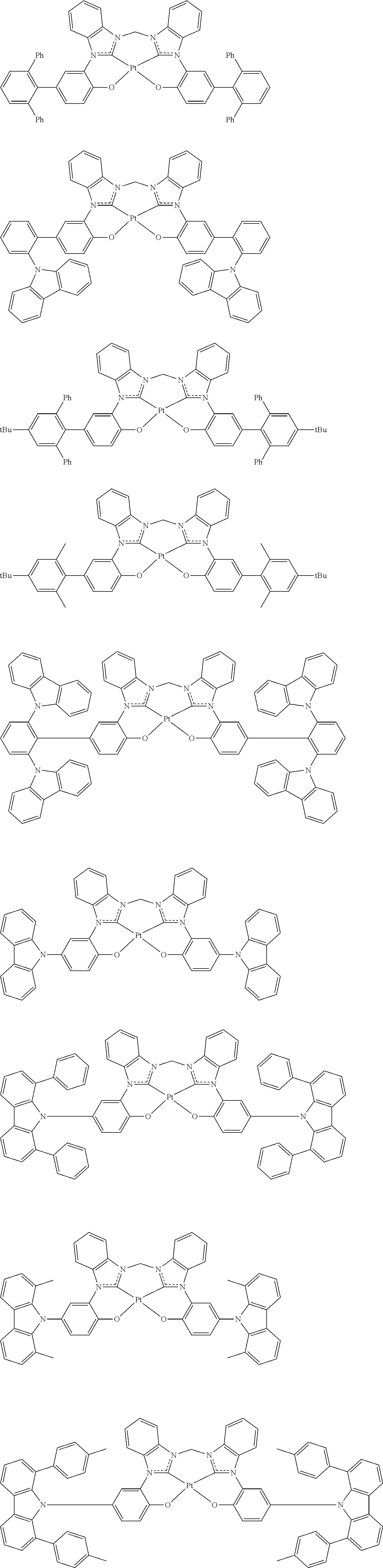

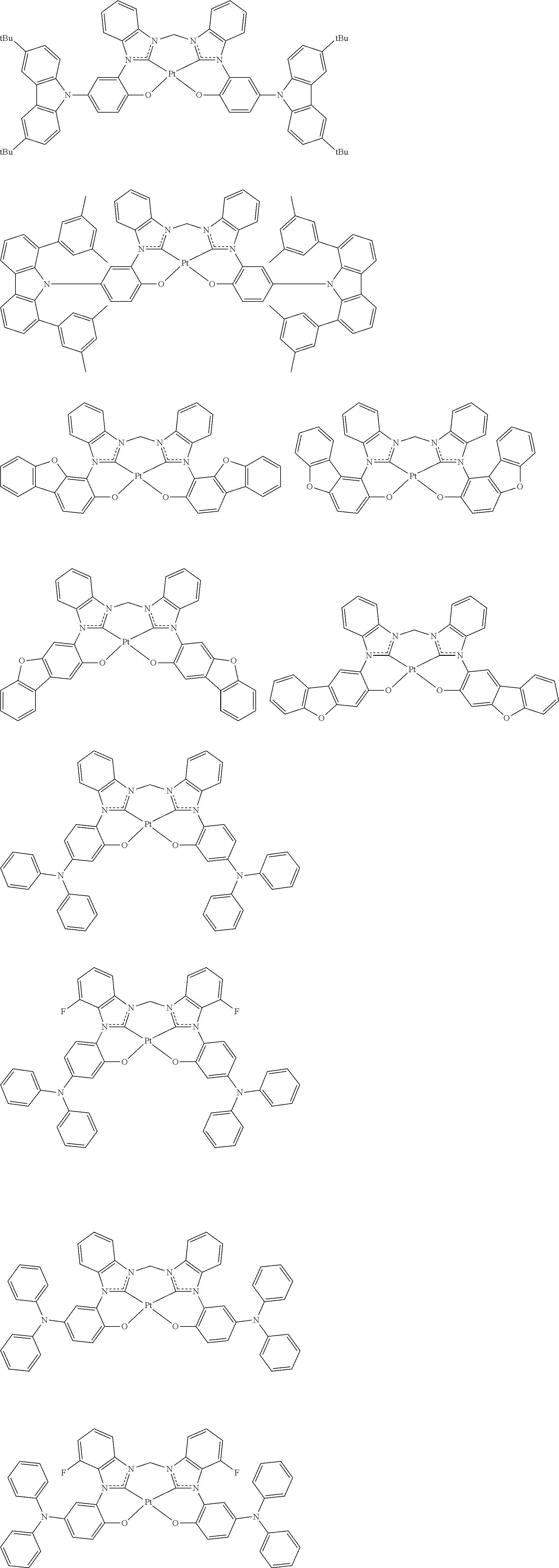

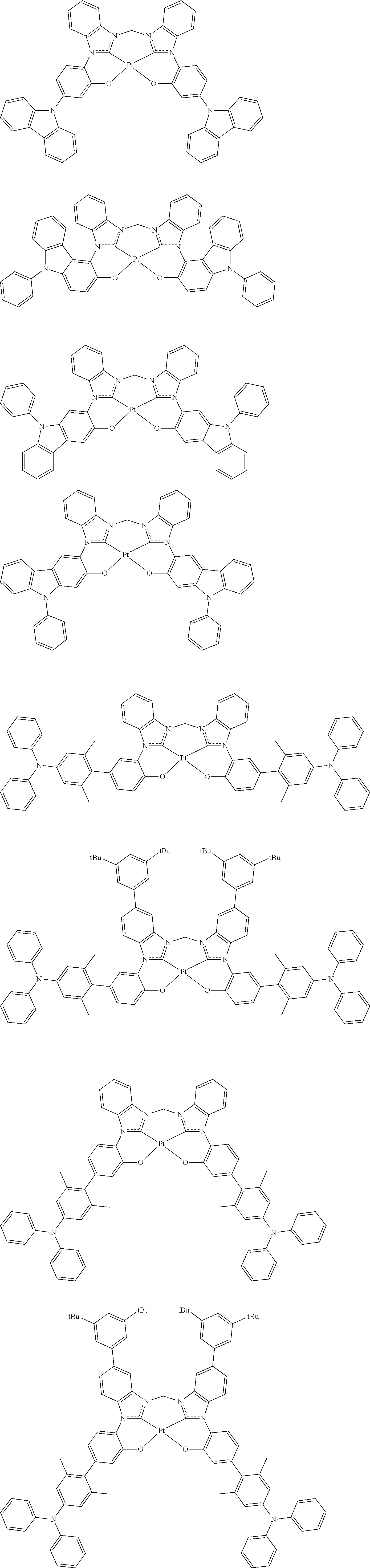

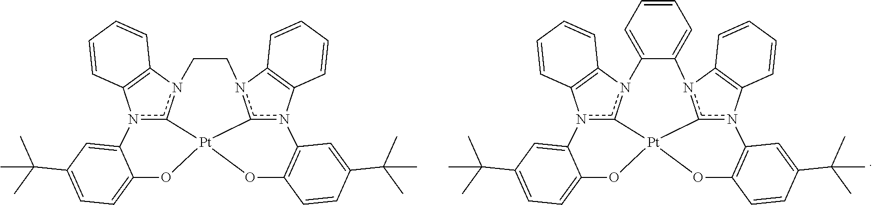

8. The platinum(II) complex of claim 1, wherein the platinum(II) complex has a maximum emission wavelength (λₘₐₓ) in a range from 420 nm to 490 nm, from 430 nm to 490 nm, from 440 nm to 490 nm, from 450 nm to 490 nm, from 460 nm to 490 nm, from 430 nm to 465 nm, or from 440 nm to 470 nm, such as from 441 nm to 454 nm.

9. The platinum(II) complex of claim 1, wherein the platinum(II) complex has an emission quantum yield (Φₑₘ) of at least 30%, at least 35%, at least 45%, at least 50%, at least 60%, at least 70%, in a range from 30% to 90%, from 30% to 85%, from 30% to 80%, from 35% to 85%, from 35% to 80%, from 45% to 85%, from 45% to 80%, from 50% to 85%, or from 50% to 80%, measured in films, at room temperature.

10. The platinum(II) complex of claim 1, wherein the platinum(II) complex has an emission lifetime (τₑₘ) of ≤5.5 μs, ≤5 μs, ≤4 μs, ≤3 μs, ≤2 μs, ≤1 μs, in a range from 0.5 μs to 5 μs, from 1 μs to 5 μs, or from 2 μs to 5 μs, such as about 2.25 μs, measured in films, at room temperature.

11. The platinum(II) complex of claim 1, wherein the platinum(II) complex has a radiative decay rate (kᵣ) of at least 1.0×10⁵ s⁻¹, at least 1.5×10⁵ s⁻¹, at least 2.0×10⁵ s⁻¹, in a range from 1.0×10⁵ s⁻¹ to 6.0×10⁵ s⁻¹, 1.0×10⁵ s⁻¹ to 5.0×10⁵ s⁻¹, 1.5×10⁵ s⁻¹ to 6.0×10⁵ s⁻¹, from 1.5×10⁵ s⁻¹ to 5.0×10⁵ s⁻¹, from 2.0×10⁵ s⁻¹ to 6.0×10⁵ s⁻¹, from 2.0×10⁵ s⁻¹ to 5.0×10⁵ s⁻¹, from 1.0×10⁵ s⁻¹ to 4.0×10⁵ s⁻¹, from 1.5×10⁵ s⁻¹ to 4.0×10⁵ s⁻¹, from 2.0×10⁵ s⁻¹ to 4.0×10⁵ s⁻¹, or from 3.0×10⁵ s⁻¹ to 6.0×10⁵ s⁻¹, such as about 3.4×10⁵ s⁻¹, measured in films, at room temperature.

12. An organic light-emitting component comprising a light-emitting layer or two or more light-emitting layers, wherein the light-emitting layer or each light-emitting layer of the two or more light-emitting layers comprises one or more platinum(II) complexes of claim 1, optionally wherein the organic light-emitting component emits light in the blue spectral region.

13. The organic light-emitting component of claim 12, wherein the total concentration of the one or more platinum(II) complexes in the light-emitting layer or each light-emitting layer of the two or more light-emitting layers is up to 20 wt %, up to 10 wt %, at least 1 wt %, in a range from about 1 wt % to about 20 wt %, from about 1 wt % to about 10 wt %, from about 2 wt % to about 20 wt %, or from about 2 wt % to about 10 wt %, such as about 2 wt %, about 6 wt %, or about 10 wt %.

14. The organic light-emitting component of claim 12, further comprising an anode, a cathode, a hole transport region, and an electron transport region,
wherein the hole transport region comprises a hole injection layer and/or a hole transport layer, and optionally an electron blocking layer,
wherein the electron transport region comprises an electron transport layer and/or an electron injection layer, and optionally a hole blocking layer,
wherein the light emitting layer is located in between the anode and the cathode,
wherein the hole transport region is located in between the anode and the light-emitting layer, and
wherein the electron transport region is located in between the cathode and the light emitting layer.

15. The organic light-emitting component of claim 12, wherein the organic light-emitting component emits light in the blue region, optionally at λₘₐₓ in a range from 420 nm to 490 nm, such as from 440 nm to 490 nm, from 450 nm to 490 nm, from 460 nm to 490 nm, from 430 nm to 480 nm, from 440 nm to 480 nm, from 450 nm to 480 nm, from 460 nm to 480 nm, or from 470 nm to 480 nm.

16. The organic light-emitting component of claim 12, wherein the organic light-emitting component has a maximum brightness (L) of at least 3000 cd m⁻², at least 4000 cd m⁻², at least 5000 cd m⁻², at least 6000 cd m⁻², at least 8000 cd m⁻², in a range from 3000 cd m⁻² to 50000 cd m⁻², from 3000 cd m⁻² to 40000 cd m⁻², from 3000 cd m⁻² to 30000 cd m⁻², from 3000 cd m⁻² to 25000 cd m⁻², or from 3000 cd m⁻² to 15000 cd m⁻².

17. The organic light-emitting component of claim 12, wherein the organic light-emitting component has a current efficiency (CE) at 1000 cd/m² of at least 20 cd A⁻¹, at least 25 cd/A, in a range from 20 cd/A to 50 cd/A, or from 20 cd/A to 45 cd/A.

18. The organic light-emitting component of claim 12, wherein the organic light-emitting component has a power efficiency (PE) at 1000 cd/m² of at least 20 lm/W, in a range from 20 lm/W to 50 lm/W, or from 20 lm/W to 45 lm/W.

19. The organic light-emitting component of claim 12, wherein the organic light-emitting component has an external quantum efficiency (EQE) at 1000 cd/m² of at least 10%, at least 15%, in a range from 10% to 35%, from 10% to 30%, from 10% to 25%, from 15% to 35%, from 15% to 30%, from 15% to 25%, from 20% to 30%, or from 15% to 20%, such as about 20%.

20. The organic light-emitting component of claim 12, wherein the organic light-emitting component is an organic light-emitting diode (“OLED”) or a light-emitting electrochemical cell (“LEEC”).

21. The organic light-emitting component of claim 12, wherein the light emitting layer or each light-emitting layer of the two or more light-emitting layers further comprises an organic dye, and wherein the one or more platinum(II) complexes act as a sensitizer to transfer energy to the organic dye.

22. The organic light-emitting component of claim 12, wherein the light emitting layer or each light-emitting layer of the two or more light-emitting layers further comprises an organic dye, and wherein the one or more platinum(II) complexes have a higher-lying singlet state than the organic dye.

23. The organic light-emitting component of claim 12, wherein the light-emitting layer or each of the light-emitting layer of the two or more light-emitting layers is formed by vacuum-evaporation deposition, spin-coating, ink-printing, or roll-to-roll printing.

24. A device comprising one or more organic light-emitting components of claim 12, wherein the device is a stationary visual display unit, a mobile visual display unit, an illumination device, a wearable device, a phototherapy device, or a medical monitoring device.
